(19) United States
(12) Patent Application Publication
(10) Pub. No.: US 2021/0382388 A1
(43) Pub. Date: Dec. 9, 2021

(54) CURABLE COMPOSITION, FILM, COLOR FILTER, METHOD FOR MANUFACTURING COLOR FILTER, SOLID-STATE IMAGING ELEMENT, IMAGE DISPLAY DEVICE, AND POLYMER COMPOUND

(71) Applicant: FUJIFILM Corporation, Tokyo (JP)

(72) Inventors: Junichi ITO, Shizuoka (JP); Yutaro FUKAMI, Shizuoka (JP); Yushi KANEKO, Shizuoka (JP); Kazuya OOTA, Shizuoka (JP); Hiromu KOIZUMI, Shizuoka (JP)

(73) Assignee: FUJIFILM Corporation, Tokyo (JP)

(21) Appl. No.: 17/395,469

(22) Filed: Aug. 6, 2021

Related U.S. Application Data
(63) Continuation of application No. PCT/JP2020/004843, filed on Feb. 7, 2020.

(30) Foreign Application Priority Data
Feb. 14, 2019 (JP) 2019-024236

(51) Int. Cl. G03F 7/00; G03F 7/039; G03F 7/038; C08F 283/02; C08F 220/58

(52) U.S. Cl. CPC G03F 7/0007; G03F 7/039; G02B 5/208; C08F 283/02; C08F 220/58; G03F 7/038

(57) ABSTRACT

Provided are a curable composition including a pigment and a resin which satisfies at least one or the following requirement 1 or the following requirement 2; a film and a color filter formed from the curable composition; a method for manufacturing a color filter formed from the curable composition; a solid-state imaging element and an image display device including the film or the color filter; and a polymer compound.

Requirement 1: the resin includes a constitutional unit having, in the same side chain, an anionic structure, a quaternary ammonium cationic structure which is ionically bonded to the anionic structure, and a radically polymerizable group.

Requirement 2: the resin includes a constitutional unit having, in a side chain, a quaternary ammonium cationic structure and a group to which a radically polymerizable group is linked.

### CROSS-REFERENCE TO RELATED APPLICATIONS

This application is a Continuation of PCT International Application No. PCT/JP2020/004843 filed on Feb. 7, 2020, which claims priority under 35 U.S.C § 119(a) to Japanese Patent Application No. 2019-024236 filed on Feb. 14, 2019. Each of the above application(s) is hereby expressly incorporated by reference, in its entirety, into the present application.

### BACKGROUND OF THE INVENTION

### 1. Field of the Invention

The present invention relates to a curable composition, a film, a color filter, a method for manufacturing a color filter, a solid-state imaging element, an image display device, and a polymer compound.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter and the like has been used as a key device in a display or an optical element.

The color filter has been manufactured using a curable composition including a colorant and a resin. In addition, in a case where a pigment is used as the colorant, the pigment is generally dispersed in the curable composition using a dispersant or the like.

JP1997-254133A (JP-H10-254133A) discloses an invention relating to a radiation sensitive coloring composition comprising (A) a copolymer consisting of at least a monofunctional macromonomer having a weight-average molecular weight of 3×10⁴ or less, which is formed by bonding a polymerizable double bond group having a specific structure to only one terminal of a polymer main chain containing a polymer component having a specific structure, a quaternary ammonium salt monomer having a specific structure, and a monomer having at least one acid amide group having a specific structure in the molecule; (B) a radiation sensitive compound; and (C) a pigment.

In addition, KR2001-0066314A discloses an electrodeposition paint composition comprising 10 to 40 mass % of a monomer which contains 0.5 to 30 mass % of a carboxylic acid compound selected from the group consisting of acrylic acid, methacrylic acid, maleic acid, and the like, 0.5 to 30 mass % of a reactant of glycidyl acrylate or glycidyl methacrylate having a specific structure and a quaternary ammonium salt, and at least one hydroxyl group selected from the group consisting of hydroxyalkyl acrylate and hydroxyalkyl methacrylate having 2 to 5 carbon atoms; 10 to 15 mass % of an acrylate copolymer which has a weight-average molecular weight of 3,000 to 30,000 obtained by reacting 10 to 70 mass % of an unsaturated monomer selected from the group consisting of alkyl acrylate and alkyl methacrylate having 2 to 5 carbon atoms at 60° C. to 120° C. and has a dielectric constant of 3.0 to 6.0 in a case where a thickness of a dry coating film is 1 to 2.5 μm; and 1 to 5 mass % of a pigment which has an average particle diameter of 20 to 150 nm selected from anthraquinone pigments and phthalocyanine pigments.

### SUMMARY OF THE INVENTION

Further improvement in adhesiveness with a support is desired for a film formed by using the curable composition.

An object of the present invention is to provide a curable composition with which a film having excellent adhesiveness with a support is formed. Another object of the present invention is to provide a film and a color filter formed from the above-described curable composition, a method for manufacturing a color filter using the above-described curable composition, a solid-state imaging element and an image display device including the film or the color filter, and a novel polymer compound.

Typical embodiments of the present invention are as follows.

<1> A curable composition comprising:

a pigment; and

a resin which satisfies at least one of the following requirement 1 or the following requirement 2,

requirement 1: the resin includes a constitutional unit having, in the same side chain, an anionic structure, a quaternary ammonium cationic structure which is ionically bonded to the anionic structure, and a radically polymerizable group,

requirement 2: the resin includes a constitutional unit having, in a side chain, a quaternary ammonium cationic structure and a group to which a radically polymerizable group is linked.

<2> The curable composition according to <1>,

in which the resin includes at least one of a constitutional unit represented by Formula (A1) or a constitutional unit represented by Formula (B1),

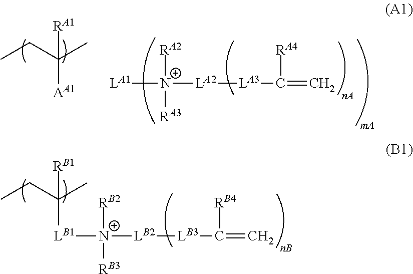

in Formula (A1), R^{A1} represents a hydrogen atom or an alkyl group,
A^{A1} represents a structure including a group in which a proton is separated from an acid group,
R^{A2} and R^{A3} each independently represent an alkyl group or an aralkyl group,
L^{A1} represents a monovalent substituent in a case where mA is 1, or represents a mA-valent linking group in a case where mA is 2 or more,
L^{A2} represents an (nA+1)-valent linking group,
L^{A3} represents a divalent linking group,
R^{A4} represents a hydrogen atom or an alkyl group,
nA represents an integer of 1 or more, and
mA represents an integer of 1 or more,
where in a case where mA is 2 or more, two or more R^{A2}'s, two or more R^{A3}'s, and two or more L^{A2}'s may be the same or different from each other,
in a case where mA is 2 or more, at least one of mA pieces of structures including a quaternary ammonium cation, which is selected from the group consisting of R^{A2} and R^{A3} included in one structure, may form a ring structure with at least one selected from the group consisting of R^{A2} and R^{A3} included in another structure,
in a case where at least one selected from the group consisting of nA and mA is 2 or more, two or more L^{A3}'s and two or more R^{A4}'s may be the same or different from each other, and
at least two of R^{A2}, R^{A3}, or L^{A2} may be bonded to each other to form a ring,
in Formula (B1), R^{B1} represents a hydrogen atom or an alkyl group,
L^{B1} represents a divalent linking group,
R^{B2} and R^{B3} each independently represent an alkyl group,
L^{B2} represents an (nB+1)-valent linking group,
L^{B3} represents a divalent linking group,
R^{B4} represents a hydrogen atom or an alkyl group, and
nB represents an integer of 1 or more,
where in a case where nB is 2 or more, two or more L^{B3}'s and two or more R^{B4}'s may be the same or different from each other, and
at least two of R^{B2}, R^{B3}, L^{B1}, or L^{B2} may be bonded to each other to form a ring.

<3> The curable composition according to <2>,

in which nA in Formula (A1) is 1 and a bond between L^{A2} and L^{A3} represents any one of groups represented by Formulae (C1) to (C4), or

nB in Formula (B1) is 1 and L^{B2} and L^{B3} represent any one of groups represented by Formulae (C1) to (C4),

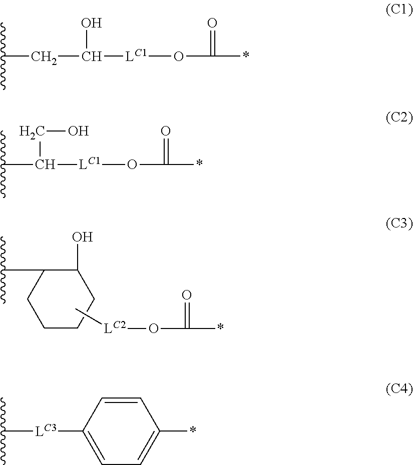

in Formulae (C1) to (C4), L^{C1}, L^{C2}, and L^{C3} each independently represent a single bond or a divalent linking group,
a wavy line part represents a bonding site with a nitrogen atom in Formula (A1) or Formula (B1), and
* represents a bonding site with a carbon atom to which R^{A4} in Formula (A1) is bonded or a carbon atom to which R^{B4} in Formula (B1) is bonded.

<4> The curable composition according to any one of <1> to <3>,

in which a content of the constitutional unit represented by Formula (A1) and a content of the constitutional unit represented by Formula (B1) in the resin are 1 mass % to 60 mass %.

<5> The curable composition according to any one of <1> to <4>,

in which the resin has a radically polymerizable group and further includes a constitutional unit D which is different from the constitutional unit represented by Formula (A1) and the constitutional unit represented by Formula (B1).

<6> The curable composition according to <5>,

in which the resin further includes a constitutional unit represented by Formula (D1) as the constitutional unit D,

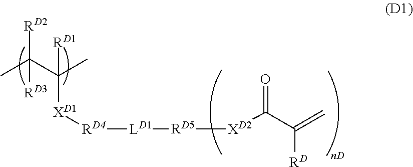

in Formula (D1), R^{D1} to R^{D3} each independently represent a hydrogen atom or an alkyl group,
X^{D1} represents —COO—, —CONR^{D6}—, or an arylene group, where R^{D6} represents a hydrogen atom, an alkyl group, or an aryl group,
R^{D4} represents a divalent linking group,
L^{D1} represents a group represented by Formula (D2), Formula (D3), or Formula (D3′),
R^{D5} represents an (n+1)-valent linking group,
X^{D2} represents an oxygen atom or NR^{D7}—, where R^{D7} represents a hydrogen atom, an alkyl group, or an aryl group,
R^{D} represents a hydrogen atom or a methyl group, and
nD represents an integer of 1 or more,
where in a case where nD is 2 or more, two or more X^{D2}'s and two or more R^{D}'s may be the same or different from each other,

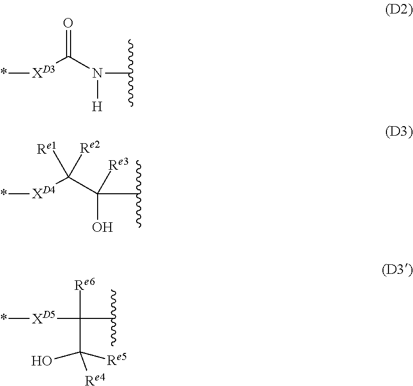

in Formulae (D2), (D3), and (D3′), X^{D3} represents an oxygen atom or —NH—,
X^{D4} represents an oxygen atom or —COO—,
R^{e1} to R^{e3} each independently represent a hydrogen atom or an alkyl group, where at least two of R^{e1} to R^{e3} may be bonded to each other to form a ring structure,
X^{D5} represents an oxygen atom or —COO—,
R^{e4} to R^{e6} each independently represent a hydrogen atom or an alkyl group, where at least two of R^{e4} to R^{e6} may be bonded to each other to form a ring structure, and
* and a wavy line part represent a bonding position with other structures.

<7> The curable composition according to any one of <1> to <6>,

in which the resin further includes a constitutional unit represented by Formula (D5),

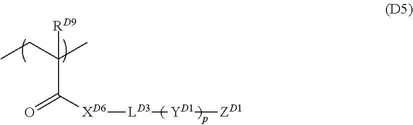

in Formula (D5), R^{D9} represents a hydrogen atom or an alkyl group,
X^{D6} represents an oxygen atom or NR^{C}—, where R^{C} represents a hydrogen atom, an alkyl group, or an aryl group,
L^{D3} represents a divalent linking group,
Y^{D1} represents an alkyleneoxy group or an alkylenecarbonyloxy group,
Z^{D1} represents an aliphatic hydrocarbon group having 1 to 20 carbon atoms or an aromatic hydrocarbon group having 6 to 20 carbon atoms, and
p represents an integer of 1 or more, where in a case where p is 2 or more, p pieces of Y^{D1}'s may be the same or different from each other.

<8> The curable composition according to any one of <1> to <7>, further comprising:

an oxime compound as a photopolymerization initiator.

<9> The curable composition according to any one of <1> to <8>, further comprising:

a polymerizable compound.

<10> The curable composition according to any one of <1> to <9>,

in which the curable composition is used for forming a colored layer or an infrared absorbing layer of a color filter.

<11> A film formed from the curable composition according to any one of <1> to <10>.

<12> A color filter formed from the curable composition according to any one of <1> to <10>.

<13> A method for manufacturing a color filter, comprising:

a step of forming a composition layer on a support by applying the curable composition according to any one of <1> to <10> to the support;

a step of patternwise exposing the composition layer; and

a step of forming a colored pattern by developing and removing an unexposed area.

<14> A method for manufacturing a color filter, comprising:

a step of forming a composition layer on a support by applying the curable composition according to any one of <1> to <10> to the support, and curing the composition layer to form a cured layer;

a step of forming a photoresist layer on the cured layer;

a step of obtaining a resist pattern by patterning the photoresist layer by exposure and development; and

a step of etching the cured layer using the resist pattern as an etching mask.

<15> A solid-state imaging element comprising:

the film according to <11>, or

the color filter according to <12>.

<16> An image display device comprising:

the film according to <11>, or

the color filter according to <12>.

<17> A polymer compound comprising:

at least one of a constitutional unit represented by Formula (A1) or a constitutional unit represented by Formula (B1),

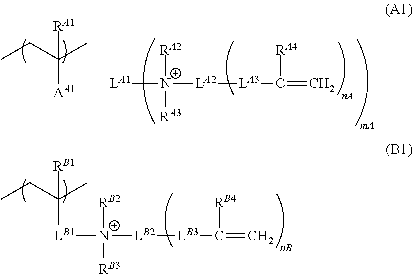

in Formula (A1), R^{A1} represents a hydrogen atom or an alkyl group,
A^{A1} represents a structure including a group in which a proton is separated from an acid group,
R^{A2} and R^{A3} each independently represent an alkyl group or an aralkyl group,
L^{A1} represents a monovalent substituent in a case where mA is 1, or represents a mA-valent linking group in a case where mA is 2 or more,
L^{A2} represents an (nA+1)-valent linking group,
L^{A3} represents a divalent linking group,
R^{A4} represents a hydrogen atom or an alkyl group,
nA represents an integer of 1 or more, and
mA represents an integer of 1 or more,
where in a case where mA is 2 or more, two or more R^{A2}'s, two or more R^{A3}'s, and two or more L^{A2}'s may be the same or different from each other,
in a case where mA is 2 or more, at least one of mA pieces of structures including a quaternary ammonium cation, which is selected from the group consisting of R^{A2} and R^{A3} included in one structure, may form a ring structure with at least one selected from the group consisting of R^{A2} and R^{A3} included in another structure,
in a case where at least one selected from the group consisting of nA and mA is 2 or more, two or more L^{A3}'s and two or more R^{A4}'s may be the same or different from each other, and
at least two of R^{A2}, R^{A3}, or L^{A2} may be bonded to each other to form a ring,
in Formula (B1), R^{B1} represents a hydrogen atom or an alkyl group,
L^{B1} represents a divalent linking group,
R^{B2} and R^{B3} each independently represent an alkyl group,
L^{B2} represents an (nB+1)-valent linking group,
L^{B3} represents a divalent linking group,
R^{B4} represents a hydrogen atom or an alkyl group, and
nB represents an integer of 1 or more,
where in a case where nB is 2 or more, two or more L^{B3}'s and two or more R^{B4}'s may be the same or different from each other, and
at least two of R^{B2}, R^{B3} L^{B1}, or L^{B2} may be bonded to each other to form a ring.

<18> The polymer compound according to <17>,

in which nA in Formula (A1) is 1 and a bond between L^{A2} and L^{A3} represents any one of groups represented by Formulae (C1) to (C4), or

nB in Formula (B1) is 1 and L^{B2} and L^{B3} represent any one of groups represented by Formulae (C1) to (C4),

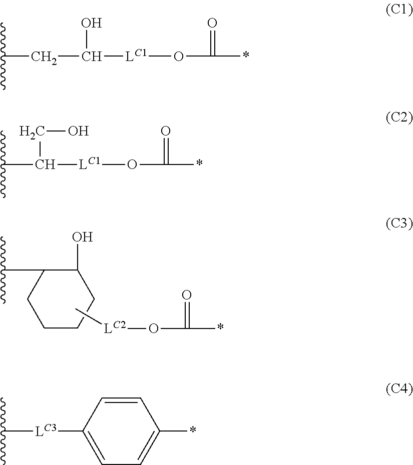

in Formulae (C1) to (C4), L^{C1}, L^{C2}, and L^{C3} each independently represent a divalent linking group,
a wavy line part represents a bonding site with a nitrogen atom in Formula (A1) or Formula (B1), and
* represents a bonding site with a carbon atom to which R^{A4} in Formula (A1) is bonded or a carbon atom to which R^{B4} in Formula (B1) is bonded.

According to the present invention, a curable composition with which a film having excellent adhesiveness with a support is formed is provided. In addition, a film and a color filter formed from the above-described curable composition, a method for manufacturing a color filter using the above-described curable composition, a solid-state imaging element and an image display device including the film or the color filter, and a novel polymer compound are provided.

### BRIEF DESCRIPTION OF THE DRAWINGS

FIG. 1 is a schematic view showing a measurement position of an undercut width in a cured product on a pattern in Example.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright line spectrum of a mercury lamp, a far ultraviolet ray represented by excimer laser, an extreme ultraviolet ray (EUV ray), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight (Mw) and a number-average molecular weight (Mn) are values in terms of polystyrene measured by gel permeation chromatography (GPC) method.

In the present specification, near-infrared rays denote light having a wavelength in a range of 700 to 2,500 nm.

In the present specification, a solid content denotes a mass of all the components of the composition excluding a solvent.

In the present specification, a pigment means a compound which is hardly dissolved in a solvent. For example, as the pigment, both of the solubility in 100 g of water at 23° C. and 100 g of propylene glycol monomethyl ether acetate at 23° C. is preferably 0.1 g or less and more preferably 0.01 g or less.

In the present specification, the term “step” denotes not only an individual step but also a step which is not clearly distinguishable from another step as long as an effect expected from the step can be achieved.

In the present specification, unless otherwise specified, a composition may include, as each component included in the composition, two or more kinds of compounds corresponding to the component. In addition, unless otherwise specified, a content of each component in the composition means the total content of all the compounds corresponding to the component.

In the present specification, unless otherwise specified, a wavy line part or * (asterisk) in the structural formula represents a bonding site with another structure.

In addition, in the present specification, a combination of preferred aspects is a more preferred aspect.

(Curable Composition)

A curable composition according to an embodiment of the present invention includes a pigment and a resin (hereinafter, also referred to as a “specific resin”) which satisfies at least one of the following requirement 1 or the following requirement 2.

Requirement 1: the resin includes a constitutional unit having, in the same side chain, an anionic structure, a quaternary ammonium cationic structure which is ionically bonded to the anionic structure, and a radically polymerizable group.

Requirement 2: the resin includes a constitutional unit having, in a side chain, a quaternary ammonium cationic structure and a group to which a radically polymerizable group is linked.

With the curable composition according to the embodiment of the present invention, a film having excellent adhesiveness to a support is obtained. The reason why the above-described effect is obtained is presumed as follows.

Since the specific resin in the curable composition according to the embodiment of the present invention satisfies at least one of the above requirement 1 or the above requirement 2, the specific resin includes a quaternary ammonium cationic structure and a radically polymerizable group in the same side chain.

Due to the electrostatic interaction between the quaternary ammonium structures, in the polymerization of radically polymerizable groups included in the same side chain with the quaternary ammonium cationic structure, the polymerization of radically polymerizable groups (intramolecular cross-linking) in the molecule of the specific resin is suppressed. For example, since polymerization (intermolecular cross-linking) between a specific resin molecule and another specific resin molecule, such as between molecules of a specific resin, is likely to occur, it is presumed that a film having excellent adhesiveness to the support is obtained.

Here, neither JP1997-254133A (JP-H10-254133A) nor KR2001-0066314A discloses or suggests a curable composition including a resin satisfying at least one of the above-described requirement 1 or requirement 2.

It is considered that the curable composition according to the embodiment of the present invention is likely to be excellent in pattern shape of a pattern obtained by using the curable composition. It is presumed that this is because the above-described intermolecular cross-linking is likely to occur due to the above-described electrostatic interaction between quaternary ammonium structures, and thus curability of the curable composition is improved.

In addition, in a case where the curable composition according to the embodiment of the present invention further includes a polymerizable compound described later, since polymerization between the resin and the polymerizable compound is more likely to occur than the polymerization between the resins due to the above-described electrostatic interaction between quaternary ammonium structures, it is considered that the curable composition is likely to be excellent in curability, and the pattern shape of the pattern obtained by curing the curable composition is more likely to be excellent.

Since the curable composition according to the embodiment of the present invention includes the specific resin, storage stability of the curable composition is likely to be improved. It is presumed that this is because the above-described electrostatic interaction suppresses aggregation of the pigments.

Since the curable composition according to the embodiment of the present invention includes the specific resin, the generation of development residue during the formation of the above-described pattern is likely to be suppressed. It is presumed that this is because the hydrophilicity of the specific resin is improved by including the quaternary ammonium structure in the side chain, and the development residue is easily removed.

Since the curable composition according to the embodiment of the present invention includes the specific resin, sustenance-defect is easily suppressed. The “sustenance-defect” means a phenomenon in which, in a case where a certain period of time (for example, 12 hours to 3 days, and the like) elapses from the application of the curable composition to the support or the like to form a composition layer until patterning by exposure, development, and the like, a defect (for example, granular aggregates are generated in the composition layer over time, and since such components are difficult to develop and remove, the components remain on the support and become defects) is found in the obtained pattern. In the curable composition according to the embodiment of the present invention, it is presumed that the above-described electrostatic interaction suppresses the occurrence of pigment aggregation even in the above-described composition layer, so that the sustenance-defect is likely to be suppressed.

The curable composition according to the embodiment of the present invention can be preferably used as a curable composition for a color filter. Specifically, the curable composition according to the embodiment of the present invention can be preferably used as a composition for forming a pixel of a color filter.

In addition, the curable composition according to the embodiment of the present invention can be preferably used as a curable composition for a solid-state imaging element, and can be more preferably used as a curable composition for forming a pixel of a color filter used in the solid-state imaging element.

In addition, the curable composition according to the embodiment of the present invention can also be preferably used as a curable composition for a display device, and can be more preferably used as a coloring composition for forming a pixel of a color filter used in the display device.

In addition, the curable composition according to the embodiment of the present invention can also be used as a composition for forming a color microlens. Examples of a method for manufacturing the color microlens include the method described in JP2018-010162A.

Hereinafter, the curable composition according to the embodiment of the present invention will be described in detail.

<Pigment>

The curable composition according to the embodiment of the present invention contains a pigment.

Examples of the pigment include a white pigment, a black pigment, a chromatic pigment, a transparent pigment, and a near-infrared absorbing pigment. In the present invention, the white pigment includes not only a pure white pigment but also a bright gray (for example, grayish-white, light gray, and the like) pigment close to white.

In addition, the pigment may be an inorganic pigment or an organic pigment, but from the viewpoint that dispersion stability is more easily improved, an organic pigment is preferable.

In addition, as the pigment, a pigment having a maximum absorption wavelength in a wavelength range of 400 to 2,000 nm is preferable, and a pigment having a maximum absorption wavelength in a wavelength range of 400 to 700 nm is more preferable.

In addition, in a case of using a pigment (preferably a chromatic pigment) having a maximum absorption wavelength in a wavelength range of 400 to 700 nm, the curable composition according to the embodiment of the present invention can be preferably used as a curable composition for forming a colored layer or an infrared absorbing layer in a color filter.

Examples of the colored layer include a red-colored layer, a green-colored layer, a blue-colored layer, a magenta-colored layer, a cyan-colored layer, and a yellow-colored layer.

The average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the curable composition is good. In the present invention, the primary particle diameter of the pigment can be determined from an image photograph obtained by observing primary particles of the pigment using a transmission electron microscope. Specifically, a projected area of the primary particles of the pigment is determined, and a diameter (circle-equivalent diameter) of a perfect circle with the same area as the projected area is calculated as the primary particle diameter of the pigment. In addition, the average primary particle diameter in the present invention is the arithmetic average value of the primary particle diameters with respect to 400 primary particles of the pigment. In addition, the primary particle of the pigment refers to a particle which is independent without aggregation.

[Chromatic Pigment]

The chromatic pigment is not particularly limited, and a known chromatic pigment can be used. Examples of the chromatic pigment include a pigment having a maximum absorption wavelength in a wavelength range of 400 to 700 nm. Examples thereof include a yellow pigment, an orange pigment, a red pigment, a green pigment, a violet pigment, and a blue pigment. Specific examples of these pigments include the following pigments.

Color Index (C. I.) Pigment Yellow (hereinafter, also simply referred to as “PY”) 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 231, 232 (methine/polymethine-based), 233 (quinoline-based), and the like (all of which are yellow pigments);

C. I. Pigment Orange (hereinafter, also simply referred to as “PO”) 2, 5, 13, 16, 17:1, 31, 34, 36, 38, 43, 46, 48, 49, 51, 52, 55, 59, 60, 61, 62, 64, 71, 73, and the like (all of which are orange pigments);

C. I. Pigment Red (hereinafter, also simply referred to as “PR”) 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, 294 (xanthene-based, Organo Ultramarine, Bluish Red), 295 (azo-based), 296 (azo-based), and the like (all of which are red pigments);

C. I. Pigment Green (hereinafter, also simply referred to as “PG”) 7, 10, 36, 37, 58, 59, 62, 63, and the like (all of which are green pigments);

C. I. Pigment Violet (hereinafter, also simply referred to as “PV”) 1, 19, 23, 27, 32, 37, 42, 60 (triarylmethane-based), 61 (xanthene-based), and the like (all of which are violet pigments); and

C. I. Pigment Blue (hereinafter, also simply referred to as “PB”) 1, 2, 15, 15:1, 15:2, 15:3, 15:4, 15:6, 16, 22, 29, 60, 64, 66, 79, 80, 87 (monoazo-based), 88 (methine/polymethine-based), and the like (all of which are blue pigments).

In the curable composition according to the embodiment of the present invention, from the viewpoint that the effects of the present invention are more easily obtained, it is preferable to include a green pigment as the pigment, more preferable to include halogenated phthalocyanine, and still more preferable to include PG 36 and/or PG 58.

In addition, it is also preferable that the curable composition according to the embodiment of the present invention includes the above-described green pigment and yellow pigment in combination. Preferred examples of the yellow pigment in this case include PY 150 and/or PY 185.

—Green Pigment—

In addition, as the green pigment, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include compounds described in WO2015/118720A. In addition, as the green pigment, compounds described in CN2010-6909027A, a phthalocyanine compound having a phosphoric acid ester as a ligand, or the like can also be used.

—Blue Pigment—

In addition, as the blue pigment, an aluminum phthalocyanine compound having a phosphorus atom can also be used. Specific examples thereof include the compounds described in paragraphs 0022 to 0030 of JP2012-247591A and paragraph 0047 of JP2011-157478A.

—Yellow Pigment—

In addition, a pigment described in JP2017-201003A and a pigment described in JP2017-197719A can be used as the yellow pigment.

In addition, as the yellow pigment, a metal azo pigment which includes at least one kind of an anion selected from the group consisting of an azo compound represented by Formula (I) and an azo compound having a tautomeric structure of the azo compound represented by Formula (I), two or more kinds of metal ions, and a melamine compound can also be used.

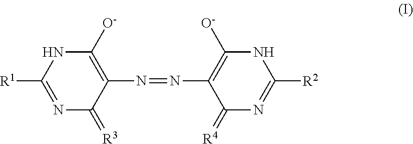

In the formula, R¹ and R² each independently represent —OH or —NR⁵R⁶, R³ and R⁴ each independently represent ═O or ═NR⁷, and R⁵ to R⁷ each independently represent a hydrogen atom or an alkyl group. The alkyl group represented by R⁵ to R⁷ preferably has 1 to 10 carbon atoms, more preferably has 1 to 6 carbon atoms, and still more preferably has 1 to 4 carbon atoms. The alkyl group may be linear, branched, or cyclic, and is preferably linear or branched and more preferably linear. The alkyl group may have a substituent. The substituent is preferably a halogen atom, a hydroxy group, an alkoxy group, a cyano group, or an amino group.

The details of the metal azo pigment can be found in paragraph Nos. 0011 to 0062 and 0137 to 0276 of JP2017-171912A, paragraph Nos. 0010 to 0062 and 0138 to 0295 of JP2017-171913A, paragraph Nos. 0011 to 0062 and 0139 to 0190 of JP2017-171914A, and paragraph Nos. 0010 to 0065 and 0142 to 0222 of JP2017-171915A, the contents of which are incorporated herein by reference.

—Red Pigment—

A diketopyrrolopyrrole-based pigment described in JP2017-201384A, in which the structure has at least one substituted bromine atom, a diketopyrrolopyrrole-based pigment described in paragraph Nos. 0016 to 0022 of JP6248838, and the like can also be used as the red pigment. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used. As the compound, a compound represented by Formula (DPP1) is preferable, and a compound represented by Formula (DPP2) is more preferable.

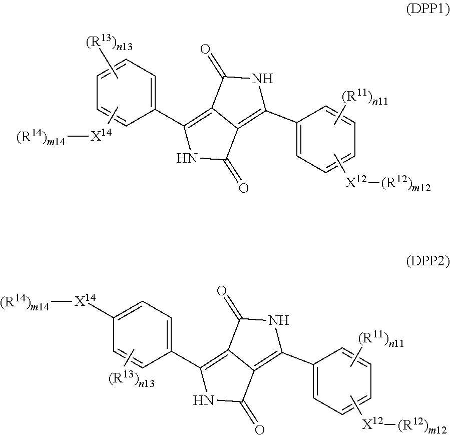

In the formulae, R¹¹ and R¹³ each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X² is an oxygen atom or a sulfur atom, m12 represents 1, in a case where X¹² is a nitrogen atom, m12 represents 2, in a case where X¹⁴ is an oxygen atom or a sulfur atom, m14 represents 1, and in a case where X¹⁴ is a nitrogen atom, m14 represents 2. Examples of the substituent represented by R¹¹ and R¹³ include the groups in substituent T described below, and preferred specific examples thereof include an alkyl group, an aryl group, a halogen atom, an acyl group, an alkoxycarbonyl group, an aryloxycarbonyl group, a heteroaryloxycarbonyl group, an amide group, a cyano group, a nitro group, a trifluoromethyl group, a sulfoxide group, and a sulfo group.

Examples of the substituent T include a linear or branched alkyl group (having preferably 1 to 24 carbon atoms, more preferably 1 to 12 carbon atoms, and still more preferably 1 to 6 carbon atoms), a cycloalkyl group (having preferably 3 to 24 carbon atoms, more preferably 3 to 12 carbon atoms, and still more preferably 3 to 6 carbon atoms), an aralkyl group (having preferably 7 to 21 carbon atoms, more preferably 7 to 15 carbon atoms, and still more preferably 7 to 11 carbon atoms), a linear or branched alkenyl group (having preferably 2 to 24 carbon atoms, more preferably 2 to 12 carbon atoms, and still more preferably 2 to 6 carbon atoms), a cycloalkenyl group (having preferably 3 to 24 carbon atoms, more preferably 3 to 12 carbon atoms, and still more preferably 3 to 6 carbon atoms), a hydroxyl group, a hydroxylalkyl group (having preferably 1 to 24 carbon atoms, more preferably 1 to 12 carbon atoms, and still more preferably 1 to 6 carbon atoms; having preferably 1 to 6 hydroxyl groups and more preferably 1 to 3 hydroxyl groups; the alkyl group may be linear, branched, chain-like, or cyclic), a hydroxylalkenyl group (having preferably 2 to 24 carbon atoms, more preferably 2 to 12 carbon atoms, and still more preferably 2 to 6 carbon atoms; having preferably 1 to 6 hydroxyl groups and more preferably 1 to 3 hydroxyl groups; the alkenyl group may be linear, branched, chain-like, or cyclic), an amino group (having preferably 0 to 24 carbon atoms, more preferably 0 to 12 carbon atoms, and still more preferably 0 to 6 carbon atoms), an aminoalkyl group (having preferably 1 to 24 carbon atoms, more preferably 1 to 12 carbon atoms, and still more preferably 1 to 6 carbon atoms; having preferably 1 to 6 amino groups and more preferably 1 to 3 amino groups; the alkyl group may be linear, branched, chain-like, or cyclic), an aminoalkenyl group (having preferably 2 to 24 carbon atoms, more preferably 2 to 12 carbon atoms, and still more preferably 2 to 6 carbon atoms; having preferably 1 to 6 amino groups and more preferably 1 to 3 amino groups; the alkenyl group may be linear, branched, chain-like, or cyclic), a thiol group, an thiolalkyl group (having preferably 1 to 24 carbon atoms, more preferably 1 to 12 carbon atoms, and still more preferably 1 to 6 carbon atoms; having preferably 1 to 6 thiol groups and more preferably 1 to 3 thiol groups; the alkyl group may be linear, branched, chain-like, or cyclic), an thiolalkenyl group (having preferably 2 to 24 carbon atoms, more preferably 2 to 12 carbon atoms, and still more preferably 2 to 6 carbon atoms; having preferably 1 to 6 thiol groups and more preferably 1 to 3 thiol groups; the alkenyl group may be linear, branched, chain-like, or cyclic), a carboxyl group, a carboxyalkyl group (having preferably 1 to 24 carbon atoms, more preferably 1 to 12 carbon atoms, and still more preferably 1 to 6 carbon atoms; having preferably 1 to 6 carboxyl groups and more preferably 1 to 3 carboxyl groups; the alkyl group may be linear, branched, chain-like, or cyclic), a carboxyalkenyl group (having preferably 2 to 24 carbon atoms, more preferably 2 to 12 carbon atoms, and still more preferably 2 to 6 carbon atoms; having preferably 1 to 6 carboxyl groups and more preferably 1 to 3 carboxyl groups; the alkenyl group may be linear, branched, chain-like, or cyclic), an aryl group (having preferably 6 to 22 carbon atoms, more preferably 6 to 18 carbon atoms, and still more preferably 6 to 10 carbon atoms), an acyl group (having preferably 2 to 12 carbon atoms, more preferably 2 to 6 carbon atoms, and still more preferably 2 or 3 carbon atoms), an acyloxy group (having preferably 2 to 12 carbon atoms, more preferably 2 to 6 carbon atoms, and still more preferably 2 or 3 carbon atoms), an aryloyl group (having preferably 7 to 23 carbon atoms, more preferably 7 to 19 carbon atoms, and still more preferably 7 to 11 carbon atoms), an aryloyloxy group (having preferably 7 to 23 carbon atoms, more preferably 7 to 19 carbon atoms, and still more preferably 7 to 11 carbon atoms), a heterocyclic group (having preferably 1 to 12 carbon atoms, more preferably 1 to 8 carbon atoms, and still more preferably 2 to 5 carbon atoms; having preferably a 5- or 6-membered ring), a (meth)acryloyl group, a (meth)acryloyloxy group, an (meth)acryloyloxyalkyl group (having preferably 1 to 24 carbon atoms, more preferably 1 to 12 carbon atoms, and still more preferably 1 to 6 carbon atoms; the alkyl group may be linear, branched, chain-like, or cyclic), a halogen atom (for example, a fluorine atom, a chlorine atom, a bromine atom, or an iodine atom), an oxo group (═O), an imino group (═NRN), and an alkylidene group (═C(R^{N})₂). R^{N} represents a hydrogen atom or an alkyl group (preferably an alkyl group having 1 to 12 carbon atoms, more preferably an alkyl group having 1 to 6 carbon atoms, still more preferably an alkyl group having 1 to 3 carbon atoms, and still more preferably a methyl group).

In the present invention, the chromatic pigment may be used in combination of two or more kinds thereof. In addition, in a case where the chromatic pigment is used in combination of two or more kinds thereof, the combination of two or more chromatic pigments may form black. Examples of such a combination include the following aspects (1) to (7). In a case where two or more chromatic pigments are included in the curable composition and the combination of two or more chromatic pigments forms black, the curable composition according to the embodiment of the present invention can be preferably used as a near-infrared transmission filter.

(1) aspect in which a red pigment and a blue pigment are contained.

(2) aspect in which a red pigment, a blue pigment, and a yellow pigment are contained.

(3) aspect in which a red pigment, a blue pigment, a yellow pigment, and a violet pigment are contained.

(4) aspect in which a red pigment, a blue pigment, a yellow pigment, a violet pigment, and a green pigment are contained.

(5) aspect in which a red pigment, a blue pigment, a yellow pigment, and a green pigment are contained.

(6) aspect in which a red pigment, a blue pigment, and a green pigment are contained.

(7) aspect in which a yellow pigment and a violet pigment are contained.

[White Pigment]

Examples of the white pigment include titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white pigment is preferably particles having a titanium atom, more preferably titanium oxide. In addition, the white pigment is preferably a particle having a refractive index of 2.10 or more at 25° C. with respect to light having a wavelength of 589 nm. The above-mentioned refractive index is preferably 2.10 to 3.00 and more preferably 2.50 to 2.75.

In addition, as the white pigment, the titanium oxide described in “Titanium Oxide-Physical Properties and Applied Technology, written by Manabu Kiyono, pages 13 to 45, published on Jun. 25, 1991, published by Shuppan Co., Ltd.” can also be used.

The white pigment is not limited to a compound formed of a single inorganic substance, and may be particles combined with other materials. For example, it is preferable to use a particle having a pore or other materials therein, a particle having a number of inorganic particles attached to a core particle, or a core-shell composite particle composed of a core particle formed of polymer particles and a shell layer formed of inorganic fine nanoparticles. With regard to the core-shell composite particle composed of a core particle formed of polymer particles and a shell layer formed of inorganic fine nanoparticles, reference can be made to, for example, the descriptions in paragraph Nos. 0012 to 0042 of JP2015-047520A, the contents of which are incorporated herein by reference.

As the white pigment, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

[Black Pigment]

The black pigment is not particularly limited, and a known black pigment can be used. Examples thereof include carbon black, titanium black, and graphite, and carbon black or titanium black is preferable and titanium black is more preferable. The titanium black is black particles containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black pigment include Color Index (C. I.) Pigment Black 1 and 7. It is preferable that the titanium black has a small primary particle diameter of the individual particles and has a small average primary particle diameter. Specifically, the average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraph Nos. 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.).

[Near-Infrared Absorbing Pigment]

The near-infrared absorbing pigment is preferably an organic pigment. In addition, the near-infrared absorbing pigment preferably has a maximum absorption wavelength in a wavelength range of more than 700 nm and 1,400 nm or less. In addition, the maximum absorption wavelength of the near-infrared absorbing pigment is preferably 1,200 nm or less, more preferably 1,000 nm or less, and still more preferably 950 nm or less. In addition, in the near-infrared absorbing pigment, A₅₅₀/Aₘₐₓ, which is a ratio of an absorbance A₅₅₀ at a wavelength of 550 nm to an absorbance Aₘₐₓ at the maximum absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. In a case where the ratio of the above-described absorbance is within the above-described range, a near-infrared absorbing pigment excellent in visible light transparency and near-infrared shielding properties can be obtained. In the present invention, the maximum absorption wavelength of the near-infrared absorbing pigment and values of absorbance at each wavelength are values obtained from an absorption spectrum of a film formed by using a curable composition including the near-infrared absorbing pigment.

The near-infrared absorbing pigment is not particularly limited, and examples thereof include a pyrrolopyrrole compound, a rylene compound, an oxonol compound, a squarylium compound, a cyanine compound, a croconium compound, a phthalocyanine compound, a naphthalocyanine compound, a pyrylium compound, an azurenium compound, an indigo compound, and a pyrromethene compound. Among these, at least one selected from the group consisting of a pyrrolopyrrole compound, a squarylium compound, a cyanine compound, a phthalocyanine compound, and a naphthalocyanine compound is preferable, a pyrrolopyrrole compound or a squarylium compound is more preferable, and a pyrrolopyrrole compound is particularly preferable.

[Transparent Pigment]

Examples of the transparent pigment include titanium oxide, zirconium oxide, silica, zinc oxide, barium sulfate, barium carbonate, alumina white, calcium carbonate, and calcium stearate.

Among these, those having a small adhesion are preferable, titanium oxide or zirconium oxide is more preferable, and zirconium oxide is still more preferable.

The content of the pigment in the total solid content of the curable composition is preferably 5 mass % or more, more preferably 10 mass % or more, still more preferably 20 mass % or more, even more preferably 30 mass % or more, particularly preferably 40 mass % or more, and most preferably 50 mass % or more. The upper limit is preferably 80 mass % or less, more preferably 70 mass % or less, and still more preferably 60 mass % or less.

[Pigment Derivative]

The curable composition according to the embodiment of the present invention may include a pigment derivative. In the present invention, it is also a preferred aspect to use a pigment and a pigment derivative in combination. Examples of the pigment derivative include a compound having a structure in which a part of a chromophore is substituted with an acid group, a basic group, or a phthalimidomethyl group. Examples of the chromophore constituting the pigment derivative include a quinoline-based skeleton, a benzimidazolone-based skeleton, a diketopyrrolopyrrole-based skeleton, an azo-based skeleton, a phthalocyanine-based skeleton, an anthraquinone-based skeleton, a quinacridone-based skeleton, a dioxazine-based skeleton, a perinone-based skeleton, a perylene-based skeleton, a thioindigo-based skeleton, an isoindoline-based skeleton, an isoindolinone-based skeleton, a quinophthalone-based skeleton, a threne-based skeleton, and a metal complex-based skeleton. Among these, a quinoline-based skeleton, a benzimidazolone-based skeleton, a diketopyrrolopyrrole-based skeleton, an azo-based skeleton, a quinophthalone-based skeleton, an isoindoline-based skeleton, or a phthalocyanine-based skeleton is preferable, and an azo-based skeleton or a benzimidazolone-based skeleton is more preferable. As the acid group included in the pigment derivative, a sulfo group or a carboxy group is preferable and a sulfo group is more preferable. As the basic group included in the pigment derivative, an amino group is preferable and a tertiary amino group is more preferable. Specific examples of the pigment derivative include compounds described in Examples described later, and compounds described in paragraph Nos. 0162 to 0183 of JP2011-252065A. The content of the pigment derivative is preferably 1 to 30 parts by mass and more preferably 3 to 20 parts by mass with respect to 100 parts by mass of the pigment. The pigment derivative may be used singly or in combination of two or more kinds thereof.

<Specific Resin>

The curable composition according to the embodiment of the present invention includes a resin (specific resin) which satisfies at least one of the following requirement 1 or the following requirement 2.

Requirement 1: the resin includes a constitutional unit having, in the same side chain, an anionic structure, a quaternary ammonium cationic structure which is ionically bonded to the anionic structure, and a radically polymerizable group.

Requirement 2: the resin includes a constitutional unit having, in a side chain, a quaternary ammonium cationic structure and a group to which a radically polymerizable group is linked.

The specific resin in the present invention may be a linear polymer compound, a star polymer compound, or a comb-shaped polymer compound. In addition, the form of the resin does not matter, and the resin may be a star polymer compound having a plurality of branch points and having a specific terminal group, which is described in JP2007-277514A.

The molecular weight (in a case of having a molecular weight distribution, weight-average molecular weight) of the side chain in the requirement 1 or the requirement 2 is preferably 50 to 1500 and more preferably 100 to 1000.

In addition, the specific resin is preferably an addition polymerization-type resin and more preferably an acrylic resin. In a case where the specific resin is an addition polymerization-type resin, examples of the specific resin include an aspect in which the side chain in the requirement 1 or the requirement 2 is a molecular chain bonded to a molecular chain formed by the addition polymerization, and is a molecular chain formed by a method other than addition polymerization.

In addition, the specific resin may be a dispersant. In the present specification, a resin which mainly is used for dispersing particles such as a pigment is also referred to as a dispersant. However, such applications of the specific resin are only exemplary, and the specific resin can also be used for other purposes in addition to such applications.

[Requirement 1]

In the above-described requirement 1, with regard to the constitutional unit having, in the same side chain, an anionic structure, a quaternary ammonium cationic structure which is ionically bonded to the anionic structure, and a radically polymerizable group, the anionic structure and the quaternary ammonium cationic structure may be ionically bonded or dissociated.

In addition, the side chain in the requirement 1 may have at least one anionic structure, quaternary ammonium cationic structure, and radically polymerizable group, respectively, or may have a plurality of at least one selected from the group consisting of an anionic structure, a quaternary ammonium cationic structure, and a radically polymerizable group in one side chain.

—Anionic Structure—

The anionic structure in the above-described requirement 1 is not particularly limited, and examples thereof include anions derived from an acid group, such as carboxylate anion, sulfonate anion, phosphonate anion, phosphinate anion, and phenolate anion. Among these, carboxylate anion is preferable.

In addition, the anionic structure in the requirement 1 may be directly connected to the main chain of the resin. For example, in a case where a carboxy group (side group) included in a constitutional unit derived from acrylic acid in an acrylic resin is anionized, the structure is an anionic structure directly connected to the main chain of the resin.

In addition, the distance (number of atoms) between the main chain and the quaternary ammonium cationic structure in a case where the anionic structure and the quaternary ammonium cationic structure are bonded to each other is preferably 4 to 70 elements, more preferably 4 to 50 elements, and still more preferably 4 to 30 elements. In the present specification, the distance between two structures in a polymer compound means the number of atoms of a linking group which connects the two structures at the shortest.

The distance between the quaternary ammonium cationic structure and the radically polymerizable group is preferably 2 to 30 elements, more preferably 3 to 20 elements, and still more preferably 4 to 15 elements.

The distance between the radically polymerizable group and the main chain is preferably 6 to 100 elements, more preferably 6 to 70 elements, and still more preferably 6 to 50 elements.

—Quaternary Ammonium Cationic Structure (Requirement 1)—

As the quaternary ammonium cationic structure in the above-described requirement 1, a structure in which at least three of four groups including four carbon atoms bonded to the nitrogen atom are hydrocarbon groups is preferable, and it is more preferable that at least three thereof are alkyl groups.

Among the above-described four groups including four carbon atoms bonded to the nitrogen atom, at least one thereof is a linking group including a bonding site with the radically polymerizable group. The above-described linking group is preferably a divalent to hexavalent linking group, more preferably a divalent to tetravalent linking group, and still more preferably a divalent or trivalent linking group. Examples of the above-described linking group include a group represented L^{A2} in Formula (A1) described later.

In addition, among the above-described four groups including four carbon atoms bonded to the nitrogen atom, it is preferable that only one thereof is the above-described linking group.

Among the above-described four groups including four carbon atoms, it is preferable that two or three thereof are alkyl groups having 1 to 4 carbon atoms, and it is preferable that two thereof are alkyl groups having 1 to 4 carbon atoms and one of the remaining two groups is a hydrocarbon group having 4 to 20 carbon atoms. In addition, the above-described two or three alkyl groups may be the same group or different groups.

As the above-described alkyl group having 1 to 4 carbon atoms, a methyl group or an ethyl group is preferable, and a methyl group is more preferable.

As the above-described hydrocarbon group having 4 to 20 carbon atoms, an alkyl group having 4 to 20 carbon atoms or a benzyl group is preferable.

In the above-described requirement 1, in a case where the side chain includes a plurality of quaternary ammonium cationic structures, the quaternary ammonium cationic structures may be bonded to each other through a linking group to form a ring structure. Examples of the ring structure formed include a ring structure represented by the following formulae. In the following formulae, * represents a bonding site with a linking group which includes a bonding site with the radically polymerizable group.

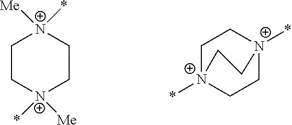 [SMILES: *[N+]1(C)CC[N+](*)(C)CC1 ; *[N+]12CC[N+](*)(CC1)CC2]

—Radically Polymerizable Group (Requirement 1)—

As the radically polymerizable group, a group having an ethylenically unsaturated group is preferable. Examples of the group having an ethylenically unsaturated group include a vinyl group, a (meth)allyl group, a (meth)acrylamide group, a (meth)acryloxy group, and a vinylphenyl group. Among these, from the viewpoint of reactivity, a (meth)acryloxy group or a vinylphenyl group is preferable, and a (meth)acryloxy group is more preferable.

[Requirement 2]

In the side chain in the above-described requirement 2, the quaternary ammonium cationic structure and the radically polymerizable group are linked to each other. That is, one side chain has both at least one quaternary ammonium cationic structure and at least one radically polymerizable group.

The side chain in the requirement 2 may have at least one quaternary ammonium cationic structure and radically polymerizable group, respectively, or may have a plurality of at least one selected from the group consisting of a quaternary ammonium cationic structure and a radically polymerizable group in one side chain.

In addition, the distance (number of atoms) between the main chain and the quaternary ammonium cationic structure is preferably 4 to 20 elements, more preferably 4 to 15 elements, and most preferably 4 to 10 elements.

The distance between the quaternary ammonium cationic structure and the polymerizable group is preferably 2 to 30 elements, more preferably 3 to 20 elements, and still more preferably 4 to 15 elements.

The distance between the polymerizable group and the main chain is preferably 6 to 50 elements, more preferably 6 to 30 elements, and still more preferably 6 to 20 elements.

Quaternary Ammonium Cationic Structure (Requirement 2)—As the quaternary ammonium cationic structure in the above-described requirement 2, a structure in which at least two of four groups including four carbon atoms bonded to the nitrogen atom are hydrocarbon groups is preferable, and it is more preferable that at least two thereof are alkyl groups.

As the above-described hydrocarbon group, an alkyl group or an aryl group is preferable, and an alkyl group or a phenyl group is more preferable.

As the above-described alkyl group, an alkyl group having 1 to 4 carbon atoms is preferable, a methyl group or an ethyl group is more preferable, and a methyl group is still more preferable. In addition, the above-described two alkyl groups may be the same group or different groups.

Among the above-described four groups including four carbon atoms bonded to the nitrogen atom, at least one thereof is a linking group including a bonding site with the radically polymerizable group, and at least one thereof is a linking group including a bonding site with the main chain in the specific resin.

The above-described linking group with the radically polymerizable group is preferably a divalent to hexavalent linking group, more preferably a divalent to tetravalent linking group, and still more preferably a divalent or trivalent linking group. Examples of the above-described linking group include a group represented L^{B2} in Formula (B1) described later.

The above-described linking group including a bonding site with the main chain in the specific resin is preferably a divalent linking group. Examples of the above-described linking group include a group represented L^{B1} in Formula (B1) described later.

The counter anion of the quaternary ammonium cationic structure in the requirement 2 may be present in the specific resin, or in other components included in the curable composition, but it is preferable to be present in the specific resin.

—Radically Polymerizable Group (Requirement 2)—As the radically polymerizable group, a group having an ethylenically unsaturated group is preferable. Examples of the group having an ethylenically unsaturated group include a vinyl group, a (meth)allyl group, a (meth)acrylamide group, a (meth)acryloxy group, and a vinylphenyl group. Among these, from the viewpoint of reactivity, a (meth)acryloxy group or a vinylphenyl group is preferable, and a (meth)acryloxy group is more preferable.

[Constitutional Unit Represented by Formula (A1) and Constitutional Unit Represented by Formula (B1)]

It is preferable that the above-described resin includes at least one of a constitutional unit represented by Formula (A1) or a constitutional unit represented by Formula (B1). A resin including the constitutional unit represented by Formula (A1) is a resin satisfying the requirement 1, and a resin including the constitutional unit represented by Formula (B1) is a resin satisfying the requirement 2.

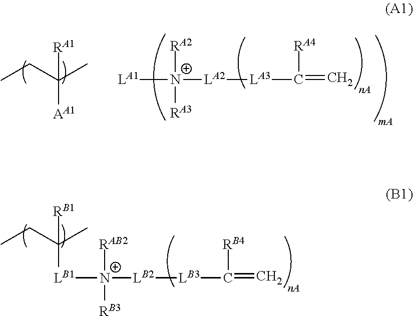

In Formula (A1), R^{A1} represents a hydrogen atom or an alkyl group,

A^{A1} represents a structure including a group in which a proton is separated from an acid group,

R^{A2} and R^{A3} each independently represent an alkyl group or an aralkyl group,

L^{A1} represents a monovalent substituent in a case where mA is 1, or represents a mA-valent linking group in a case where mA is 2 or more,

L^{A2} represents an (nA+1)-valent linking group,

L^{A3} represents a divalent linking group,

R^{A4} represents a hydrogen atom or an alkyl group,

nA represents an integer of 1 or more, and

mA represents an integer of 1 or more,

where in a case where mA is 2 or more, two or more R^{A2}'s, two or more R^{W3}'s, and two or more L^{A2}'s may be the same or different from each other,

in a case where mA is 2 or more, at least one of mA pieces of structures including a quaternary ammonium cation, which is selected from the group consisting of R^{A2} and R^{A3} included in one structure, may form a ring structure with at least one selected from the group consisting of R^{A2} and R^{A3} included in another structure,

in a case where at least one selected from the group consisting of nA and mA is 2 or more, two or more L^{A3}'s and two or more R^{A4}'s may be the same or different from each other, and

at least two of R^{A2}, R^{A3}, or L^{A2} may be bonded to each other to form a ring.

In Formula (B1), R^{B1} represents a hydrogen atom or an alkyl group,

L^{B1} represents a divalent linking group,

R^{B2} and R^{B3} each independently represent an alkyl group,

L^{B2} represents an (nB+1)-valent linking group,

L^{B3} represents a divalent linking group,

R^{B4} represents a hydrogen atom or an alkyl group, and

nB represents an integer of 1 or more,

where in a case where nB is 2 or more, two or more L^{B3}'s and two or more R^{B4}'s may be the same or different from each other, and

at least two of R^{B2}, R^{B3}, L^{B1}, or L^{B2} may be bonded to each other to form a ring.

In Formula (A1), R^{A1} is preferably a hydrogen atom or an alkyl group having 1 to 4 carbon atoms and more preferably a hydrogen atom or a methyl group.

In Formula (A1), A^{A1} represents a structure a structure including a group in which a proton is separated from an acid group, and examples of the acid group include a carboxy group, a sulfo group, a phosphoric acid group, a phosphonic acid group, and a phenolic hydroxy group, and a carboxy group is preferable. The number of acid groups included in A^{A1} may be one or plural, and it is preferable to be one. In addition, the acid group in A^{A1} may be bonded to a carbon atom to which R^{A1} in Formula (A1) is bonded directly or through a linking group. As the above-described linking group, a hydrocarbon group, an ether bond (—O—), an ester bond (—COO—), an amide bond (—CONH—), or a group in which two or more of these are bonded is preferable. Examples of the above-described hydrocarbon group include a divalent hydrocarbon group, and an alkylene group or an arylene group is preferable, and an alkylene group having 1 to 20 carbon atoms or a phenylene group is more preferable. In addition, in the present specification, unless otherwise specified, a hydrogen atom in the amide bond may be replaced with a known substituent such as an alkyl group and an aryl group.

In Formula (A1), R^{A2} and R^{A3} are each independently preferably an alkyl group, more preferably an alkyl group having 1 to 10 carbon atoms, more preferably an alkyl group having 1 to 4 carbon atoms, still more preferably a methyl group or an ethyl group, and particularly preferably a methyl group.

In Formula (A1), in a case where R^{A2} or R^{A3} is an aralkyl group, an aralkyl group having 7 to 22 carbon atoms is preferable, an aralkyl group having 7 to 10 carbon atoms is more preferable, and a benzyl group is still more preferable.

In Formula (A1), in a case where mA is 2 or more, L^{A1} is preferably an mA-valent hydrocarbon group, and more preferably a saturated aliphatic hydrocarbon, an aromatic hydrocarbon, or a group that mA hydrogen atoms are removed from or a structure in which two or more of these are bonded. In a case where mA is 1, L^{A1} is preferably an alkyl group, an aryl group, or an aralkyl group, and more preferably an alkyl group having 4 to 20 carbon atoms or a benzyl group.

In Formula (A1), L^{A2} is preferably any one of groups represented by Formulae (C1-1) to (C4-1) described later.

In Formula (A1), L^{A3} is preferably an ether bond (—O—), an ester bond (—COO—), an amide bond (—NHCO—), an alkylene group, or an arylene group, and more preferably an ester bond or a phenylene group.

In Formula (A1), R^{A4} is preferably a hydrogen atom or an alkyl group having 1 to 4 carbon atoms and more preferably a hydrogen atom or a methyl group.

In Formula (A1), nA is preferably 1 to 10, more preferably 1 to 4, still more preferably 1 or 2, and particularly preferably 1.

In Formula (A1), mA is preferably 1 to 10, more preferably 1 to 4, and still more preferably 1 to 3.

In Formula (B1), R^{B1} is preferably a hydrogen atom or an alkyl group having 1 to 4 carbon atoms and more preferably a hydrogen atom or a methyl group.

In Formula (B1), L^{B1} represents a divalent linking group, and a hydrocarbon group, an ether bond (—O—), an ester bond (—COO—), an amide bond (—CONH—), or a group in which two or more of these are bonded is preferable. Examples of the above-described hydrocarbon group include a divalent hydrocarbon group, and an alkylene group or an arylene group is preferable, and an alkylene group having 1 to 20 carbon atoms or a phenylene group is more preferable.

In Formula (B1), R^{B2} and R^{B3} are each independently preferably an alkyl group having 1 to 10 carbon atoms, more preferably an alkyl group having 1 to 4 carbon atoms, still more preferably a methyl group or an ethyl group, and particularly preferably a methyl group. In Formula (B1), L^{B2} is preferably any one of groups represented by Formulae (C1-1) to (C4-1) described later.

In Formula (B1), L^{B3} is preferably an ether bond (—O—), an ester bond (—COO—), an amide bond (—NHCO—), an alkylene group, or an arylene group, and more preferably an ester bond or a phenylene group.

In Formula (B1), nB is preferably 1 to 10, more preferably 1 to 4, still more preferably 1 or 2, and particularly preferably 1.

L^{A2} in Formula (A1) or L^{B2} in Formula (B1) is preferably any one of groups represented by Formulae (C1-1) to (C4-1).

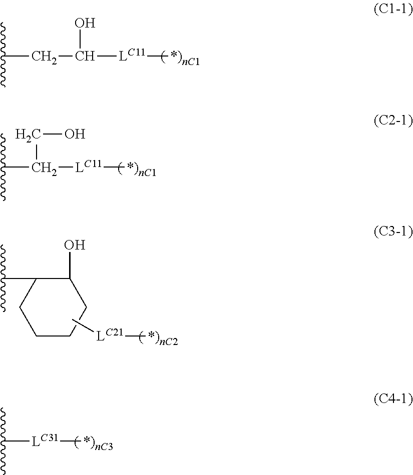

In Formulae (C1-1) to (C4-1), L^{C11} represents an (nC1+1)-valent linking group, L^{C21} represents an (nC2+1)-valent linking group, L^{C31} represents an (nC3+1)-valent hydrocarbon group, nC1 to nC3 each independently represent an integer of 1 or more, a wavy line part represents a bonding site with the nitrogen atom in Formula (A1) or Formula (B1), and * represents a bonding site with the carbon atom to which R^{A4} in Formula (A1) is bonded or the carbon atom to which R^{B4} in Formula (B1) is bonded.

In addition, in Formula (C3-1), it is sufficient that L^{C21} is bonded to any carbon atom of the cyclohexane ring in Formula (C3-1).

In Formula (C1-1) or Formula (C2-1), L^{C11} is preferably an (nC1+1)-valent hydrocarbon group, an ether bond, an ester bond, or a group in which two or more of these are bonded, and more preferably a saturated aliphatic hydrocarbon, an aromatic hydrocarbon, an ether bond, an ester bond, or a group that nC1+1 hydrogen atoms are removed from a structure in which two or more of these are bonded.

In Formula (C1-1) or Formula (C2-1), nC1 is preferably 1 to 10, preferably 1 to 4, and more preferably 1 or 2.

In Formula (C3-1), L^{C21} is preferably an (nC2+1)-valent hydrocarbon group, an ether bond, an ester bond, or a group in which two or more of these are bonded, and more preferably a saturated aliphatic hydrocarbon, an aromatic hydrocarbon, an ether bond, an ester bond, or a group that nC2+1 hydrogen atoms are removed from a structure in which two or more of these are bonded.

In Formula (C3-1), nC2 is preferably 1 to 10, preferably 1 to 4, and more preferably 1 or 2.

In Formula (C4-1), L^{C31} is preferably a saturated aliphatic hydrocarbon, an aromatic hydrocarbon, or a group that nC3+1 hydrogen atoms are removed from or a structure in which two or more of these are bonded.

In Formula (C4-1), nC3 is preferably 1 to 10, preferably 1 to 4, and more preferably 1 or 2.

In Formula (A1), in a case where L^{A2} is a group represented by Formula (C1-1), Formula (C2-1), or Formula (C3-1), L^{A3} is preferably an ester bond.

In Formula (A1), in a case where L^{A2} is a group represented by Formula (C4-1), L^{A3} is preferably a phenylene group.

In Formula (B1), in a case where L^{B2} is a group represented by Formula (C1-1), Formula (C2-1), or Formula (C3-1), L^{B3} is preferably an ester bond.

In Formula (B1), in a case where L^{B2} is a group represented by Formula (C4-1), L^{B3} is preferably a phenylene group.

In a case where the specific resin includes at least one of the constitutional unit represented by Formula (A1) or the constitutional unit represented by Formula (B1), it is preferable that nA in Formula (A1) is 1 and a bond between L^{A2} and L^{A3} represents any one of groups represented by Formulae (C1) to (C4), or nB in Formula (1) is 1 and L^{B2} and L^{B3} represent any one of groups represented by Formulae (C1) to (C4).

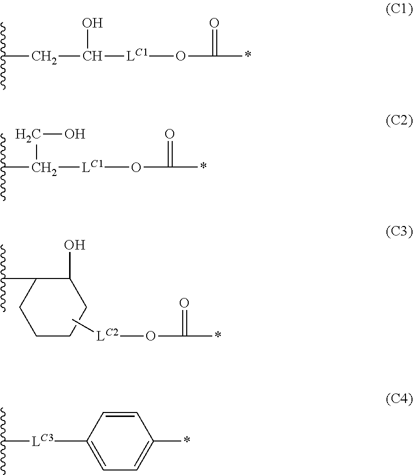

In Formulae (C1) to (C4), L^{C1}, L^{C2}, and L^{C3} each independently represent a single bond or a divalent linking group,

a wavy line part represents a bonding site with a nitrogen atom in Formula (A1) or Formula (B1), and

* represents a bonding site with a carbon atom to which R^{A4} in Formula (A1) is bonded or a carbon atom to which R^{B4} in Formula (B1) is bonded.

In addition, in Formula (C3), it is sufficient that L^{C2} is bonded to any carbon atom of the cyclohexane ring in Formula (C3).

In Formula (C1) or Formula (C2), L^{C1} is preferably a divalent hydrocarbon group, an ether bond, an ester bond, or a group in which two or more of these are bonded, more preferably an alkylene group, an arylene group, an ether bond, an ester bond, or a group in which two or more of these are bonded, and more preferably an alkylene group having 1 to 20 carbon atoms, a phenylene group, an ether bond, or a group in which two or more of these are bonded.

In Formula (C3), L^{C2} is preferably a divalent hydrocarbon group, an ether bond, an ester bond, or a group in which two or more of these are bonded, more preferably an alkylene group, an arylene group, an ether bond, an ester bond, or a group in which two or more of these are bonded, and more preferably an alkylene group having 1 to 20 carbon atoms, a phenylene group, an ether bond, or a group in which two or more of these are bonded.

In Formula (C4), L^{C3} is preferably a divalent hydrocarbon group, an ether bond, an ester bond, or a group in which two or more of these are bonded, more preferably an alkylene group, an arylene group, an ether bond, an ester bond, or a group in which two or more of these are bonded, and more preferably an alkylene group having 1 to 20 carbon atoms.

Preferred examples of the constitutional unit represented by Formula (A1) include the following structures, but the constitutional unit represented by Formula (A1) is not limited thereto. In the following specific examples, n represents an integer of 1 or more.

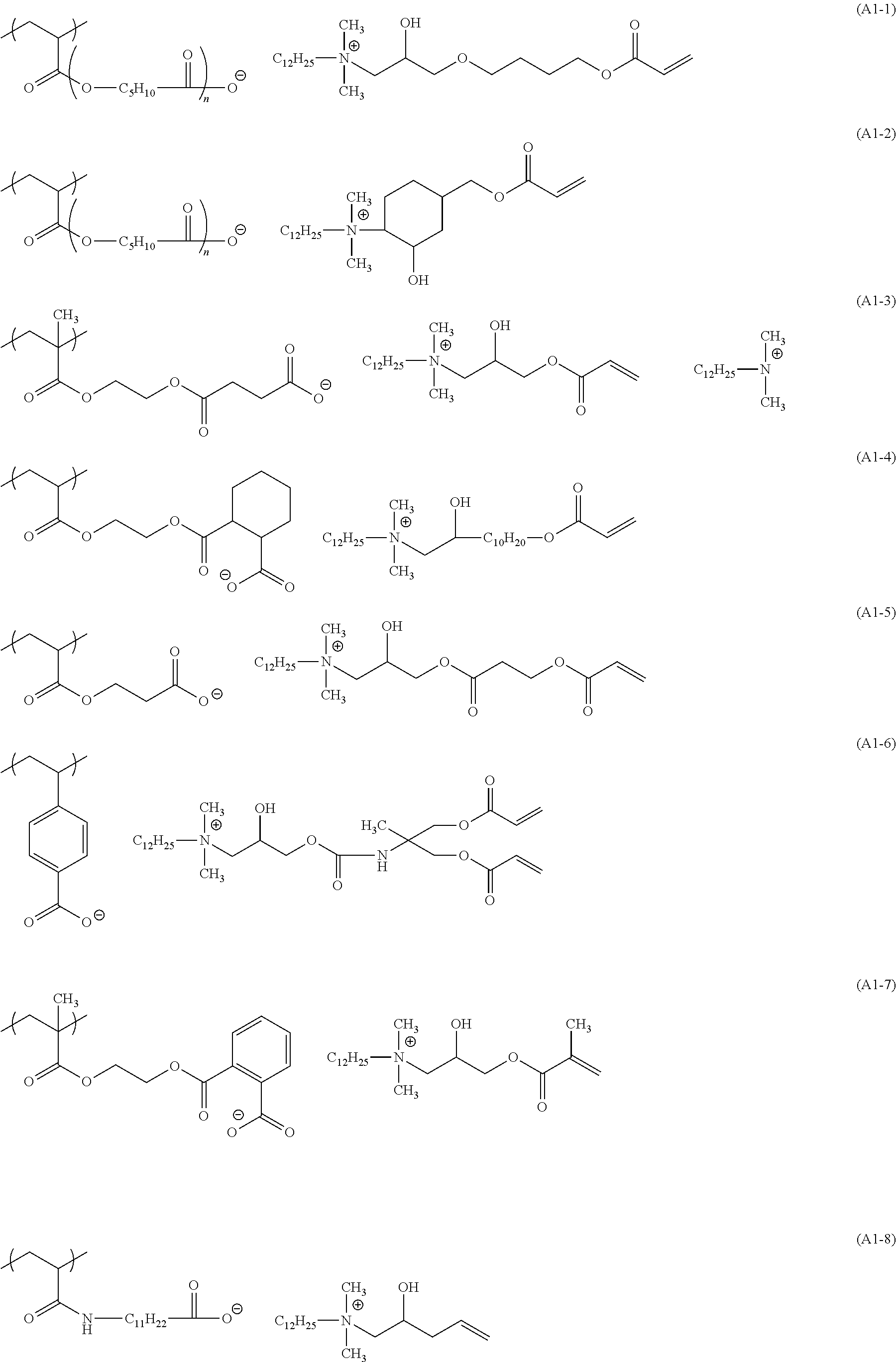

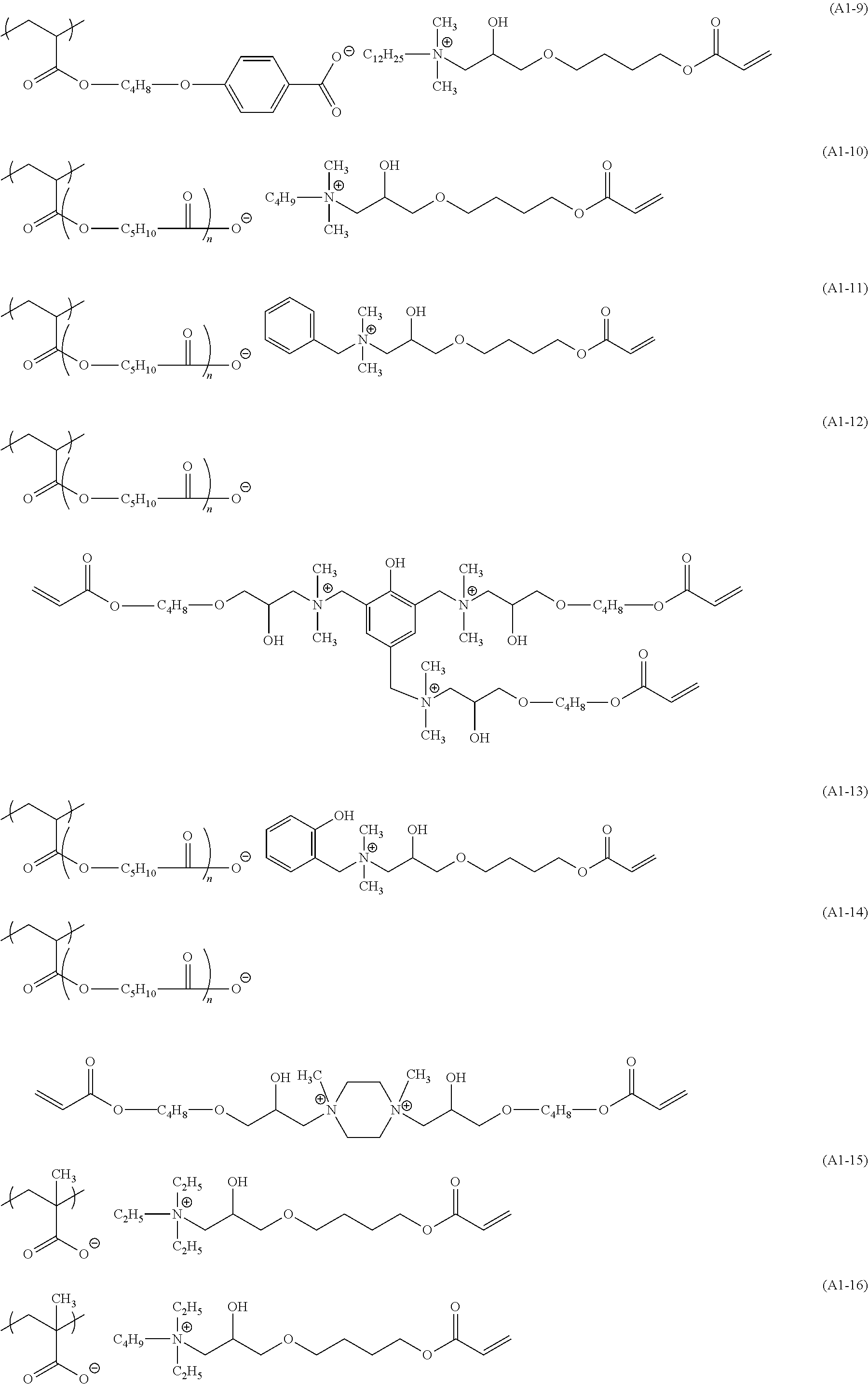

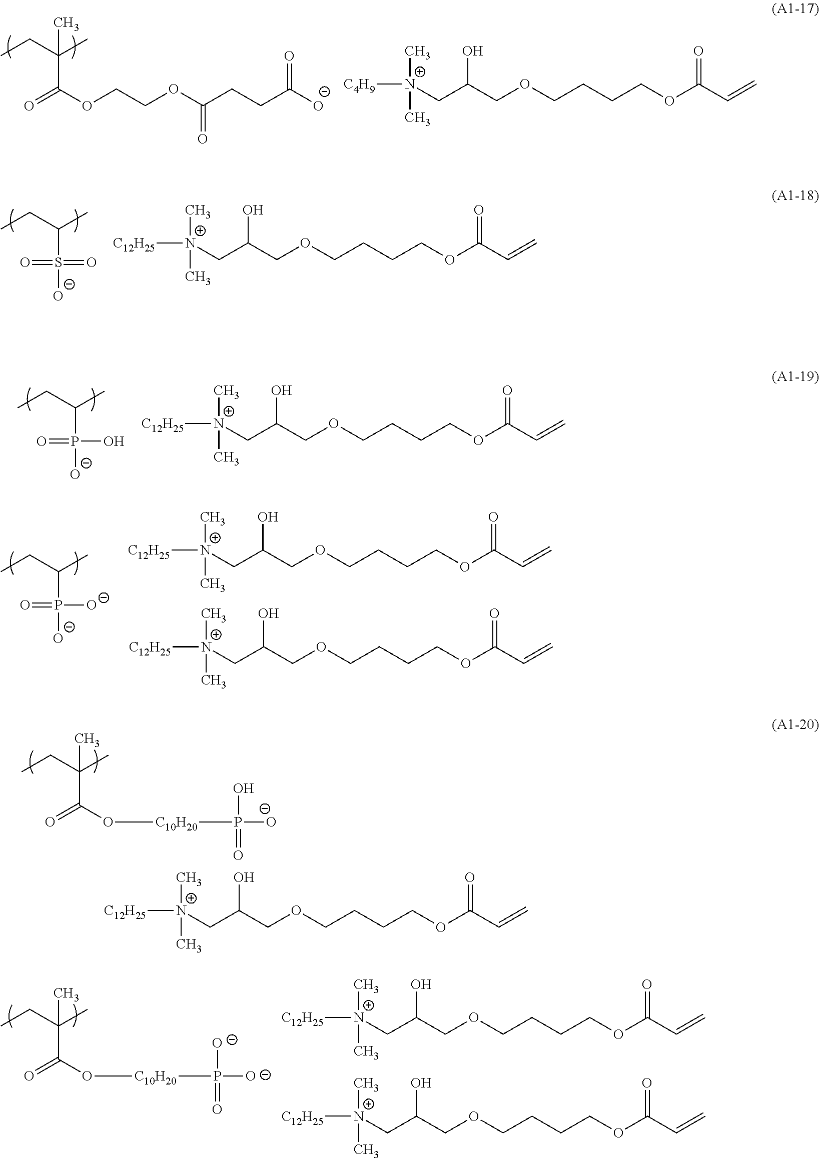

In addition, examples of the structure of the cation portion including the quaternary ammonium cationic structure and the radically polymerizable group include the following structure.

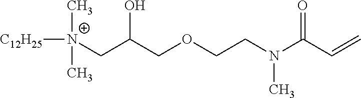

Preferred examples of the constitutional unit represented by Formula (B1) include the following structures, and it is needless to say that the constitutional unit represented by Formula (B1) is not limited thereto.

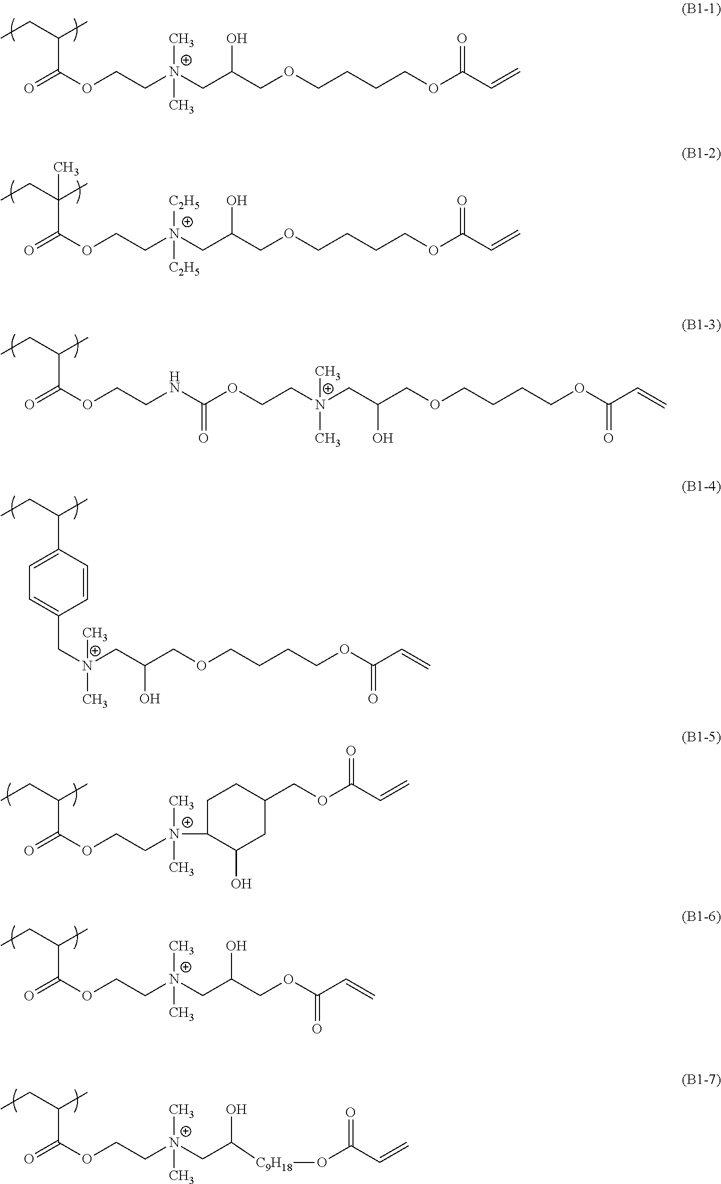

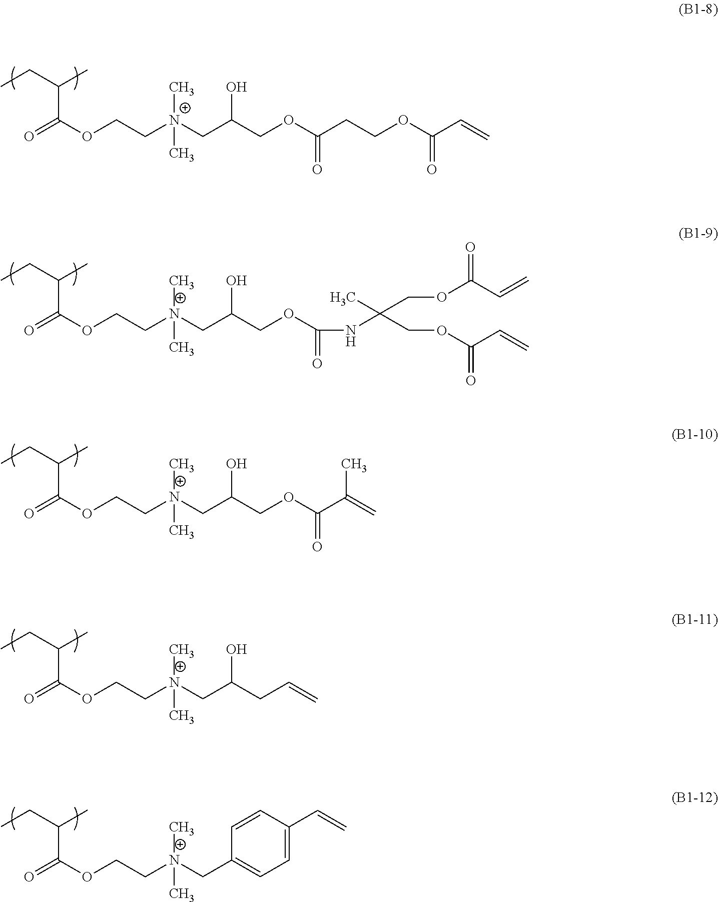

In addition, in these structures, at least a part of the constitutional unit having the quaternary ammonium cationic structure may be a structure represented by Formula (A1-1-1′) with respect to Formula (A1-1-1) (which is a partial structure in Formula (A-1)).

Specifically the structure represented by Formula (C1), which is included in the constitutional unit having a quaternary ammonium cationic structure, may be a structure represented by Formula (C2). As an example, the structure such as Formula (A1-1-1′) exists as a structural isomer in the reaction of an amine compound with a compound having an epoxy group and an acryloyl group.

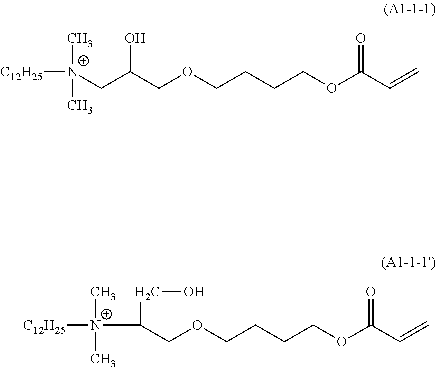

The specific resin may have one kind of the constitutional unit represented by Formula (A1), or may have two or more kinds thereof.

In addition, the specific resin may have one kind of the constitutional unit represented by Formula (B1), or may have two or more kinds thereof.

The content (in a case of including two or more kinds, total content) of the constitutional unit represented by Formula (A1) and the constitutional unit represented by Formula (B1) is preferably 1 mass % to 60 mass %, more preferably 5 mass % to 40 mass %, and still more preferably 5 to 20 mass % with respect to the total mass of the specific resin.

[Constitutional Unit D]

It is also preferable that the specific resin has a radically polymerizable group and further includes a constitutional unit D which is different from the constitutional unit represented by Formula (A1) and the constitutional unit represented by Formula (B1).

As the radically polymerizable group in the constitutional unit D, a group having an ethylenically unsaturated group is preferable. Examples of the group having an ethylenically unsaturated group include a vinyl group, a (meth)allyl group, a (meth)acrylamide group, a (meth)acryloxy group, and a vinylphenyl group. Among these, from the viewpoint of reactivity, a (meth)acryloxy group or a vinylphenyl group is preferable, and a (meth)acryloxy group is more preferable.

[Constitutional Unit Represented by Formula (D1)]

The specific resin preferably further includes a constitutional unit represented by Formula (D1) as the constitutional unit D.

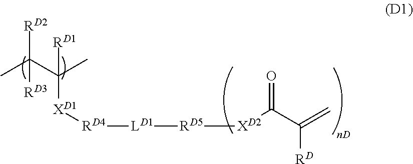

In Formula (D1), R^{D1} to R^{D3} each independently represent a hydrogen atom or an alkyl group,

X^{D1} represents —COO—, —CONR^{D6}—, or an arylene group, where R^{D6} represents a hydrogen atom, an alkyl group, or an aryl group,

R^{D4} represents a divalent linking group,

L^{D1} represents a group represented by Formula (D2), Formula (D3), or Formula (D3′),

R^{D5} represents an (n+1)-valent linking group,

X^{D2} represents an oxygen atom or NR^{D7}—, where R^{D7} represents a hydrogen atom, an alkyl group, or an aryl group,

R^{D} represents a hydrogen atom or a methyl group, and

nD represents an integer of 1 or more,

where in a case where nD is 2 or more, two or more X^{D2}'s and two or more R^{D}'S may be the same or different from each other.

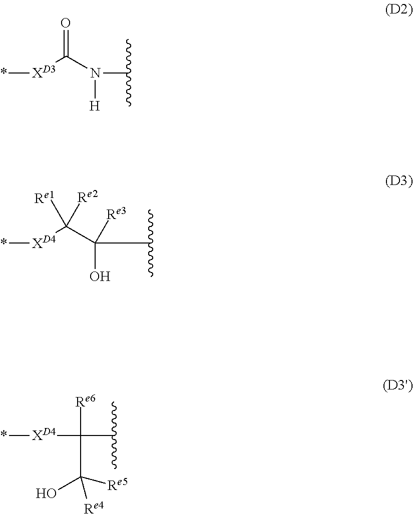

In Formulae (D2), (D3), and (D3′), X^{D3} represents an oxygen atom or —NH—,

X^{D4} represents an oxygen atom or —COO—,

R^{e1} to R^{e3} each independently represent a hydrogen atom or an alkyl group, where at least two of R^{e1} to R^{e3} may be bonded to each other to form a ring structure,

X^{D5} represents an oxygen atom or —COO—,

R^{e4} to R^{e6} each independently represent a hydrogen atom or an alkyl group, where at least two of R^{e4} to R^{e6} may be bonded to each other to form a ring structure, and

* and a wavy line part represent a bonding position with other structures.

By using a specific resin including the above-described constitutional unit represented by Formula (D1) in the curable composition, deep portion curability of a film to be obtained is likely to be excellent.

The reason why the above-described effect is obtained is not clear, but presumed as follows.

In a resin having the constitutional unit represented by Formula (D1), since the constitutional unit has, in the side chain, the group represented by Formula (D2), Formula (D3), or Formula (D3′), which is a polar group, it is considered that, in the composition, the width of movement of the (meth)acryloyl group is increased, and the reactivity is excellent. In addition, since the constitutional unit has the group represented by Formula (D2), Formula (D3), or Formula (D3′), dispersibility is excellent due to that aggregation of the resins is suppressed, and the reactivity of the (meth)acryloyl group is more improved. Therefore, it is considered that the curable composition having excellent deep portion curability can be easily obtained.

In addition, by including the constitutional unit represented by Formula (D1), a highly reactive (meth)acryloyl group can be introduced at a position away from the main chain through the group represented by Formula (D2), Formula (D3), or Formula (D3′). As a result, the (meth)acryloyl groups in the resin molecule do not react with each other, and the probability of reacting with the (meth)acryloyl group of other resin molecules or with other crosslinking components (for example, the polymerizable compound and the like) in the composition is increased. Therefore, it is considered that the crosslinking reaction proceeds efficiently in a composition having a pigment concentration, and the deep portion curability and formation of a pattern shape can be improved.

In addition, since the constitutional unit represented by Formula (D1) has a relatively long side chain structure and has the polar group represented by Formula (D2), Formula (D3), or Formula (D3′) in the side chain, it is considered that adsorbability to the pigment is enhanced, and three-dimensional resilience which suppresses aggregation of pigment particles exhibits. As a result, it is considered that the dispersibility of the pigment is improved.

Furthermore, in a case where the specific resin includes a constitutional unit represented by Formula (D4) described later, it is considered that carboxylic acid serving as an adsorptive group can be introduced at a position away from the main chain to enhance pigment adsorbability and improve dispersion stability.

In addition, by introducing the constitutional unit represented by Formula (D1), it is considered that substrate adhesiveness, formation of a pattern shape, and deep portion curability described above are also excellent, and further, by having the constitutional unit represented by Formula (D4) described later, it is considered that the dispersion stability of the curable composition is improved.

From the viewpoint of deep portion curability, R^{D1} to R^{D3} in Formula (D1) are each independently preferably a hydrogen atom or a methyl group, and more preferably a hydrogen atom. In addition, from the viewpoint of deep portion curability, it is still more preferable that R^{D1} is a hydrogen atom or a methyl group, and R^{D2} and R^{D3} are hydrogen atoms. In a case where L^{D1} is the group represented by Formula (D2), R^{D1} is still more preferably a methyl group, and in a case where L^{D1} is the group represented by Formula (D3) or Formula (D3′), R^{D1} is still more preferably a hydrogen atom.

From the viewpoint of deep portion curability, X^{D1} in Formula (D1) is preferably —COO— or —CONR^{D6}— and more preferably —COO—. In a case where X^{D1} is an arylene group, it is preferable to be a divalent aromatic hydrocarbon group having 6 to 20 carbon atoms, more preferable to be a phenylene group or a naphthylene group, and still more preferable to be a phenylene group. In a case where X^{D1} is —COO—, it is preferable that the carbon atom in —COO— is bonded to the carbon atom to which R^{D1} in Formula (D1) is bonded. In a case where X^{D1} is —CONR^{D6}—, it is preferable that the carbon atom in —CONR^{D6}— is bonded to the carbon atom to which R^{D1} in Formula (D1) is bonded.

R^{D6} is preferably a hydrogen atom or an alkyl group and more preferably a hydrogen atom.

From the viewpoint of deep portion curability, R^{D4} in Formula (D1) is preferably a hydrocarbon group or a group in which two or more hydrocarbon groups are bonded to one or more structures selected from the group consisting of ether bonds and ester bonds, and more preferably a hydrocarbon group or a group in which two or more hydrocarbon groups are bonded to one or more ester bonds.

In addition, R^{D4} in Formula (D1) is preferably a group in which two or more groups selected from the group consisting of an alkylene group, an ether group, a carbonyl group, a phenylene group, a cycloalkylene group, and an ester bond are bonded, and more preferably a group in which two or more groups selected from the group consisting of an alkylene group, an ether group, and an ester bond are bonded.

In addition, from the viewpoint of deep portion curability, R^{D4} in Formula (D1) is preferably a group having a total of 2 to 60 atoms, more preferably a group having a total of 2 to 50 atoms, and particularly preferably a group having a total of 2 to 40 atoms. Furthermore, from the viewpoint of deep portion curability, it is particularly preferable that R^{D4} is a group selected from the group consisting of a hydrocarbon group, an alkyleneoxy group, an alkylenecarbonyloxy group, and any group represented by the following structures, and R^{D5} is an alkylene group or a group in which two or more alkylene groups are bonded to one or more structures selected from the group consisting of ether bonds and ester bonds.

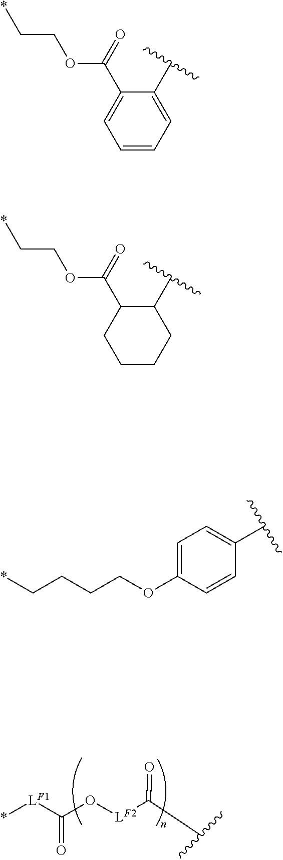

In the formulae, * and a wavy line part represent a bonding position with other structures, and it is preferable that * represents a bonding site with X^{D1} in Formula (D1) and a wavy line part represents a bonding position with L^{D1}

In addition, in the formulae, L^{F1} and L^{F2} each independently represent a hydrocarbon group, and n represents an integer of 0 or more.

An aspect in which L^{F1} and L^{F2} are each independently an alkylene group having 2 to 20 carbon atoms is also preferable.

An aspect in which L^{F1} and L^{F2} are the same groups is also preferable.

An aspect in which n is 0 to 100 is also preferable.

From the viewpoint of deep portion curability, nD in Formula (D1) is preferably an integer of 1 to 6, more preferably an integer of 1 to 3, and still more preferably 1.

From the viewpoint of deep portion curability, R^{D5} in Formula (D1) is preferably a divalent linking group, more preferably an alkylene group or a group in which two or more alkylene groups are bonded to one or more structures selected from the group consisting of ether bonds and ester bonds, still more preferably an alkyleneoxyalkylene group, and particularly preferably a methyleneoxy-n-butylene group.

In addition, from the viewpoint of deep portion curability, R^{D5} in Formula (D1) is preferably a group having a total of 2 to 40 atoms, more preferably a group having a total of 2 to 30 atoms, and particularly preferably a group having a total of 2 to 20 atoms. From the viewpoint of deep portion curability, X^{D2} in Formula (D1) is preferably an oxygen atom.

R^{D7} is preferably a hydrogen atom or an alkyl group and more preferably a hydrogen atom.

R^{D} is preferably a hydrogen atom.

From the viewpoint of dispersibility, L^{D1} in Formula (D1) is preferably the group represented by Formula (D2), and from the viewpoint of formation of a pattern shape and suppression of development residue, L^{D1} in Formula (D1) is preferably the group represented by Formula (D3) or Formula (D3′).

In Formulae (D2), (D3), and (D3′), it is preferable that * is a bonding site with R^{D4} and a wavy line part is a bonding site with R^{D5}.

From the viewpoint of deep portion curability and dispersibility, X^{D3} in Formula (D2) is preferably an oxygen atom.

In addition, in a case where L^{D1} is the group represented by Formula (D2), from the viewpoint of deep portion curability and dispersibility, it is particularly preferable that R^{D4} is a group selected from the group consisting of an ethylene group, an n-propylene group, an isopropylene group, an n-butylene group, and an isobutylene group, and R^{D5} is an ethylene group.

From the viewpoint of deep portion curability, formation of a pattern shape, and suppression of development residue, X^{D4} in Formula (D3) or Formula (D3′) is preferably —COO—. In a case where X^{D4} is —COO—, it is preferable that the oxygen atom in —COO— is bonded to the carbon atom to which R^{e1} is bonded.

From the viewpoint of deep portion curability, formation of a pattern shape, and suppression of development residue, R^{e1} to R^{e3} in Formula (D3) or Formula (D3′) are preferably hydrogen atoms.

In addition, in a case where L^{D1} is the group represented by Formula (D3) of Formula (D3′), from the viewpoint of deep portion curability, formation of a pattern shape, and suppression of development residue, it is particularly preferable that R^{D4} is a hydrocarbon group, a group in which two or more hydrocarbon groups are bonded to one or more structures selected from the group consisting of ether bonds and ester bonds, or any group represented by the following structures, and R^{D5} is an alkylene group or a group in which two or more alkylene groups are bonded to one or more structures selected from the group consisting of ether bonds and ester bonds.

Preferred examples of the group represented by Formula (D2) include a group represented by Formula (D2-1) or Formula (D2-2).

In addition, preferred examples of the group represented by Formula (D3) include a group represented by Formula (D3-1) or Formula (D3-2).

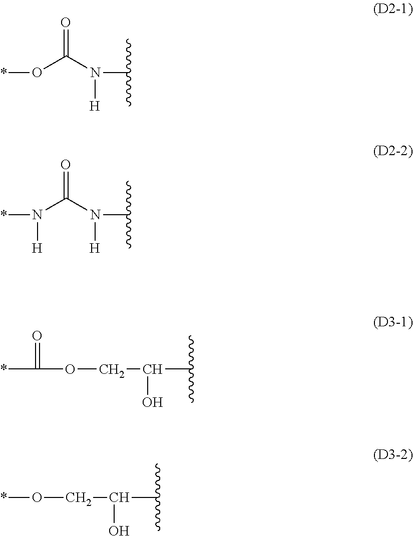 [SMILES: *NC(=O)O* ; *NC(=O)N* ; *C(=O)OCC(*)O ; *OCC(*)O]

* and the wavy line part in Formula (D2-1), Formula (D2-2), Formula (D3-1), and Formula (D3-2) are the same as * and the wavy line part in Formula (D2) of Formula (D3), and the preferred aspects thereof are also the same.

In addition, in the structures of Formula (D3-1) and Formula (D3-2), at least a part of the structures may be replaced with a structure represented by, with regard to Formula (D3-1), Formula (D3-1′), or with regard to Formula (D3-2), Formula (D3-2′). As an example, the structure such as Formula (D3-1′) exists as a structural isomer in the reaction of a carboxylic acid compound with a compound having an epoxy group and an acryloyl group. As an example, the structure such as Formula (D3-2′) exists as a structural isomer in the reaction of a phenol compound with a compound having an epoxy group and an acryloyl group.

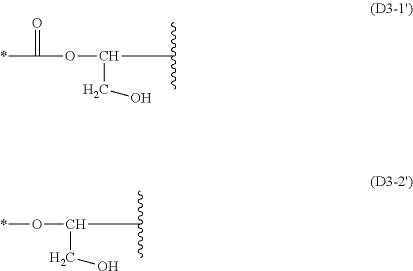 [SMILES: *C(=O)OC(*)CO ; *OC(*)CO]

Preferred examples of the constitutional unit represented by Formula (D1) include the following structures, and it is needless to say that the constitutional unit represented by Formula (D1) is not limited thereto. In the following specific examples, m represents an integer of 2 or more, and n represents an integer of 1 or more.

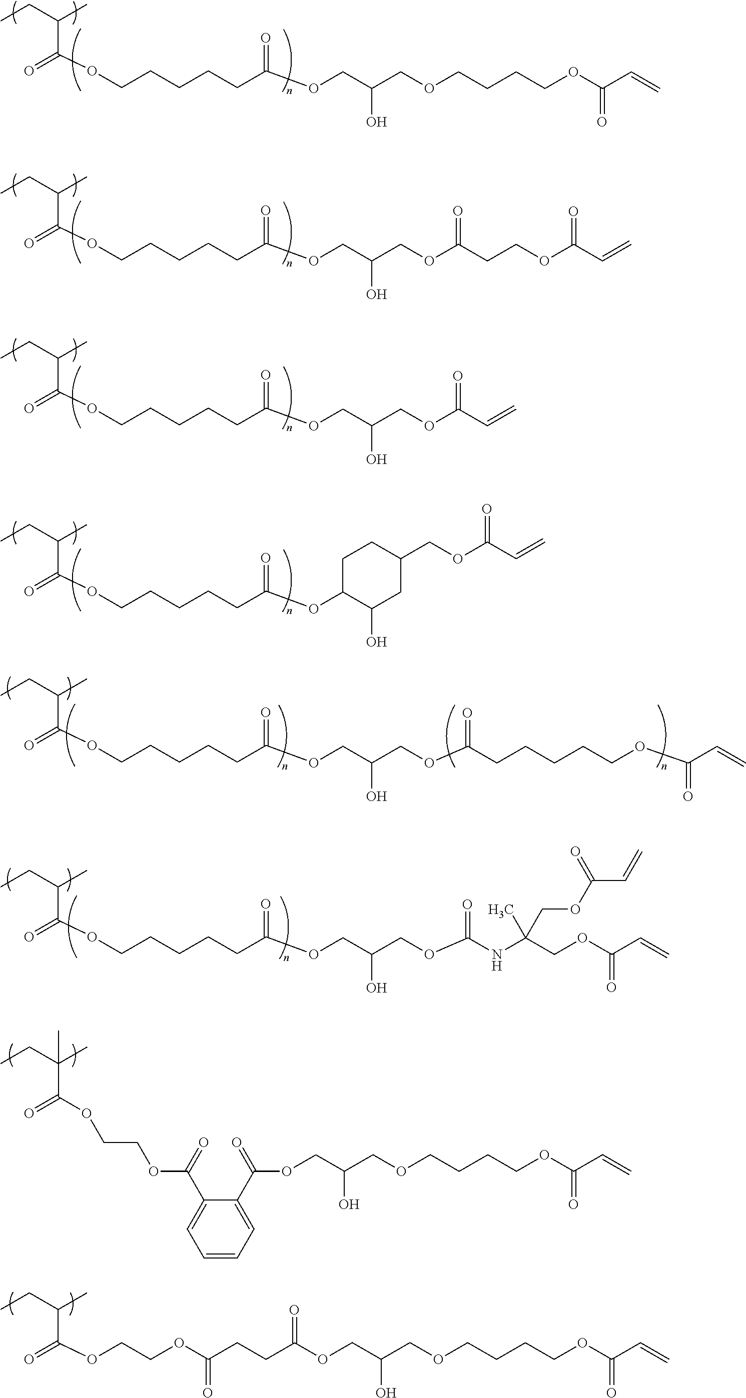

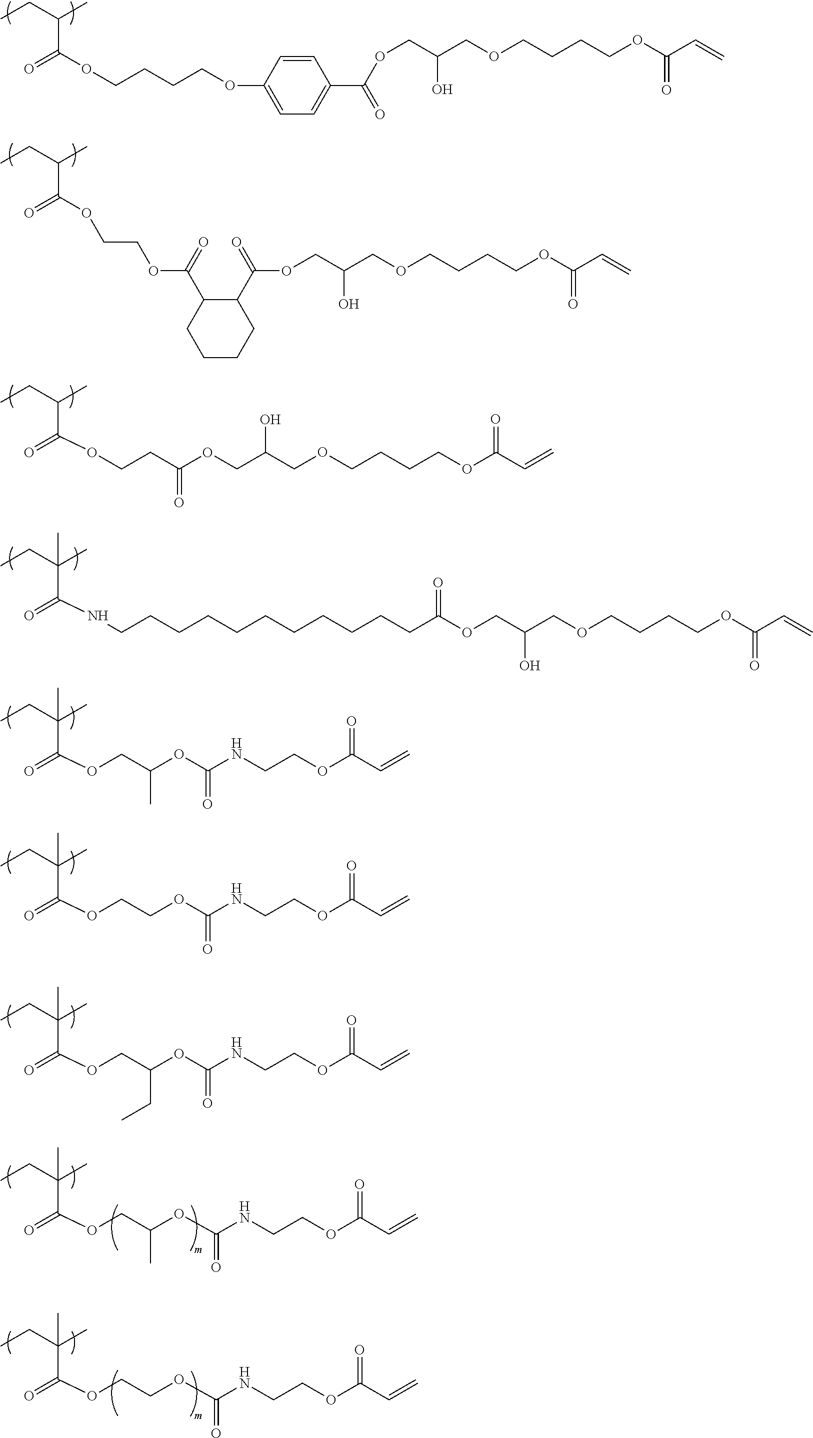

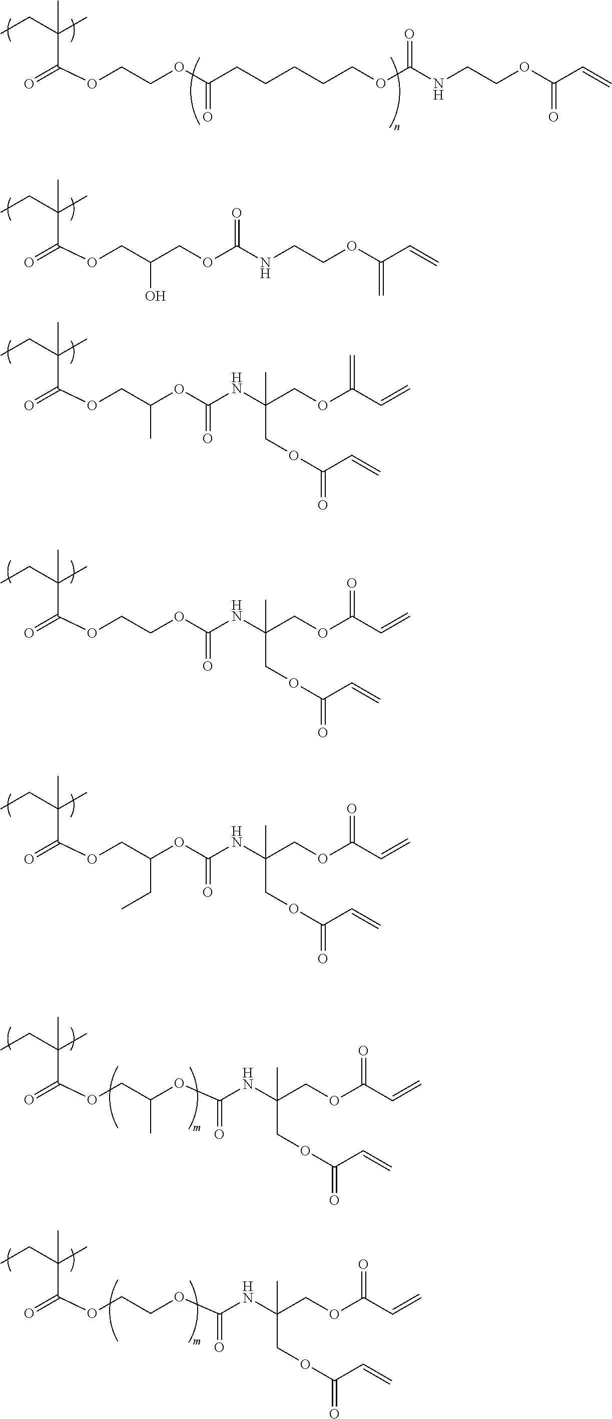

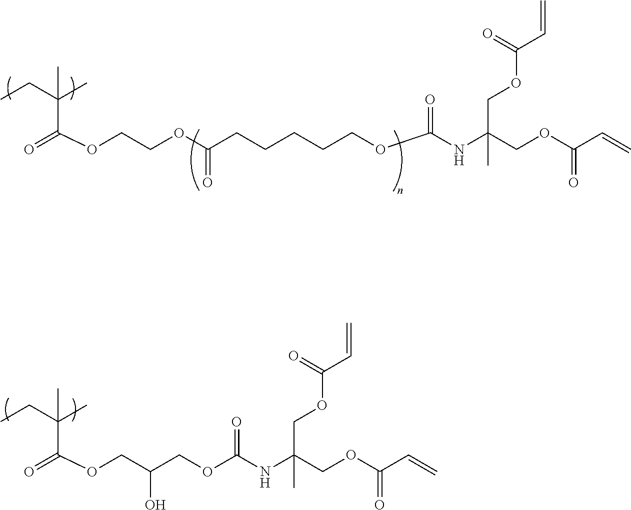

The specific resin may have one kind of the constitutional unit represented by Formula (D1), or may have two or more kinds thereof.

From the viewpoint of developability, formation of a pattern shape, dispersion stability, and deep portion curability, the content of the constitutional unit represented by Formula (D1) is preferably 1 to 80 mass %, more preferably 1 to 70 mass %, and particularly preferably 1 to 60 mass % with respect to the total mass of the specific resin.

[Constitutional Unit Represented by Formula (D4)]

From the viewpoint of dispersion stability and developability, the specific resin preferably further has a constitutional unit represented by Formula (D4).

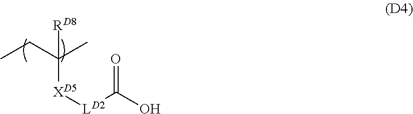

In Formula (D4), R^{D8} represents a hydrogen atom or an alkyl group, X^{D5} represents —COO—, —CONR^{B}—, or an arylene group, where R^{B} represents a hydrogen atom, an alkyl group, or an aryl group, and L^{D2} represents an aliphatic hydrocarbon group having 1 to 10 carbon atoms, an aromatic hydrocarbon group having 6 to 20 carbon atoms, or a group in which two or more groups selected from the group consisting of aliphatic hydrocarbon groups having 1 to 10 carbon atoms and aromatic hydrocarbon groups having 6 to 20 carbon atoms are bonded to one or more groups selected from the group consisting of ether bonds and ester bonds. Furthermore, in a case where X^{D5} is an arylene group, L^{D2} may be a single bond.

R^{D8} in Formula (D4) is preferably a hydrogen atom.

From the viewpoint of dispersion stability, X^{D5} in Formula (D4) is preferably —COO— or —CONR^{B}— and more preferably —COO—. In a case where X^{D5} is —COO—, it is preferable that the carbon atom in —COO— is bonded to the carbon atom to which R^{D8} in Formula (D4) is bonded. In a case where X^{D5} is —CONR^{DB}—, it is preferable that the carbon atom in —CONR^{DB}— is bonded to the carbon atom to which R^{D8} in Formula (D4) is bonded.

R^{B} is preferably a hydrogen atom or an alkyl group and more preferably a hydrogen atom.

From the viewpoint of dispersion stability, L^{D2} in Formula (D4) is preferably an aliphatic hydrocarbon group having 1 to 10 carbon atoms, or a group in which two or more aliphatic hydrocarbon groups having 1 to 10 carbon atoms are bonded to one or more ester bonds, still more preferably an aliphatic hydrocarbon group having 1 to 10 carbon atoms, and particularly preferably an alkylene group having 1 to 10 carbon atoms.

Preferred examples of the constitutional unit represented by Formula (D4) include the following structures, and it is needless to say that the constitutional unit represented by Formula (D4) is not limited thereto. In the following specific examples, n represents an integer of 1 or more.

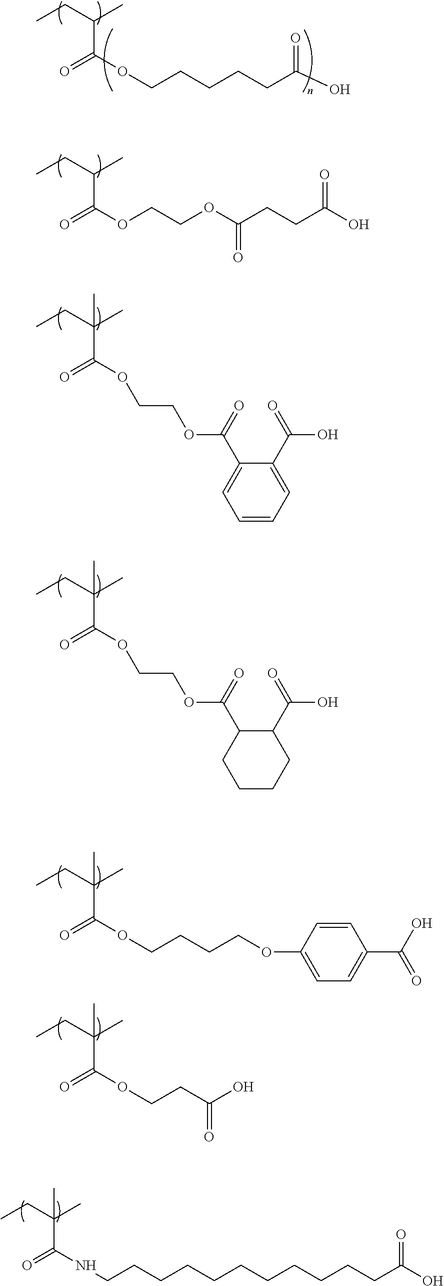

The specific resin may have one kind of the constitutional unit represented by Formula (D4), or may have two or more kinds thereof.

From the viewpoint of developability, formation of a pattern shape, and dispersion stability, the content of the constitutional unit represented by Formula (D4) is preferably 20 mass % to 80 mass %, more preferably 20 mass % to 70 mass %, and particularly preferably 20 mass % to 60 mass % with respect to the total mass of the specific resin.

[Constitutional Unit Represented by Formula (D5)]From the viewpoint of dispersion stability, the specific resin preferably has a constitutional unit represented by Formula (D5), and from the viewpoint of dispersion stability and developability, the specific resin more preferably further has the constitutional unit represented by Formula (D4) and a constitutional unit represented by Formula (D5).

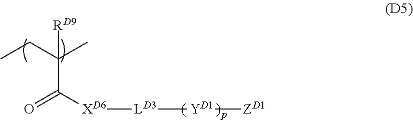

In Formula (D5), R^{D9} represents a hydrogen atom or an alkyl group, X^{D6} represents an oxygen atom or NR^{C}—, where R^{C} represents a hydrogen atom, an alkyl group, or an aryl group, L^{D3} represents a divalent linking group, Y^{D1} represents an alkyleneoxy group or an alkylenecarbonyloxy group, Z^{D1} represents an aliphatic hydrocarbon group having 1 to 20 carbon atoms or an aromatic hydrocarbon group having 6 to 20 carbon atoms, and p represents an integer of 1 or more, where in a case where p is 2 or more, p pieces of Y^{D1}'s may be the same or different from each other.

R^{D9} in Formula (D5) is preferably a hydrogen atom or a methyl group and more preferably a methyl group.

From the viewpoint of dispersion stability, X^{D6} in Formula (D5) is preferably an oxygen atom.

R^{C} is preferably a hydrogen atom or an alkyl group and more preferably a hydrogen atom.

From the viewpoint of dispersion stability, L^{D3} in Formula (D5) is preferably a group having a total of 2 to 30 atoms, more preferably a group having a total of 3 to 20 atoms, and particularly preferably a group having a total of 4 to 10 atoms.

In addition, from the viewpoint of dispersion stability, L^{D3} in Formula (D5) is preferably a group having a urethane bond or a urea bond, more preferably a group having a urethane bond, and particularly preferably a group in which an alkylene group and a urethane bond are bonded to each other.

From the viewpoint of dispersion stability, Y^{D1} in Formula (D5) is preferably an alkylenecarbonyloxy group. In addition, in a case where p pieces of Y^{D1}'s include a plurality of structures, those structures may be arranged at random, or may be arranged by forming blocks.

From the viewpoint of dispersion stability, the number of carbon atoms in the alkylenecarbonyloxy group is preferably 2 to 30, more preferably 3 to 10, and particularly preferably 5 to 8.

From the viewpoint of dispersion stability, p is an integer of 1 or more, and is preferably an integer of 3 or more.

In addition, p is preferably 100 or less, more preferably 60 or less, and particularly preferably 40 or less.

From the viewpoint of dispersion stability, Z^{D1} in Formula (D5) is preferably an aliphatic hydrocarbon group having 1 to 20 carbon atoms, more preferably an alkyl group having 4 to 20 carbon atoms, and particularly preferably an alkyl group having 6 to 20 carbon atoms.

In addition, from the viewpoint of dispersion stability, the above-described alkyl group in Z^{D1} is preferably a branched alkyl group.

Preferred examples of the constitutional unit represented by Formula (D5) include the following structures, and it is needless to say that the constitutional unit represented by Formula (D5) is not limited thereto. In the following specific examples, n represents an integer of 1 or more, and a and b each independently represent an integer of 1 or more. In addition, it is preferable that a oxyalkylene carbonyl structures or alkyleneoxy structures and b oxyalkylene carbonyl structures or alkyleneoxy structures are randomly arranged.

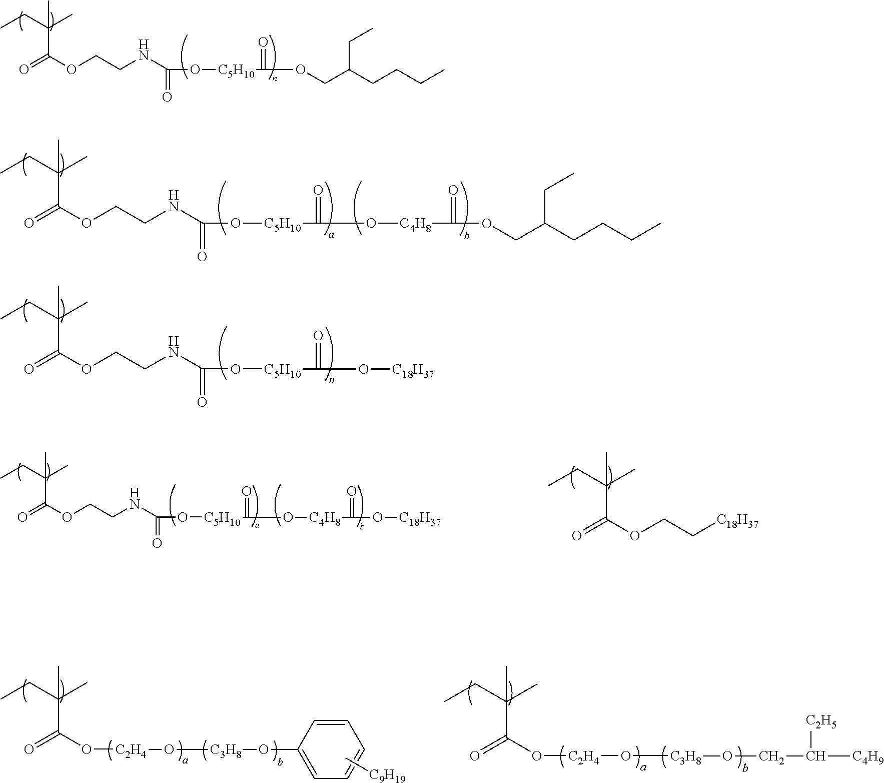

The above-described specific resin may have one kind of the constitutional unit represented by Formula (D5), or may have two or more kinds thereof.

From the viewpoint of developability and dispersion stability, the content of the constitutional unit represented by Formula (D5) is preferably 5 mass % to 80 mass %, more preferably 5 mass % to 70 mass %, and particularly preferably 5 mass % to 60 mass % with respect to the total mass of the specific resin.

[Other Constitutional Units]

The specific resin may have a constitutional unit other than the above-described constitutional units represented by Formula (A1), Formula (B1), Formula (D1), Formula (D4), and Formula (D5).

The other constitutional units are not particularly limited, and a known constitutional unit may be used.

Physical Properties of Specific Resin]

—Weight-Average Molecular Weight—

The weight-average molecular weight (Mw) of the specific resin is preferably 1,000 or more, more preferably 1,000 to 200,000, and particularly preferably 1,000 to 100,000.

—Ethylenically Unsaturated Bonding Value—

From the viewpoint of deep portion curability, formation of a pattern shape, and substrate adhesiveness, the ethylenically unsaturated bonding value of the specific resin is preferably 0.01 mmol/g to 2.5 mmol/g, more preferably 0.05 mmol/g to 2.3 mmol/g, still more preferably 0.1 mmol/g to 2.2 mmol/g, and particularly preferably 0.1 mmol/g to 2.0 mmol/g. The ethylenically unsaturated bonding value of the specific resin refers to a molar amount of ethylenically unsaturated groups per 1 g of the solid content of the specific resin, and is measured by the method described in Examples.

—Acid Value—

From the viewpoint of developability, the acid value of the specific resin is preferably 30 to 110 mgKOH/g and more preferably 40 to 90 mgKOH/g.

The above-described acid value is measured by the method described in Examples.

—Amine Value—

From the viewpoint of adhesiveness with the support, the amine value of the specific resin is preferably 0.03 to 0.8 mmol/g and more preferably 0.1 to 0.5 mmol/g.

The above-described amine value is measured by the method described in Examples.

The curable composition may contain the specific resin alone or in combination of two or more kinds thereof.

From the viewpoint of adhesiveness with the support and storage stability, the content of the specific resin is preferably 10 to 45 mass %, more preferably 12 to 40 mass %, and particularly preferably 14 to 35 mass % with respect to the total solid content of the curable composition.

In addition, from the viewpoint of adhesiveness with the support and storage stability, the content of the specific resin is preferably 20 to 60 parts by mass, more preferably 22 to 55 parts by mass, and particularly preferably 24 to 50 parts by mass with respect to 100 parts by mass of the pigment content.

The method for synthesizing the specific resin is not particularly limited, and a known or a method applying the known method can be used for the synthesis.

Examples thereof include a method of synthesizing a precursor of the above-described specific resin by a known method, and introducing a group having a radically polymerizable group in the above-described constitutional unit represented by Formula (A1) or Formula (B1) by a polymer reaction.

The above-described constitutional unit represented by Formula (A1) is introduced by the reaction of the carboxy group in the precursor of the above-described specific resin, the amine compound with the compound having an epoxy group and an acryloyl group. In addition, the above-described constitutional unit represented by Formula (A1) is introduced by the reaction of the amine compound in the precursor of the above-described specific resin with the compound having a halogeno group and an acryloyl group.

The above-described constitutional unit represented by Formula (B1) is introduced by the reaction of the amino group in the precursor of the above-described specific resin with the compound having an epoxy group and an acryloyl group. In addition, the above-described constitutional unit represented by Formula (B1) is introduced by the reaction of the amino group in the precursor of the above-described specific resin with the compound having a halogeno group and an acryloyl group.

The above-described constitutional unit represented by Formula (D1) is introduced by the reaction of the carboxy group in the precursor of the above-described specific resin with the compound having an epoxy group and an acryloyl group, and the reaction of the hydroxy group in the precursor of the above-described specific resin with the compound having an isosianato group and an acryloyl group.

These synthesis methods are merely examples, and the synthesis method of the specific resin is not particularly limited thereto.

In addition, in a case where the specific resin is a star polymer compound or a star polymer compound having a specific terminal group, these polymer compounds can be synthesized, for example, by referring to the synthesis method described in JP2007-277514A.

In addition, the above-described specific resin is composed of different constitutional units such as a constitutional unit responsible for developability, a constitutional unit responsible for dispersibility, and a constitutional unit responsible for curability, and in order to effectively exhibit different functions, it is preferable that composition of the specific resin is uniform.

Examples of a method for homogenizing composition of the specific resin include a method of adding dropwise a monomer to the reaction system so as to match the consumption rates of different monomers. In general, in a case where a concentration difference is present in the reaction system by increasing the initial concentration of a monomer having a slow consumption rate in the reaction system and then adding dropwise a monomer having a high consumption rate thereto, it is possible to match the reaction rates.

Specific examples of the specific resin in the present invention include PA-1 to PA-22, and PB-1 to PB-18 in Examples described later.

[Content]

The content of the specific resin in the total solid content of the curable composition is preferably 5 to 50 mass %. The lower limit is preferably 8 mass % or more and more preferably 10 mass % or more. The upper limit is preferably 40 mass % or less, more preferably 35 mass % or less, and still more preferably 30 mass % or less. In addition, the content of the specific resin having an acid group, in the total solid content of the curable composition, is preferably 5 to 50 mass %. The lower limit is preferably 10 mass % or more and more preferably 15 mass % or more. The upper limit is preferably 40 mass % or less, more preferably 35 mass % or less, and still more preferably 30 mass % or less.

In addition, from the viewpoint of curability, developability, and film-forming property, the total content of the polymerizable compound described later and the specific resin in the total solid content of the curable composition is preferably 10 to 65 mass %. The lower limit is preferably 15 mass % or more, more preferably 20 mass % or more, and still more preferably 30 mass % or more. The upper limit is preferably 60 mass % or less, more preferably 50 mass % or less, and still more preferably 40 mass % or less. In addition, the curable composition according to the embodiment of the present invention preferably contains 30 to 300 parts by mass of the specific resin with respect to 100 parts by mass of the polymerizable compound. The lower limit is preferably 50 parts by mass or more and more preferably 80 parts by mass or more. The upper limit is preferably 250 parts by mass or less and more preferably 200 parts by mass or less.

<Polymerizable compound>

It is preferable that the curable composition according to the embodiment of the present invention contains a polymerizable compound. A compound corresponding to the above-described specific resin does not correspond to the polymerizable compound. As the polymerizable compound, a known compound which is cross-linkable by a radical, an acid, or heat can be used. In the present invention, the polymerizable compound is preferably, for example, a compound having an ethylenically unsaturated group. Examples of the ethylenically unsaturated group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3,000. The upper limit is more preferably 2,000 or less and still more preferably 1,500 or less. The lower limit is more preferably 150 or more and still more preferably 250 or more.

The polymerizable compound is preferably a compound including 3 or more ethylenically unsaturated groups, more preferably a compound including 3 to 15 ethylenically unsaturated groups, and still more preferably a compound having 3 to 6 ethylenically unsaturated groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which the (meth)acryloyl group of these compounds is bonded through an ethylene glycol and/or a propylene glycol residue (for example, SR454 and SR499 which are commercially available from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a compound having an acid group can also be used. By using a polymerizable compound having an acid group, the polymerizable compound in an unexposed area is easily removed during development of a film formed from the curable composition and the generation of a development residue can be suppressed. Examples of the acid group include a carboxy group, a sulfo group, and a phosphoric acid group, and a carboxy group is preferable. Examples of a commercially available product of the polymerizable compound having an acid group include ARONIX M-510, M-520, and ARONIX TO-2349 (manufactured by TOAGOSEI CO., LTD.). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility of the film in a developer is good, and in a case where the acid value of the polymerizable compound is 40 mgKOH/g or less, it is advantageous in production and handling.

The polymerizable compound is preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having four ethyleneoxy groups, and KAYARAD TPA-330 manufactured by Nippon Kayaku Co., Ltd., which is a trifunctional (meth)acrylate having three isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the polymerizable compounds having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

The content of the polymerizable compound in the total solid content of the curable composition is preferably 0.1 to 50 mass %. The lower limit is more preferably 0.5 mass % or more and still more preferably 1 mass % or more. The upper limit is more preferably 45 mass % or less and still more preferably 40 mass % or less. The polymerizable compound may be used singly or in combination of two or more kinds thereof. In a case where two or more kinds thereof are used in combination, the total thereof is preferably within the above-described range.

<Photopolymerization initiator>

It is preferable that the curable composition according to the embodiment of the present invention includes a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from the group consisting of an oxime compound, an α-hydroxyketone compound, an α-aminoketone compound, and an acylphosphine compound is more preferable, and from the viewpoint that the effects of the present invention are easily obtained, an oxime compound is still more preferable. The details of the photopolymerization initiator can be found in paragraphs 0065 to 0111 of JP2014-130173A and in JP6301489B, the contents of which are incorporated herein by reference.

Examples of a commercially available product of the α-hydroxyketone compound include IRGACURE-184, DAROCUR-1173, IRGACURE-500, IRGACURE-2959, and IRGACURE-127 (all of which are manufactured by BASF). Examples of a commercially available product of the α-aminoketone compound include IRGACURE-907, IRGACURE-369, IRGACURE-379, and IRGACURE-379EG (all of which are manufactured by BASF). Examples of a commercially available product of the acylphosphine compound include IRGACURE-819, and DAROCUR-TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2000-080068A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include IRGACURE OXE01, IRGACURE OXE02, IRGACURE OXE03, and IRGACURE OXE04 (all of which are manufactured by BASF), TR-PBG-304 (manufactured by TRONLY), and ADEKA OPTOMER N-1919 (manufactured by ADEKA Corporation;
photopolymerization initiator 2 described in JP2012-014052A). In addition, as the oxime compound, it is also preferable to use a compound having low coloring property or a compound having high transparency and being resistant to discoloration. Examples of a commercially available product thereof include ADEKA ARKLS NCI-730, NCI-831, and NCI-930 (all of which are manufactured by ADEKA Corporation).

In the present invention, an oxime compound having a fluorene ring can also be used as the photopolymerization initiator. Specific examples of the oxime compound having a fluorene ring include compounds described in JP2014-137466A. The content thereof is incorporated herein by reference.

In the present invention, an oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A. The contents thereof are incorporated herein by reference.

In the present invention, an oxime compound having a nitro group can be used as the photopolymerization initiator. It is preferable that the oxime compound having a nitro group is a dimer. Specific examples of the oxime compound having a nitro group include a compound described in paragraph Nos. 0031 to 0047 of JP2013-114249A and paragraph Nos. 0008 to 0012 and 0070 to 0079 of JP2014-137466A, a compound described in paragraph Nos. 0007 to 0025 of JP4223071B, and ADEKA ARKLS NCI-831 (manufactured by ADEKA Corporation).

In the present invention, an oxime compound having a benzofuran skeleton can also be used as the photopolymerization initiator. Specific examples thereof include OE-01 to OE-75 described in WO2015/036910A.

Specific examples of the oxime compound which are preferably used in the present invention are shown below, but the present invention is not limited thereto.

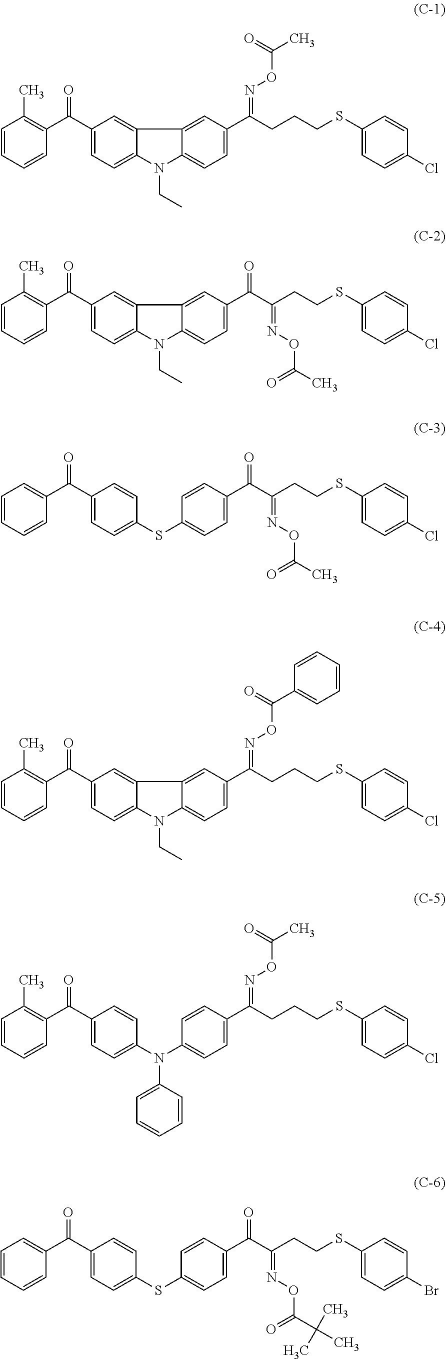 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

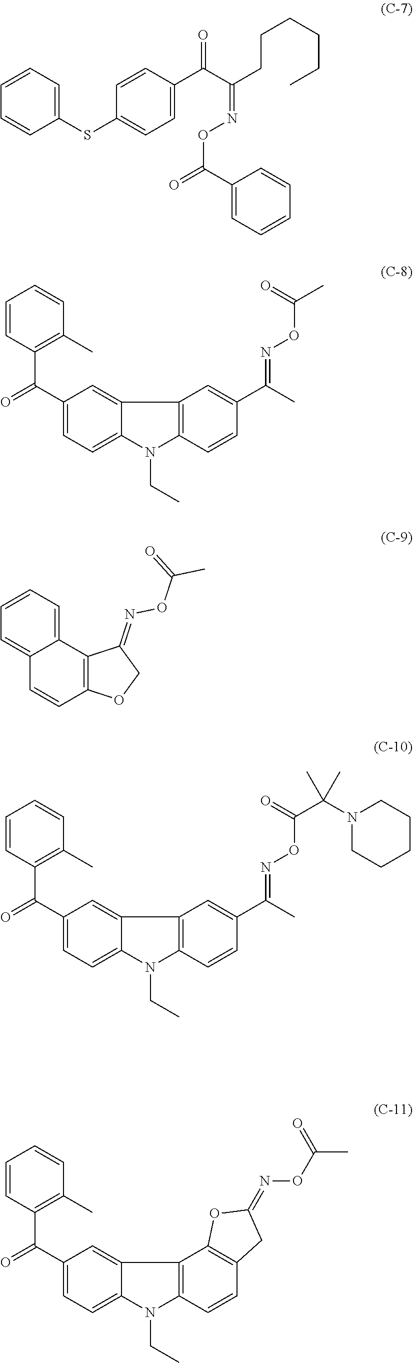 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C/C(=N\OC(C)=O)O3]

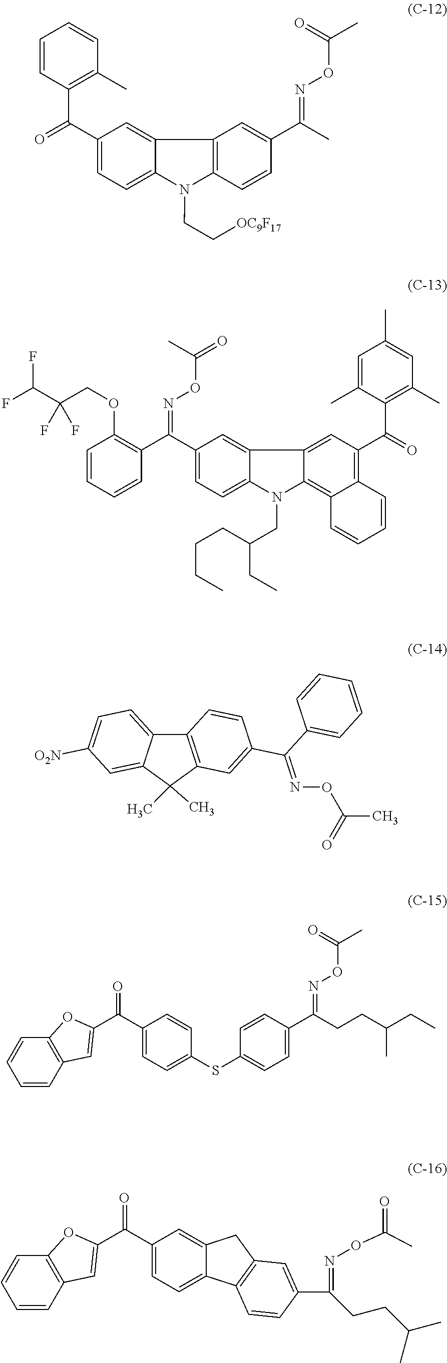

The photopolymerization initiator used in the present invention is preferably a compound having a maximum absorption wavelength in a wavelength range of 350 to 500 nm and more preferably a compound having a maximum absorption wavelength in a wavelength range of 360 to 480 nm.

In addition, from the viewpoint that the effects of the present invention are more easily obtained, the molar light absorption coefficient of the photopolymerization initiator used in the present invention at a wavelength of 365 nm is preferably 1,000 L·mol⁻¹ cm⁻¹ or more, more preferably 3,000 L·mol⁻¹ cm⁻¹ or more, and still more preferably 5,000 L·mol⁻¹·cm⁻¹ or more. In addition, the maximum value thereof is not particularly limited, but is preferably 100,000 L·mol⁻¹ cm⁻¹ or less. The molar light absorption coefficient of the photopolymerization initiator can be measured using a known method. For example, the molar light absorption coefficient is preferably measured by a spectrophotometer (Cary-5 spectrophotometer, manufactured by Varian Medical Systems, Inc.) using an ethyl acetate solvent at a concentration of 0.01 g/L.

As the photopolymerization initiator, a bifunctional or tri- or more functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the curable composition can be improved. Specific examples of the bifunctional or tri- or more functional photoradical polymerization initiator include dimers of the oxime compounds described in JP2010-527339A, JP2011-524436A, WO2015/004565A, paragraph Nos. 0412 to 0417 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; and the photopolymerization initiator (A) described in paragraph Nos. 0017 to 0026 of JP2017-151342A.

The content of the photopolymerization initiator in the total solid content of the curable composition according to the embodiment of the present invention is preferably 0.1 to 30 mass %. The lower limit is preferably 0.5 mass % or more and more preferably 1 mass % or more. The upper limit is preferably 20 mass % or less and more preferably 15 mass % or less. In the curable composition according to the embodiment of the present invention, the photopolymerization initiator may be used singly or in combination of two or more kinds thereof. In a case where two or more kinds thereof are used, the total content thereof is preferably within the above-described range.

<Other resins>

The curable composition according to the embodiment of the present invention may further include other resins. In the present invention, a compound corresponding to the above-described specific resin does not correspond to the other resins. The other resins are blended in, for example, an application for dispersing particles such as a pigment in a curable composition or an application as a binder. However, such applications of the other resins are only exemplary, and the other resins can also be used for other purposes in addition to such applications.

The weight-average molecular weight (Mw) of the other resins is preferably 3,000 to 2,000,000. The upper limit is preferably 1,000,000 or less and more preferably 500,000 or less. The lower limit is preferably 4,000 or more and more preferably 5,000 or more.

Examples of the other resins include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin. These resins may be used singly or as a mixture of two or more kinds thereof. In addition, the resins described in paragraph Nos. 0041 to 0060 of JP2017-206689A, and the resins described in paragraph Nos. 0022 to 0071 of JP2018-010856A can also be used.

[Resin Having Acid Group]

The curable composition according to the embodiment of the present invention preferably includes a resin having an acid group as the other resins. According to this aspect, developability of the curable composition can be improved, and pixels having excellent rectangularity can be easily formed. Examples of the acid group include a carboxy group, a phosphoric acid group, a sulfo group, and a phenolic hydroxy group, and a carboxy group is preferable. The resin having an acid group can be used, for example, as an alkali-soluble resin.

The resin having an acid group preferably includes a constitutional unit having an acid group in the side chain, and more preferably includes 5 to 70 mol % of constitutional units having an acid group in the side chain with respect to the total constitutional units of the resin. The upper limit of the content of the constitutional unit having an acid group in the side chain is preferably 50 mol % or less and more preferably 30 mol % or less. The lower limit of the content of the constitutional unit having an acid group in the side chain is preferably 10 mol % or more and more preferably 20 mol % or more.

In the present specification, in a case where the content of the constitutional unit is described in mol %, the constitutional unit is synonymous with the monomer unit.

It is also preferable that the resin having an acid group includes a constitutional unit derived from a monomer component including a compound represented by Formula (ED1) and/or a compound represented by Formula (ED2) (hereinafter, these compounds may be referred to as an “ether dimer”).

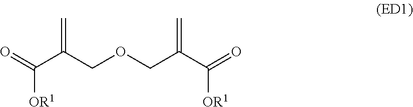

In Formula (ED1), R¹ and R² each independently represent a hydrogen atom or a hydrocarbon group having 1 to 25 carbon atoms, which may have a substituent.

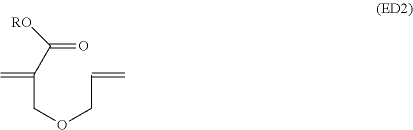

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

With regard to the specific examples of the ether dimer, reference can be made to the description in paragraph No. 0317 of JP2013-029760A, the contents of which are incorporated herein by reference.

It is also preferable that the resin used in the present invention includes a constitutional unit derived from a compound represented by Formula (X).

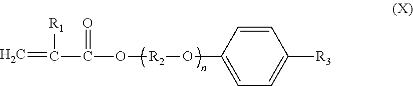

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may include a benzene ring. n represents an integer of 1 to 15.

With regard to the resin having an acid group, reference can be made to the description in paragraph Nos. 0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated herein by reference. A commercially available product can also be used as the resin having an acid group.

The acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 300 mgKOH/g or less, and still more preferably 200 mgKOH/g or less. The weight-average molecular weight (Mw) of the resin having an acid group is preferably 5,000 to 100,000. In addition, the number-average molecular weight (Mn) of the resin having an acid group is preferably 1,000 to 20,000.

Examples of the resin having an acid group include a resin having the following structures. In the structures, the parenthesized subscripts represent the content (mol %) of each constitutional unit.

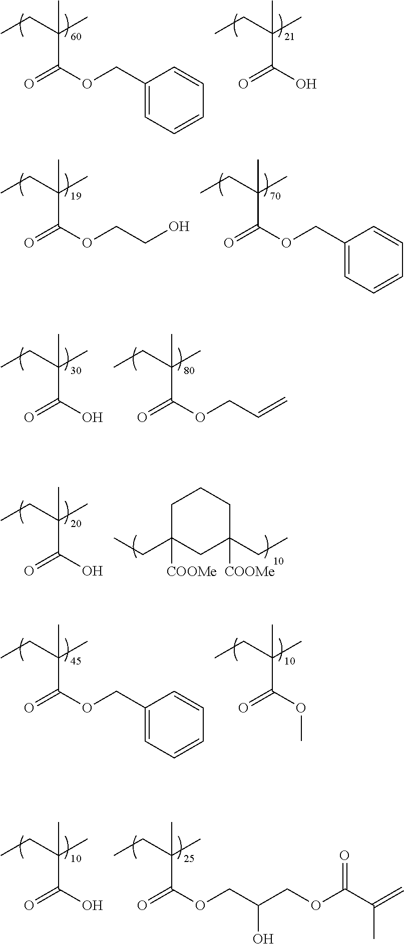

[Dispersant]

The curable composition according to the embodiment of the present invention can also include a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total content of the acid group and the basic group is 100 mol %, and more preferably a resin substantially consisting of only an acid group. The acid group included in the acidic dispersant (acidic resin) is preferably a carboxy group. The acid value of the acidic dispersant (acidic resin) is preferably 20 to 180 mgKOH/g, more preferably 30 to 150 mgKOH/g, and still more preferably 50 to 100 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

The resin used as a dispersant preferably includes a constitutional unit having an acid group. In a case where the resin used as a dispersant include a constitutional unit having an acid group, the generation of the development residue can be further suppressed in the formation of a pattern by a photolithography method.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10,000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

In addition, the above-described resin (alkali-soluble resin) having an acid group can also be used as a dispersant.

In addition, it is also preferable that the resin used as a dispersant is a resin including a constitutional unit having an ethylenically unsaturated group in the side chain. The content of the constitutional unit having an ethylenically unsaturated group in the side chain is preferably 10 mol % or more, more preferably 10 to 80 mol %, and still more preferably 20 to 70 mol % with respect to all the constitutional units of the resin.

A commercially available product is also available as the dispersant, and specific examples thereof include DISPERBYK series (for example, DISPERBYK-111, 161, and the like) manufactured by BYK Chemie, and Solsperse series (for example, Solsperse 76500) manufactured by Lubrizol Corporation. The dispersing agents described in paragraph Nos. 0041 to 0130 of JP2014-130338A can also be used, the contents of which are incorporated herein by reference. The resin described as a dispersant can be used for an application other than the dispersant. For example, the resin can also be used as a binder.

—Resin Having Curable Group—

Suitable examples of the dispersant used in the present invention also include a resin having a curable group.

As the curable group in the above-described dispersant, an ethylenically unsaturated group is preferable, at least one group selected from the group consisting of a vinyl group, a vinylphenyl group, an allyl group, a (meth)acryloyl group, a (meth)acrylamide group, and a maleimide group is more preferable, a (meth)acryloyl group is still more preferable, and an acryloyl group is particularly preferable.

In addition, the resin having a curable group preferably has a curable group in the side chain, and also preferably has a curable group at the molecular terminal of the side chain.

In addition, the preferred weight-average molecular weight of the dispersant is preferably 10,000 to 100,000.

Examples of the resin having a curable group include a resin including the above-described constitutional unit represented by Formula (D1), and a resin including the above-described constitutional unit represented by Formula (D1) and at least one selected from the group consisting of the above-described constitutional unit represented by Formula (D4) and the above-described constitutional unit represented by Formula (D5) is preferable, and a resin including the above-described constitutional unit represented by Formula (D1), the above-described constitutional unit represented by Formula (D4), and the above-described constitutional unit represented by Formula (D5) is more preferable.

In addition, the above-described resin having a curable group is a resin which does not satisfy any of the above-described requirements 1 and 2.

[Content]

In a case where the curable composition according to the embodiment of the present invention includes the other resins, the content of the other resins in the total solid content of the curable composition is preferably 0.5 to 50 mass %. The lower limit is preferably 1 mass % or more and more preferably 2 mass % or more. The upper limit is preferably 40 mass % or less, more preferably 35 mass % or less, and still more preferably 30 mass % or less. In addition, the content of the resin having an acid group, in the total solid content of the curable composition, is preferably 0.5 to 50 mass %. The lower limit is preferably 1 mass % or more and more preferably 2 mass % or more. The upper limit is preferably 40 mass % or less, more preferably 35 mass % or less, and still more preferably 30 mass % or less.

<Compound Having Cyclic Ether Group>

The curable composition according to the embodiment of the present invention can contain a compound having a cyclic ether group. Examples of the cyclic ether group include an epoxy group and an oxetanyl group. The compound having a cyclic ether group is preferably a compound having an epoxy group. Examples of the compound having an epoxy group include a compound having one or more epoxy groups in one molecule, and a compound two or more epoxy groups in one molecule is preferable. It is preferable to have 1 to 100 epoxy groups in one molecule. The upper limit of the number of epoxy groups may be, for example, 10 or less or 5 or less. The lower limit of the number of epoxy groups is preferably 2 or more. As the compound having an epoxy group, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of which are incorporated herein by reference.

The compound having an epoxy group may be a low-molecular-weight compound (for example, having a molecular weight of less than 2,000, and further, a molecular weight of less than 1,000) or a high-molecular-weight compound (macromolecule) (for example, having a molecular weight of 1,000 or more, and in a case of a polymer, having a weight-average molecular weight of 1,000 or more). The weight-average molecular weight of the compound having an epoxy group is preferably 200 to 100,000 and more preferably 500 to 50,000. The upper limit of the weight-average molecular weight is preferably 10,000 or less, more preferably 5,000 or less, and still more preferably 3,000 or less.

As the compound having an epoxy group, an epoxy resin can be preferably used. Examples of the epoxy resin include an epoxy resin which is a glycidyl etherified product of a phenol compound, an epoxy resin which is a glycidyl etherified product of various novolak resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3,300 g/eq, more preferably 310 to 1,700 g/eq, and still more preferably 310 to 1,000 g/eq.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

In a case where the curable composition according to the embodiment of the present invention contains a compound having a cyclic ether group, the content of the compound having a cyclic ether group in the total solid content of the curable composition is preferably 0.1 to 20 mass %. The lower limit is, for example, preferably 0.5 mass % or more, and more preferably 1 mass % or more. The upper limit is, for example, preferably 15 mass % or less and still more preferably 10 mass % or less. The compound having a cyclic ether group may be used singly or in combination of two or more kinds thereof. In a case of using two or more kinds thereof, the total content thereof is preferably within the above-described range.

<Silane Coupling Agent>

The curable composition according to the embodiment of the present invention can contain a silane coupling agent. According to this aspect, adhesiveness of a film to be obtained with a support can be further improved. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureide group, a sulfide group, an isocyanate group, and a phenyl group, and an amino group, a (meth)acryloyl group, or an epoxy group is preferable. Specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

The content of the silane coupling agent in the total solid content of the curable composition is preferably 0.1 to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof. In a case of using two or more kinds thereof, the total content thereof is preferably within the above-described range.

<Solvent>

The curable composition according to the embodiment of the present invention can contain a solvent. Examples of the solvent include an organic solvent. Basically, the solvent is not particularly limited as long as it satisfies the solubility of the respective components and the application properties of the curable composition. Examples of the organic solvent include an ester solvent, a ketone solvent, an alcohol solvent, an amide solvent, an ether solvent, and a hydrocarbon solvent. The details of the organic solvent can be found in paragraph No. 0223 of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the solvent is low (for example, 50 parts per million (ppm) by mass or less, 10 ppm by mass or less, or 1 ppm by mass or less with respect to the total content of the organic solvent) in consideration of environmental aspects and the like.

In the present invention, a solvent having a low metal content is preferably used. For example, the metal content in the solvent is preferably 10 ppb (parts per billion) by mass or less. A solvent in which the metal content is at a level of ppt (parts per trillion) by mass may be used as desired, and such a high-purity solvent is provided by, for example, Toyo Gosei Co., Ltd. (The Chemical Daily, Nov. 13, 2015).

Examples of a method for removing impurities such as a metal from the solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The solvent may include an isomer (a compound having the same number of atoms and a different structure). In addition, only one kind of isomers may be included, or a plurality of isomers may be included.

In the present invention, the organic solvent preferably has the content of peroxides of 0.8 mmol/L or less, and more preferably, the organic solvent does not substantially include peroxides.

The content of the solvent in the curable composition is preferably 10 to 95 mass %, more preferably 20 to 90 mass %, and still more preferably 30 to 90 mass %.

In addition, from the viewpoint of environmental regulation, it is preferable that the curable composition according to the embodiment of the present invention does not substantially contain environmentally regulated substances. In the present invention, the description “does not substantially contain environmentally regulated substances” means that the content of the environmentally regulated substances in the curable composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their amount used and handling method. These compounds can be used as a solvent in a case of producing respective components used in the curable composition according to the embodiment of the present invention, and may be incorporated into the curable composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause cross-linking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, or curable composition produced by mixing these compounds.

<Polymerization Inhibitor>

The curable composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. The content of the polymerization inhibitor in the total solid content of the curable composition is preferably 0.0001 to 5 mass %.

<Surfactant>

The curable composition according to the embodiment of the present invention can contain a surfactant. As the surfactant, various surfactants such as a fluorine-based surfactant, a nonionic surfactant, a cationic surfactant, an anionic surfactant, or a silicone-based surfactant can be used. With regard to the surfactant, reference can be made to the description in paragraph Nos. 0238 to 0245 of WO2015/166779A, the contents of which are incorporated herein by reference.

In the present invention, it is preferable that the surfactant is a fluorine-based surfactant. By containing a fluorine-based surfactant in the curable composition, liquid characteristics (particularly, fluidity) are further improved, and liquid saving properties can be further improved. In addition, it is possible to form a film with a small thickness unevenness.

The fluorine content in the fluorine-based surfactant is preferably 3 to 40 mass %, more preferably 5 to 30 mass %, and particularly preferably 7 to 25 mass %. The fluorine-based surfactant in which the fluorine content is within the above-described range is effective in terms of the evenness of the thickness of the coating film or liquid saving properties and the solubility of the surfactant in the curable composition is also good.

Examples of the fluorine-based surfactant include surfactants described in paragraph Nos. 0060 to 0064 of JP2014-041318A (paragraph Nos 0060 to 0064 of the corresponding WO2014/017669A) and the like, and surfactants described in paragraph Nos 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, MFS-330 (all of which are manufactured by DIC Corporation); FLUORAD FC430, FC431, and FC171 (all of which are manufactured by Sumitomo 3M Ltd.); SURFLON 5-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound which has a molecular structure having a functional group containing a fluorine atom and in which, by applying heat to the molecular structure, the functional group containing a fluorine atom is broken to volatilize a fluorine atom can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound can be preferably used. With regard to such a fluorine-based surfactant, reference can be made to the description in JP2016-216602A, the contents of which are incorporated herein by reference.

A block polymer can also be used as the fluorine-based surfactant. Examples thereof include the compounds described in JP2011-089090A. As the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used. The following compounds are also exemplified as the fluorine-based surfactant used in the present invention.

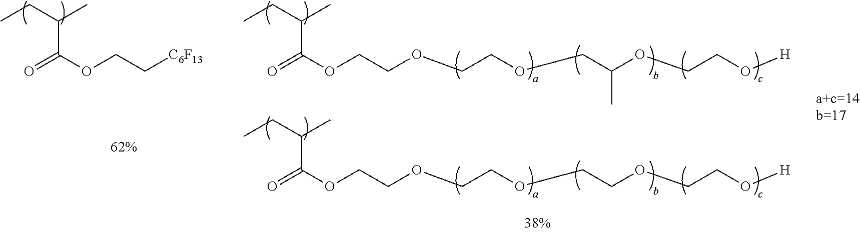

The weight-average molecular weight of the compounds is preferably 3,000 to 50,000, and is, for example, 14,000. In the compound, “%” representing the proportion of a constitutional unit is mol %.

In addition, as the fluorine-based surfactant, a fluorine-containing polymer having an ethylenically unsaturated group in the side chain can be used. Specific examples thereof include the compounds described in paragraph Nos. 0050 to 0090 and paragraph Nos. 0289 to 0295 of JP2010-164965A, and for example, MEGAFACE RS-101, RS-102, RS-718K, and RS-72-K manufactured by DIC Corporation. As the fluorine-based surfactant, the compounds described in paragraph Nos. 0015 to 0158 of JP2015-117327A can also be used.

Examples of the nonionic surfactant include glycerol, trimethylolpropane, trimethylolethane, and ethoxylate and propoxylate thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (manufactured by FUJIFILM Wako Pure Chemical Corporation), PIONIN D-6112, D-6112-W, and D-6315 (manufactured by Takemoto Oil & Fat Co., Ltd.), and OLFINE E1010, and SURFYNOL 104, 400, and 440 (manufactured by Nissin Chemical Co., Ltd.).

Examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu chemical Co., Ltd.), and BYK307, BYK323, and BYK330 (all of which are manufactured by BYK Chemie).

The content of the surfactant in the total solid content of the curable composition is preferably 0.001 mass % to 5.0 mass % and more preferably 0.005 to 3.0 mass %. The surfactant may be used singly or in combination of two or more kinds thereof. In a case of using two or more kinds thereof, the total content thereof is preferably within the above-described range.

<Other Colorants>

The curable composition according to the embodiment of the present invention may contain a colorant other than the above-described pigment. Examples the other colorants include a dye.

[Dye]

As the dye, a known dye can be used without any particular limitation. The dye may be a chromatic dye or may be a near-infrared absorbing dye. Examples of the chromatic dye include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound. In addition, thiazole compounds described in JP2012-158649A, azo compounds described in JP2011-184493A, or azo compounds described in JP2011-145540A can also be used. In addition, as yellow dyes, quinophthalone compounds described in paragraph Nos. 0011 to 0034 of JP2013-054339A, quinophthalone compounds described in paragraph Nos. 0013 to 0058 of JP2014-026228A, or the like can also be used. Examples of the near-infrared absorbing dye include a pyrrolopyrrole compound, a rylene compound, an oxonol compound, a squarylium compound, a cyanine compound, a croconium compound, a phthalocyanine compound, a naphthalocyanine compound, a pyrylium compound, an azurenium compound, an indigo compound, and a pyrromethene compound. In addition, the squarylium compounds described in JP2017-197437A, the squarylium compounds described in paragraph Nos. 0090 to 0107 of WO2017/213047A, the pyrrole ring-containing compounds described in paragraph Nos. 0019 to 0075 of JP2018-054760A, the pyrrole ring-containing compounds described in paragraph Nos. 0078 to 0082 of JP2018-040955A, the pyrrole ring-containing compounds described in paragraph Nos. 0043 to 0069 of JP2018-002773A, the squarylium compounds having an aromatic ring at the α-amide position described in paragraph Nos. 0024 to 0086 of JP2018-041047A, the amide-linked squarylium compounds described in JP2017-179131A, the compounds having a pyrrole bis-type squarylium skeleton or a croconium skeleton described in JP2017-141215A, the dihydrocarbazole bis-type squarylium compounds described in JP2017-082029, the asymmetric compounds described in paragraph Nos. 0027 to 0114 of JP2017-068120A, the pyrrole ring-containing compounds (carbazole type) described in JP2017-067963A, the phthalocyanine compounds described in JP6251530B, and the like can be used.

In addition, the curable composition according to the embodiment of the present invention may include a coloring agent multimer as the other colorants. The coloring agent multimer is preferably a dye which is used after being dissolved in a solvent, but the coloring agent multimer may form a particle. In a case where the coloring agent multimer is the particle, it is usually used in a state of being dispersed in a solvent. The coloring agent multimer in the particle state can be obtained by, for example, emulsion polymerization, and specific examples thereof include the compounds and production methods described in JP2015-214682A. The coloring agent multimer has two or more coloring agent structures in one molecule, and preferably has three or more coloring agent structures in one molecule. The upper limit is particularly not limited, but may be 100 or less. A plurality of coloring agent structures included in one molecule may be the same coloring agent structure or different coloring agent structures. The weight-average molecular weight (Mw) of the coloring agent multimer is preferably 2,000 to 50,000. The lower limit is more preferably 3,000 or more and still more preferably 6,000 or more. The upper limit is more preferably 30,000 or less and still more preferably 20,000 or less. As the coloring agent multimer, the compounds described in JP2011-213925A, JP2013-041097A, JP2015-028144A, JP2015-030742A, WO2016/031442A, or the like can also be used.

In a case where the curable composition includes other colorants, the content of the other colorants in the total solid content of the curable composition is preferably 1 mass % or more, more preferably 5 mass % or more, and particularly preferably 10 mass % or more. The upper limit is not particularly limited, but is preferably 70 mass % or less, more preferably 65 mass % or less, and still more preferably 60 mass % or less.

In addition, the content of the other colorants is preferably 5 to 50 parts by mass with respect to 100 parts by mass of the pigment. The upper limit is preferably 45 parts by mass or less and more preferably 40 parts by mass or less. The lower limit is preferably 10 parts by mass or more and still more preferably 15 parts by mass or more.

In addition, it is also possible that the curable composition according to the embodiment of the present invention does not substantially contain the other colorants. The case where the curable composition according to the embodiment of the present invention does not substantially include the other colorants means that the content of the other colorants in the total solid content of the curable composition according to the embodiment of the present invention is preferably 0.1 mass % or less, more preferably 0.05 mass % or less, and particularly preferably 0 mass %.

<Ultraviolet Absorber>

The curable composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, and the like can be used. With regard to details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Specific examples of the ultraviolet absorber include a compound having the following structures. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016).

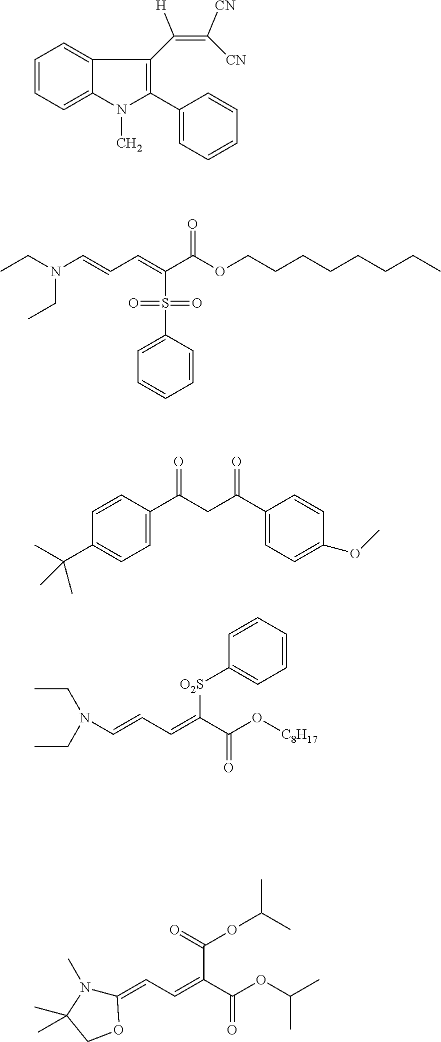

The content of the ultraviolet absorber in the total solid content of the curable composition is preferably 0.01 to 10 mass % and more preferably 0.01 to 5 mass %. In the present invention, the ultraviolet absorber may be used singly or in combination of two or more kinds thereof. In a case where two or more kinds thereof are used, the total content thereof is preferably within the above-described range.

<Antioxidant>

The curable composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitability used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (all of which are manufactured by ADEKA Corporation).

The content of the antioxidant in the total solid content of the curable composition is preferably 0.01 to 20 mass % and more preferably 0.3 to 15 mass %. The antioxidant may be used singly or in combination of two or more kinds thereof. In a case where two or more kinds thereof are used, the total content thereof is preferably within the above-described range.

<Oxidant>

The curable composition according to the embodiment of the present invention can contain an oxidant.

The oxidant may include a compound which also acts as the above-described polymerization inhibitor.

Examples of the oxidant include quinone compounds and quinodimethane compounds. As the quinone compound, benzoquinone, naphthoquinone, anthraquinone, chloranil, dichlorodicyanobenzoquinone (DDQ), and the like can be used. As the quinodimethane compound, 7,7,8,8-tetracyanoquinodimethane (TCNQ), 2-fluoro-7,7,8,8-tetracyanoquinodimethane (FTCNQ), 2,5-difluoro-7,7,8,8-tetracyanoquinodimethane (F2TCNQ), tetrafluorotetracyanoquinodimethane (F4TCNQ), and the like can be used.

It is preferable that the lowest unoccupied molecular orbital (LUMO) of the oxidant is lower than that of the pigment or dye included. The LUMO of the oxidant is preferably −3.5 eV or less, more preferably −3.8 eV or less, and most preferably −4.0 eV or less. The content of the oxidant in the total solid content of the curable composition is preferably 0.0001 to 10 mass %, more preferably 0.0005 to 5 mass %, and most preferably 0.001 to 1 mass %. The oxidant may be used singly or in combination of two or more kinds thereof. In a case where two or more kinds thereof are used, the total content thereof is preferably within the above-described range.

<Other Components>

Optionally, the curable composition according to the embodiment of the present invention may further contain a sensitizer, a curing accelerator, a filler, a thermal curing accelerator, a plasticizer, and other auxiliary agents (for example, conductive particles, an anti-foaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph Nos. 0183 and later of JP2012-003225A (corresponding to paragraph No. 0237 of US2013/0034812A) and paragraph Nos. 0101 to 0104 and 0107 to 0109 of JP2008-250074A, the content of which is incorporated herein by reference. In addition, optionally, the curable composition according to the embodiment of the present invention may contain a potential antioxidant. Examples of the potential antioxidant include a compound in which a portion that functions as the antioxidant is protected by a protective group and the protective group is desorbed by heating the compound at 100° C. to 250° C. or by heating the compound at 80° C. to 200° C. in the presence of an acid/a base catalyst. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation).

In addition, in order to adjust the refractive index of a film to be obtained, the curable composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

In addition, the curable composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to “0052 of JP2017-129774A, the compounds described in paragraph Nos. 0031 to 0034, 0058, and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

For example, in a case where a film is formed by application, the viscosity (25° C.) of the curable composition according to the embodiment of the present invention is preferably 1 to 100 mPa×s. The lower limit is more preferably 0.1 mPa×s or more and still more preferably 0.2 mPa×s or more. The upper limit is more preferably 10 mPa×s or less, still more preferably 5 mPa×s or less, and particularly preferably 3 mPa×s or less.

In the curable composition according to the embodiment of the present invention, the content of free metal which is not bonded to or coordinated with a pigment or the like is preferably 100 ppm or less, more preferably 50 ppm or less, and still more preferably 10 ppm or less, it is particularly preferable to not contain the free metal substantially. In the present specification, ppm is based on mass. According to this aspect, effects such as stabilization of pigment dispersibility (restraint of aggregation), improvement of spectral characteristics due to improvement of dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described free metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the curable composition according to the embodiment of the present invention, the content of free halogen which is not bonded to or coordinated with a pigment or the like is preferably 100 ppm or less, more preferably 50 ppm or less, and still more preferably 10 ppm or less, it is particularly preferable to not contain the free halogen substantially. Examples of halogen include F, Cl, Br, I, and anions thereof. Examples of a method for reducing free metals and halogens in the curable composition include washing with ion exchange water, filtration, ultrafiltration, and purification with an ion exchange resin.

It is also preferable that the curable composition according to the embodiment of the present invention does not substantially include terephthalic acid ester.

<Storage Container>

A storage container of the curable composition according to the embodiment of the present invention is not particularly limited, and a known storage container can be used. In addition, as the storage container, in order to suppress infiltration of impurities into the raw materials or the curable composition, a multilayer bottle in which a container inner wall having a six-layer structure is formed of six kinds of resins or a bottle in which a container inner wall having a seven-layer structure is formed of six kinds of resins is preferably used. Examples of such a container include a container described in JP2015-12335TA.

In addition, as a storage container used for the curable composition according to the embodiment of the present invention or a composition used for producing an image sensor, for the purpose of preventing metal elution from the container inner wall, improving storage stability of the composition, and suppressing the alteration of components, it is also preferable that the inner wall of the storage container is formed of glass, stainless steel, or the like.

Storage conditions of the curable composition according to the embodiment of the present invention are not particularly limited, and a known method in the related art can be used. In addition, a method described in JP2016-180058A can be used.

<Method of Preparing Curable Composition>

The curable composition according to the embodiment of the present invention can be prepared by mixing the above-described components with each other. During the preparation of the curable composition, all the components may be dissolved and/or dispersed in a solvent at the same time to prepare the curable composition. Optionally, two or more solutions or dispersion liquids in which the respective components are appropriately blended may be prepared, and the solutions or dispersion liquids may be mixed with each other during use (during application) to prepare the curable composition.

In addition, in the preparation of the curable composition, a process of dispersing the pigment is preferably included. In the process of dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. In addition, it is preferable that rough particles are removed by filtering, centrifugal separation, and the like after pulverization treatment. In addition, as the process and the disperser for dispersing the pigment, the process and the disperser described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. A material, a device, process conditions, and the like used in the salt milling step can be found in, for example, JP2015-194521A and JP2012-046629A.

During the preparation of the curable composition, it is preferable that the curable composition is filtered through a filter, for example, in order to remove foreign matter or to reduce defects. As the filter, any filter which is used in the related art for filtering or the like can be used without any particular limitation. Examples of the filter include filters formed of materials including, for example, a fluororesin such as polytetrafluoroethylene (PTFE), a polyamide-based resin such as nylon (for example, nylon-6 and nylon-6,6), and a polyolefin resin (including a polyolefin resin having a high-density or an ultrahigh molecular weight) such as polyethylene and polypropylene (PP). Among these materials, polypropylene (including high-density polypropylene) or nylon is preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Advantec Toyo Kaisha., Ltd., Nihon Entegris G.K. (formerly Nippon Microlith Co., Ltd.), Kitz Microfilter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and then the filtering using the second filter may be performed on a mixture of the dispersion liquid and other components.

(Film)

The film according to the embodiment of the present invention is a film formed from the above-described curable composition according to the embodiment of the present invention.

The film according to the embodiment of the present invention is preferably a cured film obtained by curing the curable composition according to the embodiment of the present invention. In addition, the film according to the embodiment of the present invention is preferably a film formed of a cured product of the curable composition according to the embodiment of the present invention.

The film according to the embodiment of the present invention can be used for a color filter, a near-infrared transmission filter, a near-infrared cut filter, a black matrix, a light-shielding film, a refractive index adjusting film, and the like. For example, the film according to the embodiment of the present invention can be preferably used as a colored layer of a color filter.

The thickness of the film according to the embodiment of the present invention can be appropriately adjusted according to the purpose. For example, the thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

(Color Filter)

The color filter according to an embodiment of the present invention is a color filter formed from the curable composition according to the embodiment of the present invention. It is preferable that the color filter according to the embodiment of the present invention has the film according to the embodiment of the present invention. In a case where the film according to the embodiment of the present invention is used for a color filter, as the pigment, it is preferable to use a chromatic pigment.

For example, the film thickness of the color filter according to the embodiment of the present invention is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more. The color filter according to the embodiment of the present invention can be used for a solid-state imaging element such as a charge coupled device (CCD) and a complementary metal-oxide semiconductor (CMOS), an image display device, or the like.

In addition, the color filter according to the embodiment of the present invention may include the film according to the embodiment of the present invention and a protective layer. The protective layer and the film according to the embodiment of the present invention may be in contact with each other, another layer may be provided therebetween, or a gap may be provided therebetween. By including the protective layer, various functions such as oxygen shielding, low reflection, hydrophilicity/hydrophobicity, and shielding of light (ultraviolet rays, near-infrared rays, infrared rays, and the like) having a specific wavelength can be imparted. The thickness of the protective layer is preferably 0.01 to 10 μm and still more preferably 0.1 to 5 μm. Examples of a method for forming the protective layer include a method of forming the protective layer by applying a resin composition dissolved in a solvent, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluorine resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an inkjet method can be used. As the solvent contained in the resin composition, a known solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic particles, inorganic particles, an absorber of a specific wavelength (for example, ultraviolet rays, near-infrared rays, infrared rays, and the like), a refractive index adjusting agent, an antioxidant, an adhesive agent, and a surfactant. Examples of the organic or inorganic particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of a specific wavelength, a known absorber can be used. For example, as an ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. With regard to details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. As the infrared absorber, for example, a cyclic tetrapyrrole coloring agent, an oxocarbon coloring agent, a cyanine coloring agent, a quaterrylene coloring agent, a naphthalocyanine coloring agent, a nickel complex coloring agent, a copper ion coloring agent, an iminium coloring agent, a subphthalocyanine coloring agent, a xanthene coloring agent, an azo coloring agent, a dipyrromethene coloring agent, a pyrrolopyrrole coloring agent, or the like can be used. With regard to details thereof, reference can be made to the description in paragraph Nos. 0020 to 0072 of JP2018-054760A, JP2009-263614A, and WO2017/146092A, the contents of which are incorporated herein by reference. The content of these additives can be appropriately adjusted, but is preferably 0.1 to 70 mass % and still more preferably 1 to 60 mass % with respect to the total mass of the protective layer.

In addition, as the protective layer, the protective layers described in paragraph Nos. 0073 to 0092 of JP2017-151176A can also be used.

<First Aspect of Method for Manufacturing Color Filter>

A method for manufacturing a color filter according to the embodiment of the present invention includes a step (composition layer forming step) of forming a composition layer on a support by applying a curable composition to the support, a step (exposing step) of patternwise exposing the composition layer, and a step (developing step) of forming a colored pattern by developing and removing an unexposed area.

Hereinafter, each step will be described.

[Composition Layer Forming Step]

In the composition layer forming step, a curable composition layer is formed on a support using the curable composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, an undercoat layer may be provided on the silicon substrate so as to improve adhesiveness to an upper layer, prevent the diffusion of substances, or planarize the surface of the substrate.

In the step of forming the curable composition layer, the curable composition is applied to a support.

As a method of applying the curable composition, a may be performed by a known method. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint lithography method. The application method using an ink jet method is not particularly limited, and examples thereof include a method (in particular, pp. 115 to 133) described in “Extension of Use of Ink Jet—Infinite Possibilities in Patent—” (published on February, 2005, S.B. Research Co., Ltd.) and methods described in JP2003-262716A, JP2003-185831A, JP2003-261827A, JP2012-126830A, and JP2006-169325A. In addition, with regard to the method of applying the curable composition, reference can be made to the description in WO2017/030174A and WO2017/018419A, the contents of which are incorporated herein by reference.

The curable composition layer formed on the support may be dried (pre-baked). In a case of producing a film by a low-temperature process, pre-baking may not be performed. In a case where pre-baking is performed, the temperature of pre-baking is preferably 150° C. or lower, more preferably 120° C. or lower, and still more preferably 110° C. or lower. The lower limit may be, for example, 50° C. or higher or 80° C. or higher. The pre-baking time is preferably 10 to 300 seconds, more preferably 40 to 250 seconds, and still more preferably 80 to 220 seconds. Pre-baking can be performed using a hot plate, an oven, or the like.

[Exposing Step]

Next, the curable composition layer is patternwise exposed (exposing step). For example, the curable composition layer can be patternwise exposed using a stepper exposure device or a scanner exposure device through a mask having a predetermined mask pattern. As a result, an exposed area can be cured.

As the radiation (light) which can be used during the exposure, g-rays, i-rays, or the like are preferably used. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50,000,000 W/m² or more, more preferably 100,000,000 W/m² or more, and still more preferably 200,000,000 W/m² or more. In addition, the upper limit of the maximum instantaneous illuminance is preferably 1,000,000,000 W/m² or less, more preferably 800,000,000 W/m² or less, and still more preferably 500,000,000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation dose (exposure dose) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1,000 W/m² to 100,000 W/m² (for example, 5,000 W/m², 15,000 W/m², or 35,000 W/m²). Appropriate conditions of each of the oxygen concentration and the exposure illuminance may be combined, and for example, a combination of the oxygen concentration of 10% by volume and the illuminance of 10,000 W/m², a combination of the oxygen concentration of 35% by volume and the illuminance of 20,000 W/m², or the like is available.

[Developing Step]

Next, the unexposed area of the curable composition layer is removed by development to form a pattern (pixel). The unexposed area of the curable composition layer can be removed by development using a developer. Thus, the curable composition layer of the unexposed area in the exposing step is eluted into the developer, and as a result, only a photocured portion remains. As the developer, an organic alkaline developer causing no damage on a base of element, circuit, or the like is desirable. For example, the temperature of the developer is preferably 20° C. to 30° C. The development time is preferably 20 to 180 seconds. In addition, in order to further improve residues removing properties, a step of shaking the developer off per 60 seconds and supplying a new developer may be repeated multiple times.

As the developer, an alkaline solution (alkaline developer) obtained by diluting an alkali agent with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, and 1,8-diazabicyclo[5.4.0]-7-undecene; and an inorganic alkaline compound such as sodium hydroxide, potassium hydroxide, sodium carbonate, sodium bicarbonate, sodium silicate, and sodium metasilicate. In consideration of environmental aspects and safety aspects, the alkaline agent is preferably a compound having a high molecular weight. The concentration of the alkaline agent in the alkaline solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the curable composition layer after development while rotating the support on which the curable composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to perform an additional exposure treatment or a heating treatment (post-baking) after carrying out drying. The additional exposure treatment or the post-baking is a treatment after development in order to complete curing, and the heating temperature is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions.

In a case of performing the additional exposure treatment, light used for the exposure is preferably light having a wavelength of 400 nm or less. In addition, the additional exposure treatment may be carried out by the method described in KR10-2017-0122130A.

The width of the pixel is preferably 0.5 to 20.0 μm. The lower limit is preferably 1.0 μm or more and more preferably 2.0 μm or more. The upper limit is preferably 15.0 μm or less and more preferably 10.0 μm or less.

The Young's modulus of the pixel is preferably 0.5 to 20 GPa and more preferably 2.5 to 15 GPa.

It is preferable that the pixel has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness can be measured, for example, using an atomic force microscope (AFM) Dimension 3100 manufactured by Veeco Instruments, Inc.

In addition, the contact angle of water on the pixel can be appropriately set to a preferred value and is typically in the range of 500 to 110°. The contact angle can be measured, for example, using a contact angle meter CV-DT-A Model (manufactured by Kyowa Interface Science Co., Ltd.).

It is desired that the volume resistivity value of the pixel is high. Specifically, the volume resistivity value of the pixel is preferably 10⁹ Ω×cm or more and more preferably 10¹¹ Ω×cm or more. The upper limit is not specified, but is, for example, preferably 10¹⁴ Ω×cm or less. The volume resistivity value of the pixel can be measured, for example, using an ultrahigh resistance meter 5410 (manufactured by Advantest Corporation).

By repeating the composition layer forming step, the exposing step, and the developing step (furthermore, additional exposure treatment and heating treatment as necessary) as described above for a desired number of hues, a color filter composed of a desired colored layer is formed.

The above-described manufacturing method is a method for manufacturing a pixel of a color filter, but according to the curable composition according to the embodiment of the present invention, for example, a black matrix provided between the pixels of the color filter is also manufactured. The black matrix can be manufactured by performing pattern exposure and development, and further performing post-baking as necessary, in the same manner as in the above-described pixel manufacturing method, except that, for example, a curable composition according to the embodiment of the present invention, to which a black pigment is added as the pigment, is used.

(Second Aspect of Method for Manufacturing Color Filter)

A second aspect of the method for manufacturing a color filter according to the embodiment of the present invention includes a step (cured layer forming step) of forming a composition layer on a support by applying the curable composition according to the embodiment of the present invention to the support, and curing the composition layer to form a cured layer, a step (photoresist layer forming step) of forming a photoresist layer on the cured layer, a step (resist pattern forming step) of obtaining a resist pattern by patterning the photoresist layer by exposure and development, and a step (etching step) of etching the cured layer using the resist pattern as an etching mask.

Hereinafter, each step will be described.

<Cured Layer Forming Step>

In the cured layer forming step, the curable composition according to the embodiment of the present invention is applied to a support and cured to form a cured layer.

As the support, the support in the above-described composition layer forming step is preferably used.

In addition, as a method of applying the curable composition, the applying method in the above-described composition layer forming step is preferably used.

The method of curing the applied curable composition is not particularly limited, and curing by light or heat is preferable.

In a case of curing by light, the light may be appropriately selected depending on the initiator included in the curable composition, and for example, ultraviolet rays such as g-rays and i-rays are preferably used. The exposure dose is preferably 5 to 1,500 mJ/cm², more preferably 10 to 1,000 mJ/cm², and still more preferably 10 to 500 mJ/cm².

In a case of curing by heat, the heating temperature is preferably 120° C. to 250° C. and more preferably 160° C. to 230° C. The heating time varies depending on the heating unit, but in a case of heating on a hot plate, for example, the heating time is preferably 3 to 30 minutes, and in a case of heating in an oven, for example, the heating time is preferably 30 to 90 minutes.

<Photoresist Layer Forming Step>

In the photoresist layer forming step, a photoresist layer is formed on the above-described cured layer.

In the formation of the photoresist layer, for example, a known negative or positive photosensitive composition is used, and a positive photosensitive composition is preferable.

The photoresist layer can be obtained by applying the above-described photosensitive composition to the above-described cured layer and drying the photosensitive composition as necessary.

The method of forming the photoresist layer is not particularly limited, and may be performed by a known method.

The thickness of the photoresist layer is preferably 0.1 to 3 μm, more preferably 0.2 to 2.5 μm, and more preferably 0.3 to 2 μm.

<Resist Pattern Forming Step>

In the resist pattern forming step, a resist pattern is formed by exposing and developing the above-described photoresist layer patternwise.

The above-described exposure and development are not particularly limited, and may be performed by a known method.

<Etching Step>

In the etching step, the above-described cured layer is etched through the above-described resist pattern.

The etching method is not particularly limited and may be performed by a known method. Examples thereof include a dry etching method.

<Step of Peeling Off Resist Pattern>

The second aspect of the method for manufacturing a color filter according to the embodiment of the present invention may further include a step of peeling off the resist pattern after the above-described etching step.

The method of peeling off the resist pattern is not particularly limited, and a known method is used.

(Solid-State Imaging Element)

The solid-state imaging element according to an embodiment of the present invention has the above-described film according to the embodiment of the present invention or the color filter according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiodes on the photodiodes and the transfer electrodes; have a device-protective film formed of silicon nitride or the like, which is formed to cover the entire surface of the light-shielding film and the light receiving portion of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice form by a partition wall. The partition wall in this case preferably has a low refractive index for each colored pixel. Examples of an imaging device having such a structure include the devices described in JP2012-227478A, JP2014-179577A, and WO2018/043654A. An imaging device including the solid-state imaging element according to the embodiment of the present invention can also be used as a vehicle-mounted camera or a monitoring camera, in addition to a digital camera or electronic equipment (mobile phones or the like) having an imaging function.

(Image Display Device)

The image display device according to an embodiment of the present invention has the above-described film according to the embodiment of the present invention or the color filter according to the embodiment of the present invention. Examples of the image display device include a liquid crystal display device or an organic electroluminescence display device. The definitions of image display devices or the details of the respective image display devices are described in, for example, “Electronic Display Device (edited by Akio Sasaki, Kogyo Chosakai Publishing Co., Ltd., published in 1990)”, “Display Device (edited by Sumiaki Ibuki, Sangyo Tosho Co., Ltd., published in 1989)”, and the like. In addition, the details of a liquid crystal display device can be found in, for example, “Next-Generation Liquid Crystal Display Techniques (edited by Tatsuo Uchida, Kogyo Chosakai Publishing Co., Ltd., published in 1994)”. The liquid crystal display device to which the present invention is applicable is not particularly limited. For example, the present invention is applicable to various liquid crystal display devices described in “Next-Generation Liquid Crystal Display Techniques”.

(Polymer Compound)

The polymer compound according to an embodiment of the present invention includes at least one of the above-described constitutional unit represented by Formula (A1) or the above-described constitutional unit a constitutional unit represented by Formula (B1).

The polymer compound according to the embodiment of the present invention is the same as the specific resin in the curable composition according to the embodiment of the present invention, and the preferred aspect is also the same.

### EXAMPLES

Hereinafter, the present invention will be described in detail using Examples. Materials, used amounts, proportions, treatment details, treatment procedures, and the like shown in the following examples can be appropriately changed within a range not departing from the scope of the present invention. Accordingly, the scope of the present invention is not limited to the following specific examples.

<Synthesis of Specific Resin PA-1>

A macromonomer B-1 solution described later having a concentration (solid content) of 50 mass % as a monomer 2, a monomer A-1 as a monomer 1, and propylene glycol 1-monomethyl ether 2-acetate (PGMEA) were charged into a three-neck flask to obtain a mixture.

The above-described mixture was stirred while blowing nitrogen. Next, the mixture was heated to 75° C. while nitrogen into the flask. Next, dodecyl mercaptan (0.82 g), then 2,2′-azobis(methyl 2-methylpropionate) (0.43 g; hereinafter, also referred to as “V-601”) were added to the mixture to initiate the polymerization reaction.

After heating the mixture at 75° C. for 2 hours, an additional V-601 (0.43 g) was added to the mixture. After 2 hours, an additional V-601 (0.43 g) was added to the mixture.

After a further reaction for 2 hours, the mixture was heated to 90° C. and stirred for 3 hours. The polymerization reaction was terminated by the above operation.

After terminating the reaction, dimethyldodecylamine as an amine compound (F-1) and 2,2,6,6-tetramethylpiperidine 1-oxyl (Q-1, TEMPO) as a polymerization inhibitor were added thereto under air, and 4-hydroxybutyl acrylate glycidyl ether (monomer C-1) as a reactive compound was added dropwise thereto.

After completion of the dropwise addition, the reaction was continued in air at 90° C. for 24 hours, and then the completion of the reaction was confirmed by acid value measurement. PGMEA was added to the obtained mixture so as to form a 30 mass % solution, thereby obtaining a resin PA-1.

The amounts of the monomer B-1 (solid content in the solution), the monomer A-1, the monomer C-1, F-1, and Q-1 used were as shown in Table 1.

The weight-average molecular weight of the obtained specific resin PA-1 was 17,200, and the acid value thereof was 70 mgKOH/g.

The specific resin PA-1 is a resin which satisfies the above-described requirement 1 and a resin having a constitutional unit represented by Formula (A1) described above.

—Measuring Method of Weight-Average Molecular Weight—

The weight-average molecular weight (Mw) of each macromonomer and resin was calculated by Gel permeation chromatography (GPC) measurement under the following measurement conditions. The weight-average molecular weight of the resin is shown in Table 1 or Table 2.

Device: HLC-8220GPC (manufactured by Tosoh Corporation)

Detector: differential refractometer (RI detector)

Pre-column: TSKGUARD COLUMN MP(XL) 6 mm×40 mm (manufactured by Tosoh Corporation)

Sample-side column: following 4 columns are directly connected [all manufactured by Tosoh Corporation]

TSK-GEL Multipore-HXL-M 7.8 mm×300 mm

Reference-side column: same as the sample-side column

Constant-temperature tank temperature: 40° C.

Mobile phase: tetrahydrofuran

Sample-side mobile phase flow rate: 1.0 mL/min

Reference-side mobile phase flow rate: 0.3 mL/min

Sample concentration: 0.1 mass %

Sample injection amount: 100 μL

Data collection time: 16 minutes to 46 minutes after sample injection

Sampling pitch: 300 ms (milliseconds)

—Measuring Method of Acid Value—

In addition, the acid value of each resin was determined by neutralization titration using a sodium hydroxide aqueous solution. Specifically, the obtained resin was dissolved in a solvent, the solution was titrated with a sodium hydroxide aqueous solution using a potential difference measurement method to calculate the number of millimoles of the acid included in 1 g of the solid resin, and then the acid value was determined by multiplying the calculated value by 56.1 as a molecular weight of potassium hydroxide (KOH). The acid values of the resin are listed in the column of “Acid value” of Table 1 or Table 2. In Table 1 or Table 2, the unit of acid value is (mgKOH/g).

—Measuring Method of C═C Value (Ethylenically Unsaturated Bonding Value)—

The C═C value of each resin was measured by the following method.

The ethylenically unsaturated bonding value (C═C value) was obtained by extracting a low-molecular-weight component (a) of an ethylenically unsaturated group moiety (for example, in a case where the constitutional unit represented by Formula (D1) of the above-described specific resin had an acryloxy group, acrylic acid) from the specific resin by an alkali treatment, measuring the content thereof by a high performance liquid chromatography (HPLC), and calculating the ethylenically unsaturated bonding value from the following expression based on the measured value.

Specifically, 0.1 g of the specific resin was dissolved in a tetrahydrofuran and methanol-mixed solution (50 mL/15 mL), 10 mL of a 4 mol/L sodium hydroxide aqueous solution was added thereto, and the mixture was reacted at 40° C. for 2 hours. The reaction solution is neutralized with 10.2 mL of a 4 mol/L methanesulfonic acid aqueous solution, the mixed solution to which 5 mL of ion exchange water and 2 mL of methanol are added is transferred to a 100 mL volumetric flask, and then the mixed solution is diluted in the volumetric flask by methanol to prepare a measurement sample for HPLC. Thereafter, the ethylenically unsaturated bonding value is measured under the following conditions. The content of the low-molecular-weight component (a) was calculated from a calibration curve of the low-molecular-weight component (a) prepared separately, and the ethylenically unsaturated bonding value was calculated from the following expression. The C═C values of the specific resin are listed in the column of “C═C value” of Table 1 or Table 2. In Table 1 or Table 2, the unit of C═C value is (mmol/g).

<<Ethylenically Unsaturated Bonding Value Calculation Expression>>

Ethylenically unsaturated bonding value (mmol/g)=(Content (ppm) of low-molecular-weight component (a)/Molecular weight (g/mol) of low-molecular-weight component (a)/(Weighed value (g) of liquid-prepared polymer)×(concentration of solid contents (%) of polymer solution/100)×10)

### —HPLC Measurement Conditions—

Measuring equipment: Agilent-1200 (manufactured by Agilent Technologies, Inc.)

Column: Synergi 4u Polar-RP 80A manufactured by Phenomenex; 250 mm×4.60 mm (inner diameter)+guard column Column temperature: 40° C.

Analysis time: 15 minutes

Flow rate: 1.0 mL/min (maximum liquid delivery pressure: 182 bar (18.2 MPa))

Injection amount: 5 μl

Detection wavelength: 210 nm

Eluent: tetrahydrofuran (for stabilizer-free HPLC)/buffer solution (ion exchange aqueous solution containing 0.2% by volume of phosphoric acid and 0.2% by volume of triethylamine)=55/45 (% by volume)

In the present specification, % by volume is a value at 25° C.

—Measuring Method of Amine Value—

Approximately 0.5 g of the sample was precisely weighed and dissolved in 50 mL of acetic acid, and the mixture was titrated with a 0.1 mol/L acetic acid perchlorate solution using an electric titration method (potentiometric titration) and an automatic potentiometric titrator (AT-710M; manufactured by KYOTO ELECTRONICS MANUFACTURING CO., LTD.). In addition, a blank test was performed in the same manner as described above to make corrections.

Amine value=a×5.611/c

a: consumption amount (mL) of 0.1 mol/L perchloric acid

c: amount (g) of sample

The amine values of the resin are listed in the column of “Amine value” of Table 1 or Table 2. In Table 1 or Table 2, the unit of amine value is (mmol/g).

<Synthesis of Specific Resins PA-2 to PA-25>

PA-2 to PA-22 were synthesized by the same method as the method for synthesizing PA-1, except that the monomer 1, monomer 2, monomer 3, reactive compound, amine compound, and polymerization inhibitor were changed to those shown in Table 1. In a case where the monomer 3 was added, the monomer 3 was further added to the mixture of the monomer 1 and the monomer 2.

In Table 1, the unit of the numerical value described in the column of “Content” is “g”. In Table 1, the components described as “-” were not used.

PA-2 to PA-22 are a resin which satisfies the above-described requirement 1 and a resin having a constitutional unit represented by Formula (A1) described above.

In Table 1, the description in the column of “Constitutional unit A1” is a constitutional unit represented by any one of Formulae (A1-1) to (A1-17) described above, and shows a constitutional unit included in each resin.

<Synthesis of Resin PZ-1>

PZ-1 was synthesized by the same method as the method for synthesizing PA-1, except that the monomer 1, monomer 2, monomer 3, reactive compound, amine compound, and polymerization inhibitor were changed to those shown in Table 1.

Since the resin PZ-1 uses F-8 as the amine compound, the structure in which the quaternary ammonium cation structure and the radically polymerizable group are linked cannot be formed, and the resin PZ-1 is a resin which does not satisfy any of the above-described requirements 1 and 2.

TABLE 1

| | | | | | | | | | | | | | Weight- | | | | |
|---|---|---|---|---|---|---|---|---|---|---|---|---|---|---|---|---|---|
| | | | | | | | | | | | | | average | | | | Con- |
| | | | | | | | | | | | Polymer- | | mole- | | | | stitu- |
| | | | | | | | Reactive | | Amine | | ization | | cular | | | | tional |
| | Monomer 1 | | Monomer 2 | | Monomer 3 | | compound | | compound | | inhibitor | | weight | Acid | C═C | Amine | unit |
| Resin | Type | Content | Type | Content | Type | Content | Type | Content | Type | Content | Type | Content | (Mw) | value | value | value | A1 |
| PA-1 | A-1 | 50.99 | B-1 | 30.39 | — | — | C-1 | 9.01 | F-1 | 9.60 | Q-1 | 0.3 | 17200 | 70 | 0.45 | 0.45 | A1-1 |
| PA-2 | A-1 | 44.14 | B-1 | 41.38 | — | — | C-1 | 8.05 | F-1 | 6.43 | Q-2 | 0.3 | 23300 | 60 | 0.40 | 0.30 | A1-1 |
| PA-3 | A-1 | 48.32 | B-1 | 40.43 | — | — | C-1 | 9.10 | F-1 | 2.15 | Q-1 | 0.3 | 17800 | 65 | 0.45 | 0.10 | A1-1 |
| PA-4 | A-1 | 53.67 | B-1 | 36.54 | — | — | C-1 | 9.14 | F-1 | 0.65 | Q-1 | 0.3 | 14900 | 75 | 0.45 | 0.03 | A1-1 |
| PA-5 | A-1 | 53.67 | — | — | E1-1 | 34.97 | C-1 | 9.19 | F-1 | 2.17 | Q-1 | 0.3 | 23700 | 75 | 0.45 | 0.10 | A1-1 |
| PA-6 | A-1 | 46.81 | B-1 | 43.71 | — | — | C-2 | 7.29 | F-1 | 2.18 | Q-1 | 0.3 | 12400 | 65 | 0.40 | 0.10 | A1-2 |
| PA-7 | A-2 | 35.88 | B-1 | 56.80 | — | — | C-3 | 5.13 | F-1 | 2.19 | Q-1 | 0.1 | 19000 | 65 | 0.40 | 0.10 | A1-3 |
| PA-8 | A-3 | 42.13 | B-1 | 46.06 | — | — | C-4 | 9.61 | F-1 | 2.20 | Q-1 | 0.25 | 12600 | 65 | 0.40 | 0.10 | A1-4 |
| | | | | | | | | | | | Q-3 | 0.25 | | | | | |
| PA-9 | A-4 | 22.46 | B-1 | 67.31 | — | — | C-5 | 8.01 | F-1 | 2.21 | Q-1 | 0.3 | 41600 | 65 | 0.40 | 0.10 | A1-5 |
| PA-10 | A-5 | 23.09 | B-1 | 65.03 | — | — | C-6 | 9.65 | F-1 | 2.22 | Q-1 | 0.2 | 18200 | 65 | 0.40 | 0.10 | A1-6 |
| | | | | | | | | | | | Q-3 | 0.1 | | | | | |
| PA-11 | A-6 | 43.54 | B-1 | 48.54 | — | — | C-7 | 5.69 | F-1 | 2.23 | Q-1 | 0.05 | 41800 | 70 | 0.40 | 0.10 | A1-7 |
| PA-12 | A-7 | 49.23 | B-1 | 43.96 | — | — | C-8 | 4.57 | F-1 | 2.24 | Q-1 | 0.3 | 15600 | 75 | 0.40 | 0.10 | A1-8 |
| PA-13 | A-8 | 45.90 | B-1 | 43.84 | — | — | C-1 | 8.01 | F-1 | 2.25 | Q-1 | 0.3 | 25900 | 75 | 0.40 | 0.10 | A1-9 |
| PA-14 | A-1 | 52.17 | B-2 | 38.81 | — | — | C-1 | 8.01 | F-2 | 1.01 | Q-1 | 0.3 | 13100 | 75 | 0.40 | 0.10 | A1-10 |
| PA-15 | A-1 | 52.17 | B-3 | 38.47 | — | — | C-1 | 8.01 | F-3 | 1.35 | Q-1 | 0.3 | 18000 | 75 | 0.40 | 0.10 | A1-11 |
| PA-16 | A-1 | 52.17 | B-4 | 37.17 | — | — | C-1 | 8.01 | F-4 | 2.65 | Q-1 | 0.3 | 51200 | 75 | 0.40 | 0.10 | A1-12 |
| PA-17 | A-1 | 52.17 | B-5 | 38.31 | — | — | C-1 | 8.01 | F-5 | 1.51 | Q-1 | 0.3 | 15200 | 75 | 0.40 | 0.10 | A1-13 |
| PA-18 | A-1 | 52.17 | B-6 | 38.68 | — | — | C-1 | 8.01 | F-6 | 1.14 | Q-1 | 0.3 | 19600 | 75 | 0.40 | 0.10 | A1-14 |
| PA-19 | A-9 | 18.76 | — | — | E-4 | 54.18 | C-1 | 24.02 | F-7 | 3.04 | Q-1 | 1 | 8900 | 55 | 1.20 | 0.30 | A1-15 |
| PA-20 | A-9 | 18.39 | — | — | E-6 | 63.37 | C-1 | 16.02 | F-2 | 2.22 | Q-1 | 0.6 | 18300 | 75 | 0.80 | 0.10 | A1-16 |
| PA-21 | A-2 | 35.33 | — | — | E-3 | 37.95 | C-1 | 20.02 | F-2 | 6.70 | Q-1 | 0.6 | 14300 | 30 | 1.00 | 0.30 | A1-17 |
| PA-22 | A-1 | 63.40 | — | — | E-5 | 31.36 | C-1 | 3.00 | F-2 | 2.24 | Q-1 | 0.3 | 22100 | 110 | 0.15 | 0.10 | A1-10 |
| PA-23 | A-1 | 40.00 | B-1 | 41.38 | — | — | C-1 | 8.05 | F-1 | 6.43 | Q-2 | 0.3 | 19800 | 64 | 0.40 | 0.30 | A1-1 |
| | A-10 | 4.14 | | | | | | | | | | | | | | | A1-18 |
| PA-24 | A-1 | 40.00 | B-1 | 41.38 | — | — | C-1 | 8.05 | F-1 | 6.43 | Q-2 | 0.3 | 21300 | 68 | 0.40 | 0.30 | A1-1 |
| | A-11 | 4.14 | | | | | | | | | | | | | | | A1-19 |
| PA-25 | A-1 | 40.00 | B-1 | 41.38 | — | — | C-1 | 8.05 | F-1 | 6.43 | Q-2 | 0.3 | 24100 | 59 | 0.40 | 0.30 | A1-1 |
| | A-12 | 4.14 | | | | | | | | | | | | | | | A1-20 |
| PZ-1 | A-9 | 14.95 | — | — | E-1 | 77.26 | C-8 | 4.57 | F-8 | 3.22 | Q-3 | 0.3 | 15300 | 75 | 0.40 | 0.10 | — |

Details of each component shown in Table 1 are shown below.

[Monomer 1]
A-1: ARONIX M-5300, ω-carboxy-polycaprolactone monoacrylate (manufactured by TOAGOSEI CO., LTD.)
A-2: LIGHT ESTER HO-MS, 2-methacryloyloxyethyl succinic acid (manufactured by KYOEISHA CHEMICAL Co., LTD.)
A-3: LIGHT ESTER HOA-HH, 2-acryloyloxyethyl hexahydrophthalic acid (manufactured by KYOEISHA CHEMICAL Co., LTD.)
A-4: βCEA, p-carboxyethyl acrylate (manufactured by DAICEL-ALLNEX LTD.)
A-5: vinylbenzoic acid (manufactured by TOKYO CHEMICAL INDUSTRY CO., LTD.)
A-6: CB-12-methacryloyloxyethyl phthalic acid (manufactured by Shin-Nakamura Chemical Co., Ltd.)
A-7: 12-methacrylamidododecanoic acid (synthetic product, synthesized by a known method)
A-8: 4-(4-(acrylolyloxy)butoxy)benzoic acid (synthetic product, synthesized by a known method)
A-9: methacrylic acid
A-10: vinylsulfonic acid (manufactured by TOKYO CHEMICAL INDUSTRY CO., LTD.)
A-11: vinylphosphonic acid (manufactured by TOKYO CHEMICAL INDUSTRY CO., LTD.)
A-12: 10-(Phosphonooxy)decyl methacrylate (manufactured by FUJIFILM Wako Pure Chemical Corporation)

[Monomer 2]
B-1: synthetic product according to the following synthesis example B1
B-2: synthetic product according to the following synthesis example B2
B-3: synthetic product according to the following synthesis example B3
B-4: Blemmer PSE1300 (manufactured by NOF Corporation.), stearoxypolyethylene glycol monomethacrylate
B-5: Blemmer 75ANEP-600 (manufactured by NOF Corporation), nonylphenoxy(ethylene glycol-polypropylene glycol) monoacrylate
B-6: Blemmer 50POEP800B (manufactured by NOF Corporation), octoxypolyethylene glycol-polypropylene glycol monomethacrylate

By using at least one compound of B-1 to B-6 as the monomer 2, the constitutional unit represented by Formula (D5) described above is introduced into the specific resin.

—Synthesis of B-1—

A method for synthesizing the macromonomer B-1 (also simply referred to as “B-1”), which is the monomer 2, containing a constitutional unit composed of an oxyalkylene carbonyl group is shown below.

ε-caprolactone (1256.62 parts, corresponding to a cyclic compound) and 2-ethyl-1-hexanol (143.38 parts, corresponding to a ring-opening polymerization initiator) were charged into a flask to obtain a mixture. Next, the above-described mixture was stirred while blowing nitrogen.

Next, monobutyltin oxide (0.63 parts) was added to the mixture and the obtained mixture was heated to 90° C. After 6 hours, using ¹H-nuclear magnetic resonance (NMR), it was confirmed that a signal derived from 2-ethyl-1-hexanol in the mixture had disappeared, and then the mixture was heated to 110° C. After continuing the polymerization reaction at 110° C. for 2 hours under nitrogen, it was confirmed by ¹H-NMR that a signal derived from ε-caprolactone had disappeared, and then the temperature was lowered to 80° C. Thereafter, 2,6-di-t-butyl-4-methylphenol (0.78 parts) was added to the mixture containing the above-described compound, and 2-methacryloyloxyethyl isocyanate (174.15 parts) was added dropwise to the obtained mixture over 30 minutes. After 1 hour from the completion of the dropwise addition, it was confirmed by ¹H-NMR that a signal derived from 2-methacryloyloxyethyl isocyanate (MOI) had disappeared, and then propylene glycol monomethyl ether acetate (PGMEA) (1575.57 parts) was added to the mixture to obtain a macromonomer B-1 solution having a concentration of 50 mass %. The structure of the macromonomer B-1 was confirmed by ¹H-NMR. The weight-average molecular weight of the obtained macromonomer B-1 was 3,000.

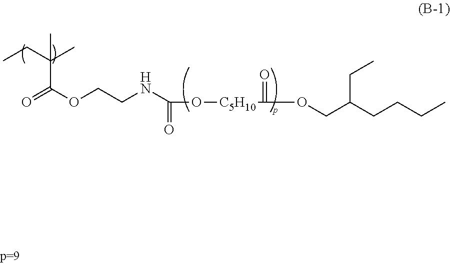

—Synthesis of B-2—

B-2 was synthesized in the same manner as in B-1, except that 2-ethyl-1-hexanol (143.38 g) was changed to stearyl alcohol (297.88 g).

The structure (shown in Formula (B-2)) of B-2 was confirmed by ¹H-NMR. The weight-average molecular weight of the obtained B-2 was 3,400.

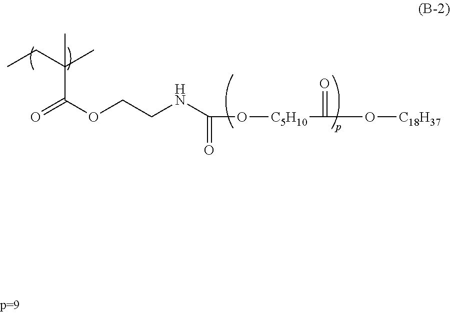

—Synthesis of B-3—

ε-caprolactone (243.45 parts, corresponding to a cyclic compound), S-valerolactone (60.86 parts, corresponding to a cyclic compound), and 2-ethyl-1-hexanol (35.69 parts, corresponding to a ring-opening polymerization initiator) were charged into a flask to obtain a mixture. Next, the above-described mixture was stirred while blowing nitrogen.

Next, monobutyltin oxide (0.156 parts) was added to the mixture and the obtained mixture was heated to 90° C. After 6 hours, using ¹H-nuclear magnetic resonance (NMR), it was confirmed that a signal derived from 2-ethyl-1-hexanol in the mixture had disappeared, and then the mixture was heated to 110° C. After continuing the polymerization reaction at 110° C. for 12 hours under nitrogen, it was confirmed by ¹H-NMR that a signal derived from ε-caprolactone and δ-valerolactone had disappeared, and then the temperature was lowered to 80° C. Thereafter, 2,6-di-t-butyl-4-methylphenol (0.19 parts) was added to the mixture containing the above-described compound, and 2-methacryloyloxyethyl isocyanate (42.52 parts) was added dropwise to the obtained mixture over 30 minutes. After 1 hour from the completion of the dropwise addition, it was confirmed by ¹H-NMR that a signal derived from 2-methacryloyloxyethyl isocyanate (MOI) had disappeared, and then propylene glycol monomethyl ether acetate (PGMEA) (382.87 parts) was added to the mixture to obtain a macromonomer B-3 solution having a concentration of 50 mass %. The structure of the macromonomer B-3 was confirmed by ¹H-NMR. The weight-average molecular weight of the obtained macromonomer B-3 was 3,000.

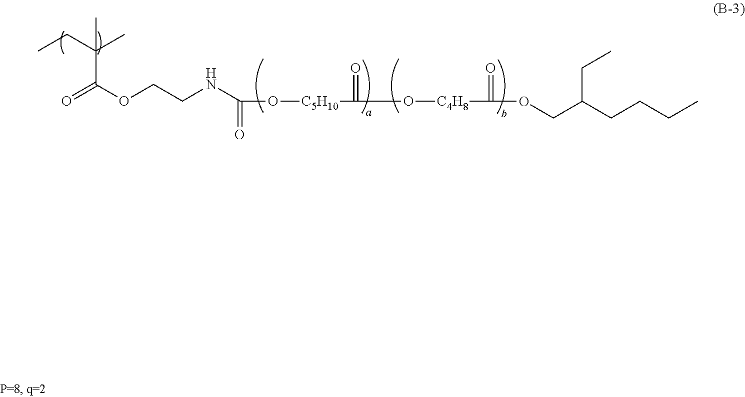

[Monomer 3]
E-1: benzyl methacrylate (manufactured by TOKYO CHEMICAL INDUSTRY CO., LTD.)
E-3: 2-ethylhexyl methacrylate (manufactured by TOKYO CHEMICAL INDUSTRY CO., LTD.)
E-4: ARONIX M120 (manufactured by TOAGOSEI CO., LTD.), 2-(2-((2-ethylhexyl)oxy)ethoxy)ethyl acrylate
E-5: dicyclopentanyl methacrylate (manufactured by TOKYO CHEMICAL INDUSTRY CO., LTD.)
E-6: 2-methoxyethyl acrylate (manufactured by TOKYO CHEMICAL INDUSTRY CO., LTD.)
E-7: 2-(methacryloyloxy)ethyltrimethylammonium chloride (manufactured by TOKYO CHEMICAL INDUSTRY CO., LTD.)

[Reactive Compound]
C-1: 4HBAGE, 4-hydroxybutyl acrylate glycidyl ether (manufactured by Nihon Kasei CO., LTD.)
C-2: 3,4-epoxycyclohexylmethyl acrylate (manufactured by Daicel Corporation)
C-3: glycidyl acrylate (manufactured by TOKYO CHEMICAL INDUSTRY CO., LTD.)
C-4: 9-(oxiran-2-yl)nonyl acrylate (synthetic product below)
C-5: 3-(oxiran-2-ylmethoxy)-3-oxopropyl acrylate (synthetic product below)
C-6: 2-methyl-2-(((oxiran-2-ylmethoxy) carbonyl) amino)propane-1,3-diyl diacrylate (synthetic product below)
C-7: GMA, glycidyl methacrylate (manufactured by TOKYO CHEMICAL INDUSTRY CO., LTD.)
C-8: allyl glycidyl ether (manufactured by TOKYO CHEMICAL INDUSTRY CO., LTD.)
C-9: chloromethylstyrene (manufactured by TOKYO CHEMICAL INDUSTRY CO., LTD.)

—Synthesis of C-4—

153.65 g of 3-chloropropionyl chloride (manufactured by TOKYO CHEMICAL INDUSTRY CO., LTD.) was added dropwise to a flask into which 200 g of 10-undecen-1-ol (manufactured by TOKYO CHEMICAL INDUSTRY CO., LTD.) and 1,378 g of dimethylacetamide (DMAc) was charged while ice cooling, and the mixture was stirred under ice cooling for 1.5 hours. After confirming the disappearance of the raw material alcohol and the target product by ¹H-NMR, the stirring was stopped. After adding 2,000 ml of ethyl acetate thereto, the mixture was washed twice with 2,000 ml of 3.5 mass % hydrochloric acid aqueous solution, and washed twice with 2,000 ml of 5 mass % sodium bicarbonate water, the organic layer was dried over magnesium sulfate, and the solvent was distilled off under reduced pressure to obtain 296 g of an intermediate. To a flask containing 192 g of the intermediate and 918 g of dichloromethane, 200 g of metachloroperbenzoic acid was added in 5 portions every hour under a water bath, and the mixture was stirred overnight.

After confirming by ¹H-NMR that the peak of the terminal double bond of the raw material had disappeared, 1,487 g of 5 mass % sodium bicarbonate water was added to the reaction solution, and the mixture was stirred for 2 hours. Thereafter, 500 ml of ethyl acetate was added thereto for extraction, 500 ml of 5 mass % sodium thiosulfate aqueous solution was added thereto, the mixture was stirred for 1 hour, the aqueous layer was discarded, and the organic layer was concentrated under reduced pressure to obtain 211.5 g of an intermediate.

210 g of the above-described intermediate, 822 g of methylene chloride, and 182.3 mg of p-methoxyphenol was added thereto, and a mixed solution of 231 g of diazabicycloundecene and 441 g of methylene chloride was added dropwise to the mixture while maintaining 10° C. or lower under ice cooling.

The product was confirmed by ¹H-NMR, a mixed solution of 91.1 g of acetic acid and 147 g of methylene chloride was added dropwise thereto while maintaining 10° C. or lower, and the mixture was stirred at room temperature for 2 hours.

The methylene chloride was concentrated under reduced pressure, 1,050 g of hexane was added thereto, and the mixture was washed with 420 g of water and 420 g of 5 mass % sodium bicarbonate water, thereby obtaining 137.9 g of C-4 as a target product.

—Synthesis of C-5—

23.3 g of β-carboxyethyl acrylate, 87 mg of p-methoxyphenol, 117 g of chloroform, 16.8 g of glycidol, and 1.98 g of N,N-dimethylaminopyridine were added in a flask, 37.26 g of 1-(3-dimethylaminopropyl)-3-ethylcarbodiimido hydrochloride was added thereto in portions under ice cooling, and the mixture was stirred for 1 hour. Thereafter, the mixture was washed with 150 ml of 0.1 specified (0.1 mol/L) hydrochloric acid water, washed with 150 ml of water, and the organic layer was concentrated under reduced pressure, thereby obtaining 20 g of C-5 as a target product.

—Synthesis of C-6—

5.0 g of glycidol (manufactured by Sigma-Aldrich Co. LLC), 53 g of butyl acetate, 0.04 g of p-methoxyphenol, 14.5 g of Karenz BEI (manufactured by SHOWA DENKO K.K.), and 0.04 g of NEOSTANN U600 (manufactured by Nitto Kasei Co., Ltd.) were added in a flask, and the mixture was slowly heated to 60° C. After continuing the polymerization reaction at 60° C. for 4 hours, the disappearance of a signal derived from Karenz BEI was confirmed by ¹H-NMR, and 50 g of water was added thereto and the mixture was stirred. The organic layer obtained by separating the mixture and discarding the aqueous layer was washed again with 50 g of water. 3 g of magnesium sulfate was added to the washed organic layer, the washed organic layer was filtered, and 2,6-di-t-butyl-4-methylphenol (0.4 g) was added thereto and concentrated, thereby obtaining 12 g of C-6.

[Amine Compound]
F-1: dimethyldodecylamine (manufactured by TOKYO CHEMICAL INDUSTRY CO., LTD.)
F-2: dimethylbutylamine (manufactured by TOKYO CHEMICAL INDUSTRY CO., LTD.)
F-3: dimethylbenzylamine (manufactured by TOKYO CHEMICAL INDUSTRY CO., LTD.)
F-4: 2,4,6-tris(dimethylaminomethyl) phenol (manufactured by TOKYO CHEMICAL INDUSTRY CO., LTD.)
F-5: 2-(dimethylaminomethyl) phenol
F-6: N,N-dimethylpiperazine (manufactured by TOKYO CHEMICAL INDUSTRY CO., LTD.)
F-7: triethylamine (manufactured by TOKYO CHEMICAL INDUSTRY CO., LTD.)
F-8: tetrabutylammonium bromide (TBAB) (manufactured by TOKYO CHEMICAL INDUSTRY CO., LTD.)

[Polymerization Inhibitor]
Q-1: TEMPO free radical (2,2,6,6-tetramethylpiperidine 1-oxyl)
Q-2: 4-hydroxy-TEMPO free radical (4-hydroxy-2,2,6,6-tetramethylpiperidine 2-oxyl)
Q-3: p-methoxyphenol

<Synthesis of Specific Resin PA-26>

A mixed solution including 36.25 parts by mass of 20 mass % solution of a chain transfer agent CTA-1 (structure below) obtained by the synthesis method described in JP2007-277514A, 18 parts by mass of methacrylic acid, and 20 parts by mass of methyl methacrylate was prepared so as to be a 30 mass % 1-methoxy-2-propanol solution, and the mixed solution was heated to 75° C. under a nitrogen stream.

0.5 parts by mass of azobisisobutyronitrile (AIBN, manufactured by FUJIFILM Wako Pure Chemical Corporation, initiator) was added thereto, the mixture was heated for 3 hours, 0.5 parts by mass of AIBN was added thereto again, and the mixture was reacted at 90° C. for 3 hours under a nitrogen stream. Thereafter, after cooling to room temperature (25° C.; the same applies hereinafter) and replacing with air, 20 parts by mass of 4-hydroxybutyl acrylate glycidyl ether, 4.02 parts by mass of dimethyldodecylamine, and 0.023 parts by mass of 2,2,6,6-tetramethylpiperidine 1-oxyl (TEMPO) were added thereto, and the mixture was heated and stirred at 90° C. for 36 hours.

Thereafter, the mixture was cooled to room temperature and diluted with acetone. After reprecipitation with a large amount of methanol and vacuum drying, 65.1 parts by mass of a solid (specific resin PA-26) including a polymer compound PA-26 (polystyrene-equivalent weight-average molecular weight: 18,600, acid value: 88.5 mgKOH/g, C═C value: 1.44 mmol/g, amine value: 0.27 mmol/g) was obtained.

PA-26 is a resin which satisfies the above-described requirement 1 and a resin having a constitutional unit represented by Formula (A1) described above.

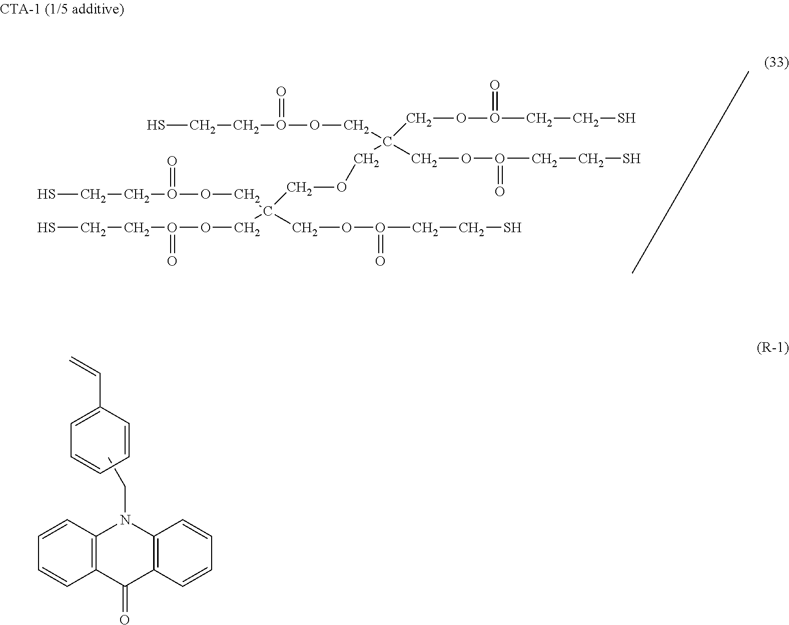

<Synthesis of Specific Resin PA-27>

A mixed solution including 24.17 parts by mass of 30 mass % solution of a chain transfer agent CTA-15 (structure below) obtained by the synthesis method described in JP2007-277514A, 10 parts by mass of methacrylic acid, and 29.59 parts by mass of methyl methacrylate was prepared so as to be a 30 mass % 1-methoxy-2-propanol solution, and the mixed solution was heated to 75° C. under a nitrogen stream. 0.5 parts by mass of V-601 was added thereto, the mixture was heated for 3 hours, 0.5 parts by mass of V-601 was added thereto again, and the mixture was reacted at 90° C. for 3 hours under a nitrogen stream. Thereafter, after cooling to room temperature and replacing with air, 14.21 parts by mass of glycidyl methacrylate, 4 parts by mass of dimethyldodecylamine, and 0.023 parts by mass of TEMPO were added thereto, and the mixture was heated and stirred at 90° C. for 36 hours.

Thereafter, the mixture was cooled to room temperature and diluted with acetone. After reprecipitation with a large amount of methanol and vacuum drying, 51.5 parts by mass of a solid including a polymer compound PA-27 (polystyrene-equivalent weight-average molecular weight: 13,800, acid value: 21 mgKOH/g, C═C value: 1.54 mmol/g, amine value: 0.29 mmol/g) was obtained.

PA-27 is a resin which satisfies the above-described requirement 1 and a resin having a constitutional unit represented by Formula (A1) described above.

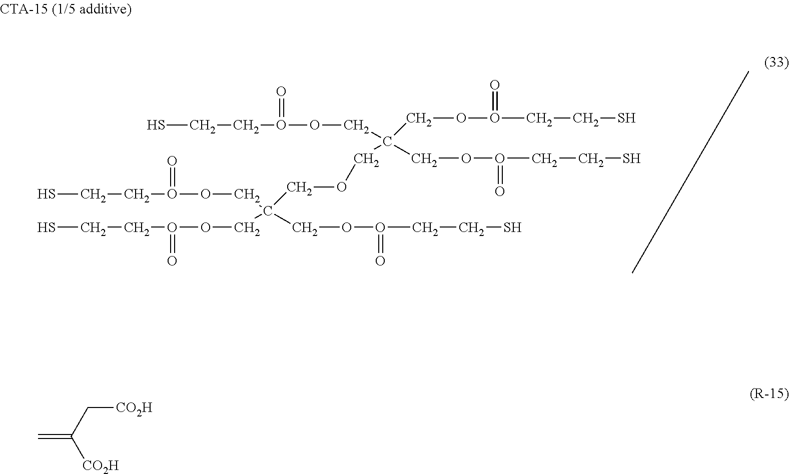

<Synthesis of Specific Resin PB-2>

A macromonomer B-1 solution having a concentration (solid content) of 50 mass % as a monomer 2, ω-carboxy-polycaprolactone monoacrylate as a monomer 1, 2-(dimethylamino)ethyl acrylate as a monomer 4, and 171 g of PGMEA were charged into a three-neck flask to obtain a mixture.

The above-described mixture was stirred while blowing nitrogen. Next, the mixture was heated to 75° C. while nitrogen into the flask. Next, 1.34 g dodecyl mercaptan, then 0.7 g of V-601 were added to the mixture to initiate the polymerization reaction. After heating the mixture at 75° C. for 2 hours, 0.7 g of an additional V-601 was added to the mixture. After 2 hours, 0.7 g of an additional V-601 was added to the mixture.

After a further reaction for 2 hours, the mixture was heated to 90° C. and stirred for 3 hours. The polymerization reaction was terminated by the above operation.

After completion of the reaction, TEMPO (Q-1) was added thereto under air, and 4-hydroxybutyl acrylate glycidyl ether (C-1) was added dropwise thereto.

After the dropwise addition, the reaction was continued for 24 hours under air at 90° C. PGMEA was added to the obtained mixture so as to form a 30 mass % solution, thereby obtaining a resin PB-2.

The amounts of the monomer 2 (solid content in the solution), the monomer 1, the monomer 4, C-1, and Q-1 used were as shown in Table 2.

The weight-average molecular weight of the obtained resin PB-2 was 19,200, and the acid value thereof was 60 mgKOH/mg.

The specific resin PB-2 is a resin which satisfies the above-described requirement 2 and a resin having a constitutional unit represented by Formula (B1) described above.

<Synthesis of Specific Resins PB-1 and PB-3 to PB-18>

PB-1 and PB-3 to PB-18 were synthesized by the same method as the method for synthesizing PA-1, except that the monomer 1, monomer 2, monomer 3, monomer 4, reactive compound, and polymerization inhibitor were changed to those shown in Table 2. In a case where the monomer 3 was added, the monomer 3 was further added to the mixture of the monomer 1, the monomer 2, and the monomer 4.

In Table 2, the unit of the numerical value described in the column of “Content” is “mass %”. In Table 2, the components described as “-” were not used.

In Table 2, the description in the column of “Constitutional unit B1” is a constitutional unit represented by any one of Formulae (B1-1) to (B1-12) described above, and shows a constitutional unit included in each resin.

PB-1 and PB-3 to PB-18 are a resin which satisfies the above-described requirement 2 and a resin having a constitutional unit represented by Formula (B1) described above.

<Synthesis of Resin PZ-2>

PZ-2 was synthesized by the same method as the method for synthesizing PB-2, except that the monomer 1, monomer 2, monomer 3, monomer 4, reactive compound, and polymerization inhibitor were changed to those shown in Table 2.

Since the resin PZ-2 uses E-1 and E-7 as the monomer 4, the structure in which the quaternary ammonium cation structure and the radically polymerizable group are linked cannot be formed, and the resin PZ-2 is a resin which does not satisfy any of the above-described requirements 1 and 2.

TABLE 2

| | | | | | | | | | | | | | Weight- | | | | |
|---|---|---|---|---|---|---|---|---|---|---|---|---|---|---|---|---|---|
| | | | | | | | | | | | | | average | | | | |
| | | | | | | | | | | | Polymer- | | mole- | | | | Con- |
| | | | | | | | Reactive | | | | ization | | cular | | | | stitu- |
| | Monomer 1 | | Monomer 2 | | Monomer 4 | | compound | | Monomer 3 | | inhibitor | | weight | Acid | C═C | Amine | tional |
| Resin | Type | Content | Type | Content | Type | Content | Type | Content | Type | Content | Type | Content | (Mw) | value | value | value | unit B1 |
| PB-1 | A-1 | 50.50 | B-1 | 23.90 | D-1 | 8.59 | C-1 | 12.01 | — | — | Q-1 | 0.3 | 13800 | 70 | 0.60 | 0.60 | B1-1 |
| PB-2 | A-1 | 44.14 | B-1 | 43.56 | D-1 | 4.30 | C-1 | 8.01 | — | — | Q-1 | 0.3 | 19200 | 60 | 0.40 | 0.30 | B1-1 |
| PB-3 | A-1 | 48.32 | B-1 | 41.24 | D-1 | 1.43 | C-1 | 9.01 | — | — | Q-1 | 0.3 | 18800 | 65 | 0.45 | 0.10 | B1-1 |
| PB-4 | A-1 | 53.67 | B-1 | 36.89 | D-1 | 0.43 | C-1 | 9.01 | — | — | Q-1 | 0.3 | 15300 | 75 | 0.45 | 0.03 | B1-1 |
| PB-5 | A-1 | 48.32 | B-1 | 40.82 | D-2 | 1.85 | C-1 | 9.01 | — | — | Q-1 | 0.3 | 21800 | 65 | 0.45 | 0.10 | B1-2 |
| PB-6 | A-1 | 48.32 | B-1 | 40.37 | D-3 | 2.30 | C-1 | 9.01 | — | — | Q-1 | 0.3 | 22100 | 65 | 0.45 | 0.10 | B1-3 |
| PB-7 | A-1 | 48.32 | B-1 | 41.06 | D-4 | 1.61 | C-1 | 9.01 | — | — | Q-1 | 0.3 | 28300 | 65 | 0.45 | 0.10 | B1-4 |
| PB-8 | A-2 | 37.03 | — | — | D-1 | 1.43 | C-2 | 8.20 | E-1 | 53.34 | Q-1 | 0.3 | 31500 | 65 | 0.45 | 0.10 | B1-5 |
| PB-9 | A-3 | 43.48 | B-2 | 49.32 | D-1 | 1.43 | C-3 | 5.77 | — | — | Q-1 | 0.3 | 17100 | 65 | 0.45 | 0.10 | B1-6 |
| PB-10 | A-4 | 23.19 | B-3 | 64.57 | D-1 | 1.43 | C-4 | 10.82 | — | — | Q-1 | 0.3 | 10500 | 65 | 0.45 | 0.10 | B1-7 |
| PB-11 | A-5 | 23.83 | B-4 | 65.73 | D-1 | 1.43 | C-5 | 9.01 | — | — | Q-1 | 0.3 | 52800 | 65 | 0.45 | 0.10 | B1-8 |
| PB-12 | A-6 | 42.51 | B-5 | 45.20 | D-1 | 1.43 | C-6 | 10.86 | — | — | Q-2 | 0.25 | 18400 | 65 | 0.45 | 0.10 | B1-9 |
| | | | | | | | | | | | Q-3 | 0.15 | | | | | |
| PB-13 | A-7 | 45.59 | B-6 | 46.58 | D-1 | 1.43 | C-7 | 6.40 | — | — | Q-1 | 0.3 | 13800 | 65 | 0.45 | 0.10 | B1-10 |
| PB-14 | A-8 | 42.51 | B-1 | 50.92 | D-1 | 1.43 | C-8 | 5.14 | — | — | Q-1 | 0.3 | 27800 | 65 | 0.45 | 0.10 | B1-11 |
| PB-15 | A-9 | 18.98 | — | — | D-1 | 4.30 | C-9 | 18.31 | E-4 | 58.41 | Q-1 | 0.3 | 18300 | 55 | 1.20 | 0.30 | B1-12 |
| PB-16 | A-9 | 18.60 | — | — | D-1 | 1.43 | C-1 | 16.02 | E-6 | 63.95 | Q-1 | 1 | 8100 | 75 | 0.80 | 0.10 | B1-1 |
| PB-17 | A-2 | 35.33 | — | — | D-1 | 4.30 | C-1 | 20.02 | E-3 | 40.35 | Q-2 | 0.3 | 18100 | 30 | 1.00 | 0.30 | B1-1 |
| PB-18 | A-1 | 63.40 | — | — | D-1 | 5.73 | C-1 | 3.00 | E-5 | 27.87 | Q-1 | 0.3 | 16400 | 110 | 0.15 | 0.40 | B1-1 |
| PB-19 | A-1 | 40.00 | B-1 | 43.56 | D-1 | 4.30 | C-1 | 8.01 | — | — | Q-1 | 0.3 | 16600 | 64 | 0.40 | 0.30 | B1-1 |
| | A-10 | 4.14 | | | | | | | | | | | | | | | |
| PB-20 | A-1 | 40.00 | B-1 | 43.56 | D-1 | 4.30 | C-1 | 8.01 | — | — | Q-1 | 0.3 | 17200 | 68 | 0.40 | 0.30 | B1-1 |
| | A-11 | 4.14 | | | | | | | | | | | | | | | |
| PB-21 | A-1 | 40.00 | B-1 | 43.56 | D-1 | 4.30 | C-1 | 8.01 | — | — | Q-1 | 0.3 | 18900 | 59 | 0.40 | 0.30 | B1-1 |
| | A-12 | 4.14 | | | | | | | | | | | | | | | |
| PZ-2 | A-9 | 20.11 | — | — | E-1 | 56.01 | C-8 | 11.41 | — | — | Q-3 | 0.05 | 18100 | 75 | 1.00 | 0.60 | — |
| | | | | | E-7 | 12.46 | | | | | | | | | | | |

Among the components listed in Table 2, components other than those described above are shown below.

[Monomer 4]
D-1: 2-(dimethylamino)ethyl acrylate (manufactured by TOKYO CHEMICAL INDUSTRY CO., LTD.)
D-2: 2-(diethylamino)ethyl methacrylate (manufactured by TOKYO CHEMICAL INDUSTRY CO., LTD.)
D-3: 2-(((2-(dimethylamino)ethoxy)carbonyl)amino)ethyl acrylate (synthetic product, synthesized with reference to Bulletin of the Chemical Society of Japan, 2011, vol. 84, #11, pp. 1215 to 1226)
D-4: N,N-dimethyl-1-(4-vinylphenyl)methylamine (synthetic product, synthesized with reference to Angewandte Chemie—International Edition, 2007, vol. 46, #46, pp. 8869 to 8871)

<Synthesis of Specific Resin PB-19>

A mixed solution including 36.25 parts by mass of 20 mass % solution of a chain transfer agent CTA-1 (structure above) obtained by the synthesis method described in JP2007-277514A, 12 parts by mass of methacrylic acid, 5.46 parts by mass of 2-(dimethylamino)ethyl methacrylate, and 14 parts by mass of methyl methacrylate was prepared so as to be a 30 mass % 1-methoxy-2-propanol solution, and the mixed solution was heated to 75° C. under a nitrogen stream.

0.5 parts by mass of AIBN was added thereto, the mixture was heated for 3 hours, 0.5 parts by mass of AIBN was added thereto again, and the mixture was reacted at 90° C. for 3 hours under a nitrogen stream. Thereafter, after cooling to room temperature (25° C.; the same applies hereinafter) and replacing with air, 15 parts by mass of 4-hydroxybutyl acrylate glycidyl ether and 0.023 parts by mass of TEMPO were added thereto, and the mixture was heated and stirred at 90° C. for 36 hours.

Thereafter, the mixture was cooled to room temperature and diluted with acetone. After reprecipitation with a large amount of methanol and vacuum drying, 62.9 parts by mass of a solid (specific resin PB-19) including a polymer compound PB-19 (polystyrene-equivalent weight-average molecular weight: 14,600, acid value: 67.4 mgKOH/g, C═C value: 1.39 mmol/g, amine value: 0.71 mmol/g) was obtained.

PB-19 is a resin which satisfies the above-described requirement 2 and a resin having a constitutional unit represented by Formula (B1) described above.

<Synthesis of Specific Resin PB-20>

A mixed solution including 24.17 parts by mass of 30 mass % solution of a chain transfer agent CTA-24 (structure below) obtained by the synthesis method described in JP2007-277514A, 14.32 parts by mass of 2-(dimethylamino)ethyl methacrylate, and 6.51 parts by mass of 2-hydroxyethyl methacrylate was prepared so as to be a 30 mass % 1-methoxy-2-propanol solution, and the mixed solution was heated to 75° C. under a nitrogen stream.

0.5 parts by mass of V-601 was added thereto, the mixture was heated for 3 hours, 0.5 parts of V-601 was added thereto again, and the mixture was reacted at 90° C. for 3 hours under a nitrogen stream. Thereafter, after cooling to room temperature (25° C.; the same applies hereinafter) and replacing with air, 20.02 parts by mass of 4-hydroxybutyl acrylate glycidyl ether and 0.023 parts by mass of TEMPO were added thereto, and the mixture was heated and stirred at 90° C. for 36 hours. Thereafter, after cooling to room temperature and replacing with air, 11.96 parts by mass of Karenz BEI manufactured by SHOWA DENKO K.K., 0.61 parts by mass of NEOSTANN U600 manufactured by Nitto Kasei Co., Ltd., and 0.023 parts by mass of TEMPO were added thereto, and the mixture was heated and stirred at 90° C. for 36 hours.

Thereafter, the mixture was cooled to room temperature and diluted with acetone. After reprecipitation with a large amount of methanol and vacuum drying, 57.4 parts by mass of a solid (specific resin PB-20) including a polymer compound PB-20 (polystyrene-equivalent weight-average molecular weight: 19500, acid value: 12.5 mgKOH/g, C═C value: 3.33 mmol/g, amine value: 1.67 mmol/g) was obtained.

PB-20 is a resin which satisfies the above-described requirement 2 and a resin having a constitutional unit represented by Formula (B1) described above.

<Preparation of Pigment Dispersion Liquid>

The pigments, dispersion aids (pigment derivatives), resins, polymerization inhibitors, and solvents described in Tables 3 to 5 were mixed, and then 230 parts by mass of zirconia beads having a diameter of 0.3 mm were added thereto to perform a dispersion treatment for 5 hours using a paint shaker. The beads were separated by filtration, and a dispersion liquid was produced. The numerical values indicating the contents described in Tables 3 to 5 are parts by mass.

In addition, for example, the description of PA-12/P1=1/1, and the like in the column of “Type” of “Resin” in the pigment dispersion liquid R-12 indicates that, as the resin, PA-12 and PT were used at a ratio (mass ratio) of 1/1, and the total amount used was 4.2 parts by mass.

In addition, in Tables 3 to 5, the description of “-” indicates that the corresponding compound is not contained.

TABLE 3

| | | | | | | | Polymerization | | | |
|---|---|---|---|---|---|---|---|---|---|---|
| | Pigment | | Dispersion aid | | Resin | | inhibitor | | Solvent | |
| | | Part by | | Part by | | Part by | | Part by | | Part by |
| | Type | mass | mass | Type | Type | mass | Type | mass | Type | mass |
| R-1 | PR254 | 12.00 | B1 | 1.39 | PA-1 | 4.2 | Q1 | 0.01 | J1 | 82.40 |
| R-2 | PR254 | 12.00 | B1 | 1.39 | PA-2 | 4.2 | Q1 | 0.01 | J1 | 82.40 |
| R-3 | PR254 | 12.00 | B1 | 1.39 | PA-3 | 4.2 | Q1 | 0.01 | J1 | 82.40 |
| R-4 | PR254 | 12.00 | B1 | 1.39 | PA-4 | 4.2 | Q1 | 0.01 | J1 | 82.40 |
| R-5 | PR254 | 12.00 | B1 | 1.39 | PA-5 | 4.2 | Q1 | 0.01 | J1 | 82.40 |
| R-6 | PR254 | 12.00 | B1 | 1.39 | PA-6 | 4.2 | Q1 | 0.01 | J4 | 82.40 |
| R-7 | PR254 | 12.00 | B2 | 1.39 | PA-7 | 4.2 | Q1 | 0.01 | J1 | 82.40 |
| R-8 | PR254 | 12.00 | B1 | 1.39 | PA-8 | 4.2 | Q1 | 0.001 | J1 | 82.41 |
| R-9 | PR254 | 12.00 | B1 | 1.39 | PA-9 | 4.2 | Q2 | 0.01 | J1 | 82.40 |
| R-10 | PR254 | 12.00 | B1 | 1.39 | PA-10 | 3.6 | Q1 | 0.01 | J1 | 83.00 |
| R-11 | PR254 | 12.00 | B1 | 1.39 | PA-11 | 4.2 | Q1 | 0.01 | J1 | 82.40 |
| R-12 | PR254 | 12.00 | B1 | 1.39 | PA-12/ | 4.2 | Q1 | 0.05 | J1 | 82.36 |
| | | | | | P1 = 1/1 | | | | | |
| R-13 | PR254 | 12.00 | B1 | 1.39 | PA-1/ | 4.2 | Q1 | 0.01 | J2 | 82.40 |
| | | | | | PA13 = 1/1 | | | | | |
| R-14 | PR254 | 12.00 | B1 | 1 | PA-14 | 4.8 | Q1 | 0.01 | J1 | 82.19 |
| R-15 | PR254 | 12.00 | B1 | 1.39 | PA-15 | 4.2 | Q1 | 0.01 | J1/ | 82.40 |
| | | | | | | | | | J3 = 1/1 | |
| R-16 | PR254 | 12.00 | B3 | 1.39 | PA-16 | 4.2 | Q1 | 0.01 | J1 | 82.40 |
| R-17 | PR254 | 12.00 | B1 | 1.39 | PA-17 | 4.2 | Q1 | 0.01 | J3 | 82.40 |
| R-18 | PR264 | 12.00 | B1 | 1.39 | PA-18 | 4.2 | Q1 | 0.01 | J1 | 82.40 |
| R-19 | PR272 | 12.00 | B1 | 1.39 | PA-19 | 4.2 | Q1 | 0.01 | J1 | 82.40 |
| R-20 | PR254 | 8.3 | B1 | 2.3 | PA-20 | 4.4 | Q1 | 0.01 | J1 | 81.29 |
| | PY139 | 3.7 | | | | | | | | |
| R-21 | PR254 | 12.00 | B1 | 1.39 | PA-21 | 4.2 | Q1 | 0.01 | J1 | 82.40 |
| R-22 | PR254 | 12.00 | B1 | 1.39 | PA-22 | 4.2 | Q1 | 0.01 | J1 | 82.40 |
| R-23 | PR254 | 12.00 | B1 | 1.39 | PB-1 | 4.2 | Q1 | 0.01 | J1 | 82.40 |
| R-24 | PR254 | 12.00 | B1 | 1.39 | PB-2 | 4.2 | Q1 | 0.01 | J1 | 82.40 |
| R-25 | PR254 | 12.00 | B1 | 1.39 | PB-3 | 4.2 | Q1 | 0.01 | J1 | 82.40 |
| R-26 | PR254 | 12.00 | B3 | 1.39 | PB-4 | 4.2 | Q1 | 0.01 | J1 | 82.40 |
| R-27 | PR254 | 12.00 | B1 | 1.39 | PB-5 | 4.2 | Q1 | 0.01 | J2 | 82.40 |
| R-28 | PR254 | 12.00 | B1 | 1.39 | PB-6 | 4.2 | Q1 | 0.01 | J1 | 82.40 |
| R-29 | PR254 | 12.00 | B1 | 1.39 | PB-7 | 4.2 | Q1 | 0.01 | J1 | 82.40 |
| R-30 | PR254 | 12.00 | B1 | 1.39 | PB-8 | 4.2 | Q1 | 0.01 | J3 | 82.40 |
| R-31 | PR254 | 12.00 | B2 | 1.39 | PB-9 | 4.2 | Q1 | 0.01 | J1 | 82.40 |
| R-32 | PR254 | 12.00 | B1 | 1.39 | PB-1/ | 4.2 | Q1 | 0.01 | J1 | 82.40 |
| | | | | | PB10 = 1/1 | | | | | |
| R-33 | PR254 | 12.00 | B1 | 1.39 | PB-11 | 4.2 | Q1 | 0.01 | J1 | 82.40 |
| R-34 | PR264 | 12.00 | B1 | 1.39 | PB-12 | 4.2 | Q1 | 0.01 | J1 | 82.40 |
| R-35 | PR272 | 12.00 | B1 | 1.39 | PB-13 | 4.2 | Q1 | 0.01 | J1 | 82.40 |
| R-36 | PR254 | 8.3 | B1 | 2.3 | PB-14 | 4.4 | Q1 | 0.01 | J1 | 81.29 |
| | PY139 | 3.7 | | | | | | | | |
| R-37 | PR254 | 12.00 | B1 | 1.39 | PB-15 | 4.2 | Q1 | 0.01 | J1 | 82.40 |
| R-38 | PR254 | 12.00 | B1 | 1.39 | PB-16 | 4.2 | Q1 | 0.01 | J1 | 82.40 |

TABLE 4

| | | | | | | | Polymerization | | | |
|---|---|---|---|---|---|---|---|---|---|---|
| | Pigment | | Dispersion aid | | Resin | | inhibitor | | Solvent | |
| | | Part by | | Part by | | Part by | | Part by | | Part by |
| | Type | mass | Type | mass | Type | mass | Type | mass | Type | mass |
| R-39 | PR254 | 12.00 | B1 | 1.39 | PB-17 | 4.2 | Q1 | 0.01 | J1/ | 82.40 |
| | | | | | | | | | J3 = 1/1 | |
| R-40 | PR254 | 12.00 | B1 | 1.39 | PB-18 | 4.2 | Q1 | 0.01 | J1 | 82.40 |
| R-41 | PR254 | 12.00 | B1 | 1.39 | PA-26 | 4.2 | Q1 | 0.01 | J1 | 82.40 |
| R-42 | PR254 | 12.00 | B1 | 1.39 | PA-27 | 4.2 | Q1 | 0.01 | J1 | 82.40 |
| R-43 | PR254 | 12.00 | B1 | 1.39 | PB-19 | 4.2 | Q1 | 0.01 | J1 | 82.40 |
| R-44 | PR254 | 12.00 | B1 | 1.39 | PB-20 | 4.2 | Q1 | 0.01 | J1 | 82.40 |
| R-45 | PR254 | 12.00 | B1 | 1.39 | PZ-1 | 4.2 | Q1 | 0.01 | J1 | 82.40 |
| R-46 | PR254 | 12.00 | B1 | 1.39 | PZ-2 | 4.2 | Q1 | 0.01 | J1 | 82.40 |
| R-47 | PR254 | 12.00 | B1 | 1.39 | PA-23 | 4.2 | Q1 | 0.01 | J1 | 82.40 |
| R-48 | PR254 | 12.00 | B1 | 1.39 | PA-24 | 4.2 | Q1 | 0.01 | J1 | 82.40 |
| R-49 | PR254 | 12.00 | B1 | 1.39 | PA-25 | 4.2 | Q1 | 0.01 | J1 | 82.40 |
| R-50 | PR254 | 12.00 | B1 | 1.39 | PB-19 | 4.2 | Q1 | 0.01 | J1 | 82.40 |
| R-51 | PR254 | 12.00 | B1 | 1.39 | PB-20 | 4.2 | Q1 | 0.01 | J1 | 82.40 |
| R-52 | PR254 | 12.00 | B1 | 1.39 | PB-21 | 4.2 | Q1 | 0.01 | J1 | 83.01 |
| Y-1 | PY139 | 11.0 | B1 | 1.59 | PA-1 | 4.4 | Q1 | 0.01 | J1 | 83.01 |
| Y-2 | PY139/ | 11.0 | B1 | 1.59 | PA-1 | 4.4 | Q1 | 0.01 | J1 | 83.01 |
| | PY150 = 8/2 | | | | | | | | | |
| Y-3 | PY139 | 11.0 | B1 | 1.59 | C-2 | 4.4 | Q1 | 0.01 | J1 | 83.01 |
| Y-4 | PY150 | 11.0 | B1 | 1.59 | PA-1 | 4.4 | Q1 | 0.01 | J1 | 83.01 |
| Y-5 | PY150 | 11.0 | B1 | 1.59 | C-2 | 4.4 | Q1 | 0.01 | J1 | 83.01 |
| B-1 | PB15:6 | 10.00 | — | — | PA-1 | 5.38 | Q1 | 0.01 | J1 | 83.01 |
| | PV23 | 2.59 | | | | | | | | |
| B-2 | PB15:6 | 10.00 | — | — | PA-3 | 5.38 | Q1 | 0.01 | J1 | 83.01 |
| | PV23 | 2.59 | | | | | | | | |
| B-3 | PB15:6 | 10.00 | — | — | PA-21 | 5.38 | Q1 | 0.01 | J1 | 83.01 |
| | PV23 | 2.59 | | | | | | | | |
| B-4 | PB15:6 | 10.00 | — | — | PB-3 | 5.38 | Q1 | 0.01 | J1 | 83.01 |
| | PV23 | 2.59 | | | | | | | | |
| B-5 | PB15:6 | 10.00 | — | — | PB-15 | 5.38 | Q1 | 0.01 | J1 | 83.01 |
| | PV23 | 2.59 | | | | | | | | |
| B-6 | PB15:6 | 10.00 | — | — | PB-16 | 5.38 | Q1 | 0.01 | J1 | 83.01 |
| | PV23 | 2.59 | | | | | | | | |
| G-1 | PG58 | 9.2 | B1 | 1.2 | PA-3 | 4.95 | Q1 | 0.01 | J1 | 82.34 |
| | PY185 | 2.3 | | | | | | | | |
| G-2 | PG36 | 12.1 | B1 | 1.2 | PA-2 | 4.95 | Q1 | 0.01 | J1 | 79.24 |
| | PY150 | 1.8 | | | | | | | | |
| | PY185 | 0.7 | | | | | | | | |
| G-3 | PG58 | 6.2 | B1 | 1.2 | PA-5 | 4.95 | Q1 | 0.01 | J1 | 82.34 |
| | PG36 | 3.0 | | | | | | | | |
| | PY185 | 2.3 | | | | | | | | |
| G-4 | PG58 | 9.2 | B1 | 1.2 | PB-2 | 4.95 | Q1 | 0.01 | J1 | 82.34 |
| | PY185 | 2.3 | | | | | | | | |

TABLE 5

| | | | | | | | Polymerization | | | |
|---|---|---|---|---|---|---|---|---|---|---|
| | Pigment | | Dispersion aid | | Resin | | inhibitor | | Solvent | |
| | | Part by | | Part by | | Part by | | Part by | | Part by |
| | Type | mass | Type | mass | Type | mass | Type | mass | Type | mass |
| G-5 | PG36 | 12.1 | B1 | 1.2 | PB-4 | 4.95 | Q1 | 0.01 | J1 | 79.24 |
| | PY150 | 1.8 | | | | | | | | |
| | PY185 | 0.7 | | | | | | | | |
| G-6 | PG58 | 6.2 | B1 | 1.2 | PB-8 | 4.95 | Q1 | 0.01 | J1 | 82.34 |
| | PG36 | 3.0 | | | | | | | | |
| | PY185 | 2.3 | | | | | | | | |
| G-7 | PG58 | 6.2 | B1 | 1.2 | PB-15 | 4.95 | Q1 | 0.01 | J1 | 82.34 |
| | PG36 | 3.0 | | | | | | | | |
| | PY185 | 2.3 | | | | | | | | |
| G-8 | PG58 | 6.2 | B1 | 1.2 | PB-16 | 4.95 | Q1 | 0.01 | J1 | 82.34 |
| | PG36 | 3.0 | | | | | | | | |
| | PY185 | 2.3 | | | | | | | | |
| Bk-1 | TiON | 25.00 | — | — | PA-1 | 10 | Q1 | 0.03 | J2 | 64.97 |
| Bk-2 | TiN | 25.00 | — | — | PA-3 | 10 | Q1 | 0.03 | J2 | 64.97 |
| Bk-3 | TiON | 25.00 | — | — | PA-5 | 10 | Q1 | 0.03 | J2 | 64.97 |
| Bk-4 | TiON | 25.00 | — | — | PB-1 | 10 | Q1 | 0.03 | J2 | 64.97 |
| Bk-5 | TiN | 25.00 | — | — | PB-8 | 10 | Q1 | 0.03 | J2 | 64.97 |
| Bk-6 | TiON | 25.00 | — | — | PB-15 | 10 | Q1 | 0.03 | J2 | 64.97 |
| IR-1 | K1 | 11.00 | B1 | 1.59 | PA-1 | 6 | Q1 | 0.01 | J1 | 81.41 |
| IR-2 | K2 | 6.70 | K3 | 0.8 | PA-3 | 6.0 | Q1 | 0.01 | J1 | 86.50 |
| IR-3 | K2 | 6.70 | K4 | 0.8 | PA-5 | 6.0 | Q1 | 0.01 | J1 | 86.50 |
| IR-4 | K1 | 11.00 | B1 | 1.59 | PB-1 | 6 | Q1 | 0.01 | J1 | 81.41 |
| IR-5 | K2 | 6.70 | K3 | 0.8 | PB-8 | 6.0 | Q1 | 0.01 | J1 | 86.50 |
| IR-6 | K2 | 6.70 | K4 | 0.8 | PB-15 | 6.0 | Q1 | 0.01 | J1 | 86.50 |

Details of the materials indicated by the abbreviations in the above tables are as follows.

[Pigment]
PR254: C. I. Pigment Red 254
PR264: C. I. Pigment Red 264
PR272: C. I. Pigment Red 272
PY139: C. I Pigment Yellow 139
PY150: C. I. Pigment Yellow 150
PB15:6: C. I. Pigment Blue 15:6
PV23: C. I Pigment Violet 23
PG58: C. I. Pigment Green 58
PG36: C. I Pigment Green 36
PY185: C. I. Pigment Yellow 185
TiON: titanium oxynitride
TiN: titanium nitride
K1: compound having the following structure
K2: compound having the following structure

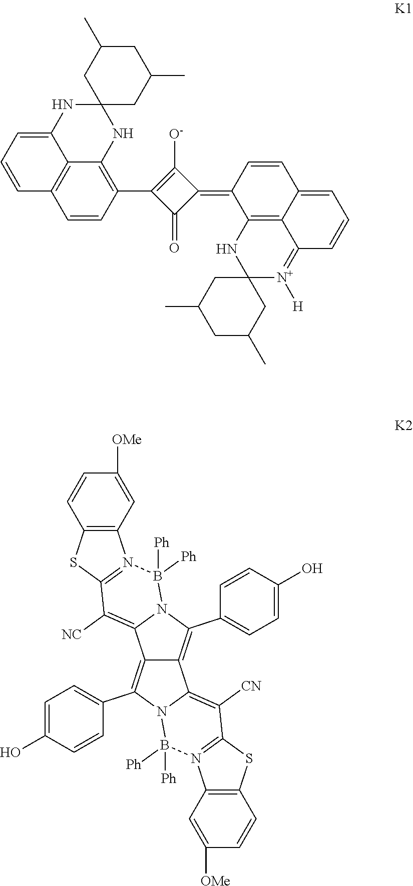

[Dispersion Aid (Pigment Derivative)]
H1 to B3: compounds having the following structures
K3 and K4: compounds having the following structures

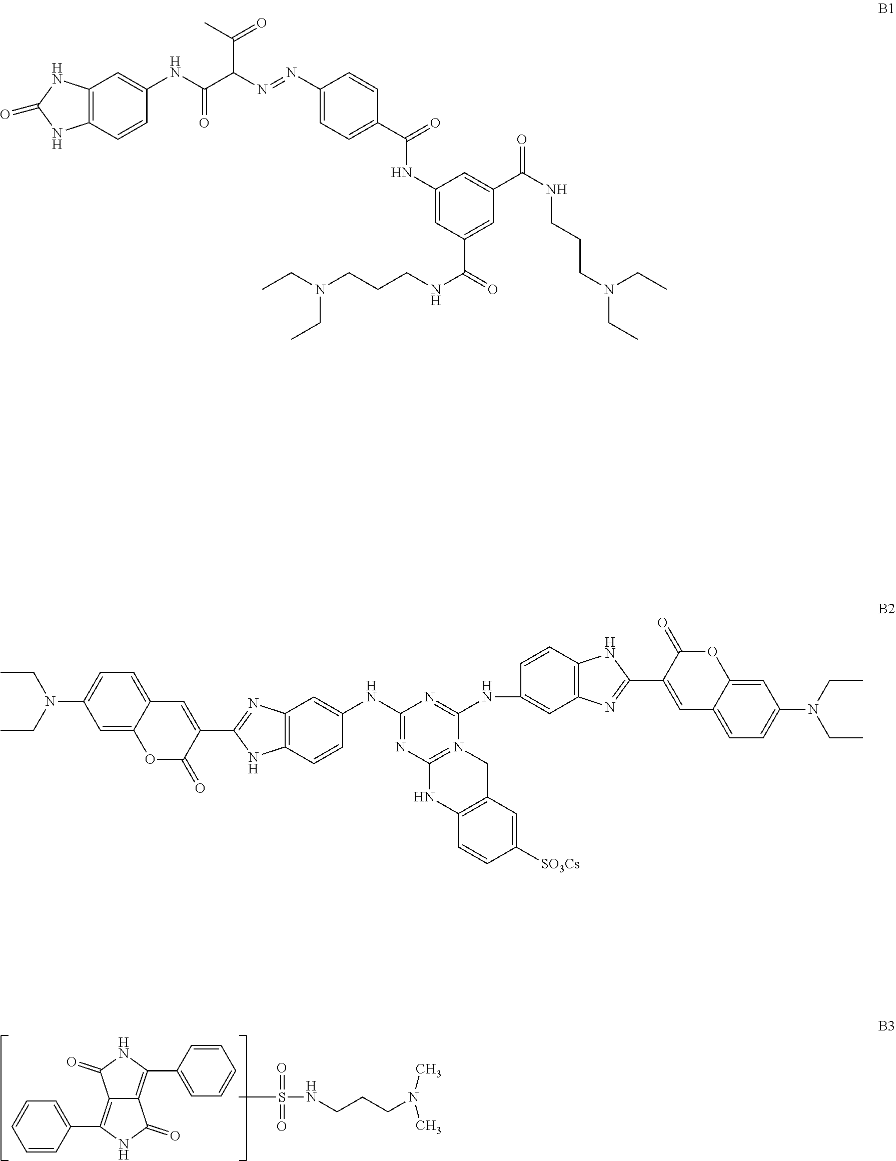

[Resin (Specific Resin)]
PA-1 to PA-27: synthetic products in the above-described synthesis examples
PB-1 to PB-20: synthetic products in the above-described synthesis examples
PZ-1 and PZ-2: synthetic products in the above-described synthesis examples

[Polymerization Inhibitor]
Q1: TEMPO free radical (2,2,6,6-tetramethylpiperidine 1-oxyl)
Q2: 4-hydroxy-TEMPO free radical (4-hydroxy-2,2,6,6-tetramethylpiperidine 2-oxyl)
Q3: p-methoxyphenol

[Solvent]
J1: propylene glycol monomethyl ether acetate (PGMEA)
J2: cyclohexanone
J3: cyclopentanone
J4: propylene glycol monomethyl ether (PGME)

### Examples 1 to 76 and Comparative Examples 1 and 2

In each Example and Comparative Example, raw materials shown in Tables 6 to 8 were mixed to prepare a curable composition.

In Tables 6 to 8, the description of “R-1”, “Y-1” and the like in the column of “Pigment dispersion liquid 1” or “Pigment dispersion liquid 2” means that the above-described “pigment dispersion liquid R-1”, “pigment dispersion liquid Y-1”, and the like were used.

In addition, for example, the description of “R-13/R-19=9/1”, and the like in the column of “Pigment dispersion liquid 1” and the like indicates that, as the pigment dispersion liquid, 44.8 parts by mass of a total of “R-13” and “R-19” was contained, and the content mass ratio of “R-13” and “R-19” was 9:1.

In addition, in Tables 6 to 8, the description of “-” indicates that the corresponding compound is not contained.

TABLE 6

| | | Pigment | | Pigment | | | | Photopoly- | | Polymer- | | | | | | Evaluation result | | | | |
|---|---|---|---|---|---|---|---|---|---|---|---|---|---|---|---|---|---|---|---|---|
| | | dispersion | | dispersion | | Other | | merization | | izable | | | | | | | | De- | | |
| | | liquid 1 | | liquid 2 | | resin | | initiator | | compound | | Surfactant | | Solvent | | Adhe- | | velop- | Stor- | |
| | | | Part | | Part | | Part | | Part | | Part | | Part | | Part | sion | Pat- | ment | age | |
| | | | by | | by | | by | | by | | by | | by | | by | sensi- | tern | resi- | stabi- | De- |
| | | Type | mass | Type | mass | Type | mass | Type | mass | Type | mass | Type | mass | Type | mass | tivity | shape | due | lity | fect |
| Exam- | 1 | R-1 | 42 | Y-1 | 19 | P1 | 1.02 | I1 | 0.45 | M4 | 0.86 | H1 | 4.17 | J1 | 32.5 | 5 | AA | 5 | 5 | 5 |
| ple | 2 | R-2 | 48.2 | Y-1 | 21.2 | — | — | I2 | 0.37 | M5 | 0.1 | H1 | 3.34 | J1 | 26.79 | 5 | AA | 5 | 4 | 5 |
| | 3 | R-3 | 48.2 | Y-1 | 21.2 | — | — | I2 | 0.37 | — | — | H1 | 3.34 | J1 | 26.89 | 3 | A | 5 | 4 | 4 |
| | 4 | R-4 | 44.8 | Y-1 | 20.2 | — | — | I1 | 0.37 | M4 | 0.4 | H1 | 4.17 | J1 | 30.06 | 4 | A | 4 | 4 | 3 |
| | 5 | R-5 | 44.8 | Y-1 | 20.2 | — | — | I1 | 0.37 | M1 | 0.4 | H1 | 4.17 | J1 | 30.06 | 5 | A | 4 | 3 | 4 |
| | 6 | R-6 | 44.8 | Y-1 | 20.2 | — | — | I6 | 0.37 | M4 | 0.4 | H1 | 4.17 | J4 | 30.06 | 4 | A | 4 | 4 | 4 |
| | 7 | R-7 | 44.8 | Y-5 | 20.2 | — | — | I1 | 0.37 | M3 | 0.4 | H1 | 4.17 | J1 | 30.06 | 4 | A | 4 | 4 | 4 |
| | 8 | R-8 | 44.8 | Y-1 | 20.2 | — | — | I1 | 0.37 | M4 | 0.4 | H1 | 4.17 | J1 | 30.06 | 4 | A | 4 | 4 | 4 |
| | 9 | R-9 | 44.8 | Y-1 | 20.2 | — | — | I3 | 0.37 | M4 | 0.4 | H1 | 4.17 | J1 | 30.06 | 4 | A | 4 | 4 | 4 |
| | 10 | R-10 | 42 | Y-1 | 19 | P1 | 1.02 | I1 | 0.45 | M2/ | 0.86 | H1 | 4.17 | J1 | 32.5 | 4 | A | 4 | 4 | 4 |
| | | | | | | | | | | M6 = | | | | | | | | | | |
| | | | | | | | | | | 2/3 | | | | | | | | | | |
| | 11 | R-11 | 44.8 | Y-1 | 20.2 | — | — | I1/ | 0.37 | M4 | 0.4 | H1 | 4.17 | J1 | 30.06 | 4 | A | 4 | 4 | 4 |
| | | | | | | | | I6 = | | | | | | | | | | | | |
| | | | | | | | | 8/2 | | | | | | | | | | | | |
| | 12 | R-12 | 44.8 | Y-1 | 20.2 | — | — | I1 | 0.37 | M4 | 0.4 | H1 | 4.17 | J1 | 30.06 | 4 | A | 4 | 4 | 4 |
| | 13 | R-13/ | 44.8 | Y-1 | 20.2 | — | — | I1 | 0.37 | M4 | 0.4 | H1 | 4.17 | J2 | 30.06 | 5 | A | 4 | 4 | 4 |
| | | R-19 = | | | | | | | | | | | | | | | | | | |
| | | 9/1 | | | | | | | | | | | | | | | | | | |
| | 14 | R-14 | 44.8 | Y-1 | 20.2 | — | — | I1 | 0.37 | M4 | 0.4 | H1 | 4.17 | J1 | 30.06 | 5 | A | 5 | 5 | 4 |
| | 15 | R-15 | 44.8 | Y-3 | 20.2 | — | — | I4 | 0.37 | M4 | 0.4 | H1 | 4.17 | J1/ | 30.06 | 5 | A | 5 | 5 | 4 |
| | | | | | | | | | | | | | | J3 = | | | | | | |
| | | | | | | | | | | | | | | 1/1 | | | | | | |
| | 16 | R-16 | 44.8 | Y-1 | 20.2 | — | — | I1 | 0.37 | M4 | 0.4 | H1 | 4.17 | J1 | 30.06 | 5 | A | 5 | 5 | 4 |
| | 17 | R-17 | 42 | Y-1 | 19 | P1 | 1.02 | I1 | 0.45 | M4 | 0.86 | H1 | 4.17 | J3 | 32.5 | 5 | A | 5 | 5 | 4 |
| | 18 | R-18 | 42 | Y-1 | 19 | P1/ | 1.02 | I1 | 0.45 | M4 | 0.86 | H1 | 4.17 | J1 | 32.5 | 5 | A | 5 | 5 | 4 |
| | | | | | | P2 = | | | | | | | | | | | | | | |
| | | | | | | 1/1 | | | | | | | | | | | | | | |
| | 19 | R-19 | 42 | Y-1 | 19 | P1 | 1.02 | I1 | 0.45 | M4 | 0.86 | H1 | 4.17 | J1 | 32.5 | 5 | AA | 4 | 4 | 3 |
| | 20 | R-20 | 71 | — | — | — | — | I2 | 0.37 | — | — | H1 | 3.34 | J1 | 25.29 | 3 | A | 5 | 3 | 4 |
| | 21 | R-21 | 42 | Y-1 | 19 | P1 | 1.02 | I1 | 0.45 | M4 | 0.86 | H1 | 4.17 | J1 | 32.5 | 5 | AA | 5 | 3 | 5 |
| | 22 | R-22 | 42 | Y-1 | 19 | P1 | 1.02 | I1 | 0.45 | M4 | 0.86 | H1 | 4.17 | J1 | 32.5 | 3 | A | 5 | 3 | 4 |
| | 23 | R-23 | 44.8 | Y-1 | 20.2 | — | — | I1 | 0.37 | M4 | 0.4 | H1 | 4.17 | J1 | 30.06 | 5 | AA | 5 | 5 | 5 |
| | 24 | R-24 | 44.8 | Y-1 | 20.2 | — | — | I1 | 0.37 | M4 | 0.4 | H1 | 4.17 | J1 | 30.06 | 5 | AA | 5 | 4 | 5 |

TABLE 7

| | | Pigment | | Pigment | | | | Photopoly- | | Poly- | | | | | | Evaluation result | | | | |
|---|---|---|---|---|---|---|---|---|---|---|---|---|---|---|---|---|---|---|---|---|
| | | dispersion | | dispersion | | Other | | merization | | merizable | | | | | | | | De- | | |
| | | liquid 1 | | liquid 2 | | resin | | initiator | | compound | | Surfactant | | Solvent | | Adhe- | | velop- | Stor- | |
| | | | Part | | Part | | Part | | Part | | Part | | Part | | Part | sion | Pat- | ment | age | |
| | | | by | | by | | by | | by | | by | | by | | by | sensi- | tern | resi- | stabi- | De- |
| | | Type | mass | Type | mass | Type | mass | Type | mass | Type | mass | Type | mass | Type | mass | tivity | shape | due | lity | fect |
| Exam- | 25 | R-25 | 44.8 | Y-1 | 20.2 | — | — | I1 | 0.37 | M4 | 0.4 | H1 | 4.17 | J1 | 30.06 | 5 | A | 5 | 4 | 4 |
| ple | 26 | R-26 | 44.8 | Y-1 | 20.2 | — | — | I1 | 0.37 | M4 | 0.4 | H1 | 4.17 | J1 | 30.06 | 4 | A | 4 | 4 | 3 |
| | 27 | R-27 | 44.8 | Y-1 | 20.2 | — | — | I1 | 0.37 | M4 | 0.4 | H1 | 4.17 | J2 | 30.06 | 5 | A | 5 | 4 | 4 |
| | 28 | R-28 | 44.8 | Y-3 | 20.2 | — | — | I1 | 0.37 | M4 | 0.4 | H1 | 4.17 | J1 | 30.06 | 5 | A | 5 | 4 | 4 |
| | 29 | R-29 | 44.8 | Y-1 | 20.2 | — | — | I5 | 0.37 | M4 | 0.4 | H1 | 4.17 | J1 | 30.06 | 5 | A | 5 | 4 | 4 |
| | 30 | R-30 | 44.8 | Y-1 | 20.2 | — | — | I1 | 0.37 | M4 | 0.4 | H1 | 4.17 | J3 | 30.06 | 5 | A | 4 | 3 | 4 |
| | 31 | R-31 | 44.8 | Y-1 | 20.2 | — | — | I1 | 0.37 | M4 | 0.4 | H1 | 4.17 | J1 | 30.06 | 4 | A | 4 | 4 | 4 |
| | 32 | R-32 | 44.8 | Y-2 | 20.2 | — | — | I1 | 0.37 | M4 | 0.4 | H1 | 4.17 | J1 | 30.06 | 4 | A | 4 | 4 | 4 |
| | 33 | R-33 | 44.8 | Y-1 | 20.2 | — | — | I1 | 0.37 | M4 | 0.4 | H1 | 4.17 | J1 | 30.06 | 4 | A | 4 | 4 | 4 |
| | 34 | R-34 | 42 | Y-1 | 19 | P1 | 1.02 | I1 | 0.45 | M4 | 0.86 | H1 | 4.17 | J1 | 32.5 | 4 | A | 4 | 4 | 4 |
| | 35 | R-35 | 42 | Y-1 | 19 | P1 | 1.02 | I1 | 0.45 | M4 | 0.86 | H1 | 4.17 | J1 | 32.5 | 4 | A | 4 | 4 | 4 |
| | 36 | R-36 | 71 | — | — | — | — | I2 | 0.37 | — | — | H1 | 3.34 | J1 | 25.29 | 3 | A | 4 | 4 | 4 |
| | 37 | R-37 | 42 | Y-1 | 19 | P1 | 1.02 | I1 | 0.45 | M4 | 0.86 | H1 | 4.17 | J1 | 32.5 | 5 | AA | 4 | 4 | 3 |
| | 38 | R-38 | 42 | Y-1 | 19 | P1 | 1.02 | I1 | 0.45 | M4 | 0.86 | H1 | 4.17 | J1 | 32.5 | 5 | A | 5 | 3 | 4 |
| | 39 | R-39 | 42 | Y-4 | 19 | P1 | 1.02 | I1 | 0.45 | M4 | 0.86 | H1 | 4.17 | J1/ | 32.5 | 5 | AA | 5 | 3 | 5 |
| | | | | | | | | | | | | | | J3 = 1/1 | | | | | | |
| | 40 | R-40 | 42 | Y-1 | 19 | P1 | 1.02 | I1 | 0.45 | M4 | 0.86 | H1 | 4.17 | J1 | 32.5 | 3 | A | 5 | 3 | 4 |
| | 41 | R-41 | 42 | Y-1 | 19 | P1 | 1.02 | I1 | 0.45 | M4 | 0.86 | H1 | 4.17 | J1 | 32.5 | 5 | AA | 5 | 4 | 4 |
| | 42 | R-42 | 42 | Y-1 | 19 | P1 | 1.02 | I1 | 0.45 | M4 | 0.86 | H1 | 4.17 | J1 | 32.5 | 5 | AA | 5 | 4 | 4 |
| | 43 | R-43 | 42 | Y-1 | 19 | P1 | 1.02 | I1 | 0.45 | M4 | 0.86 | H1 | 4.17 | J1 | 32.5 | 5 | AA | 5 | 4 | 4 |
| | 44 | R-44 | 42 | Y-1 | 19 | P1 | 1.02 | I1 | 0.45 | M4 | 0.86 | H1 | 4.17 | J1 | 32.5 | 5 | AA | 5 | 4 | 4 |
| | 45 | R-47 | 48.2 | Y-1 | 21.2 | — | — | I2 | 0.37 | M5 | 0.1 | H1 | 3.34 | J1 | 26.79 | 5 | AA | 5 | 4 | 5 |
| | 46 | R-48 | 48.2 | Y-1 | 21.2 | — | — | I2 | 0.37 | M5 | 0.1 | H1 | 3.34 | J1 | 26.79 | 5 | AA | 5 | 4 | 5 |
| | 47 | R-49 | 48.2 | Y-1 | 21.2 | — | — | I2 | 0.37 | M5 | 0.1 | H1 | 3.34 | J1 | 26.79 | 5 | AA | 5 | 4 | 5 |
| | 48 | R-50 | 44.8 | Y-1 | 20.2 | — | — | I1 | 0.37 | M4 | 0.4 | H1 | 4.17 | J1 | 30.06 | 5 | AA | 5 | 4 | 5 |
| | 49 | R-45 | 44.8 | Y-1 | 20.2 | — | — | I1 | 0.37 | M4 | 0.4 | H1 | 4.17 | J1 | 30.06 | 5 | AA | 5 | 4 | 5 |
| | 50 | R-52 | 44.8 | Y-1 | 20.2 | — | — | I1 | 0.37 | M4 | 0.4 | H1 | 4.17 | J1 | 30.06 | 5 | AA | 5 | 4 | 5 |
| Com- | 1 | R-45 | 44.8 | Y-2 | 20.2 | — | — | I1 | 0.37 | M4 | 0.4 | H1 | 4.17 | J1 | 30.06 | 1 | C | 1 | 1 | 1 |
| para- | 2 | R-46 | 44.8 | Y-2 | 20.2 | — | — | I1 | 0.37 | M4 | 0.4 | H1 | 4.17 | J1 | 30.06 | 1 | C | 1 | 1 | 1 |
| tive | | | | | | | | | | | | | | | | | | | | |
| exam- | | | | | | | | | | | | | | | | | | | | |
| ple | | | | | | | | | | | | | | | | | | | | |

TABLE 8

| | | Pigment | | Pigment | | | | Photopoly- | | Polymer- | | | | | | | | | | |
|---|---|---|---|---|---|---|---|---|---|---|---|---|---|---|---|---|---|---|---|---|
| | | dispersion | | dispersion | | Other | | merization | | izable | | | | | | Evaluation result | | | | |
| | | liquid 1 | | liquid 2 | | resin | | initiator | | compound | | Surfactant | | Solvent | | Adhe- | | De- | Stor- | |
| | | | Part | | Part | | Part | | Part | | Part | | Part | | Part | sion | Pat- | velop- | age | |
| | | | by | | by | | by | | by | | by | | by | | by | sensi- | tern | ment | stabi- | De- |
| | | Type | mass | Type | mass | Type | mass | Type | mass | Type | mass | Type | mass | Type | mass | tivity | shape | residue | lity | fect |
| Exam- | 51 | B-1 | 71.3 | — | — | — | — | I2 | 0.37 | — | — | H1 | 3.34 | J1 | 24.99 | 3 | AA | 5 | 5 | 5 |
| ple | 52 | B-2 | 71 | — | — | — | — | I2 | 0.37 | M4 | 0.3 | H1 | 3.34 | J1 | 24.99 | 5 | A | 5 | 4 | 4 |
| | 53 | B-3 | 71 | — | — | — | — | I2 | 0.37 | M4 | 0.3 | H1 | 3.34 | J1 | 24.99 | 5 | AA | 5 | 3 | 5 |
| | 54 | B-4 | 71 | — | — | — | — | I2 | 0.37 | M4 | 0.3 | H1 | 3.34 | J1 | 24.99 | 5 | A | 5 | 4 | 4 |
| | 55 | B-5 | 71 | — | — | — | — | I2 | 0.37 | M1 | 0.3 | H1 | 3.34 | J1 | 24.99 | 5 | AA | 4 | 4 | 3 |
| | 56 | B-6 | 71.3 | — | — | — | — | I2 | 0.37 | — | — | H1 | 3.34 | J1 | 24.99 | 3 | A | 5 | 3 | 4 |
| | 57 | G-1 | 65 | — | — | — | — | I2 | 0.37 | M4 | 0.3 | H1 | 3.34 | J1 | 30.99 | 5 | A | 5 | 4 | 4 |
| | 58 | G-2 | 68 | — | — | — | — | I2 | 0.37 | M4 | 0.3 | H1 | 3.34 | J1 | 27.99 | 5 | AA | 5 | 4 | 5 |
| | 59 | G-3 | 68 | — | — | — | — | I1 | 0.37 | M4 | 0.4 | H1 | 3.34 | J1 | 27.89 | 5 | A | 4 | 3 | 4 |
| | 60 | G-4 | 65 | — | — | — | — | I2 | 0.37 | M4 | 0.3 | H1 | 3.34 | J1 | 30.99 | 5 | AA | 5 | 4 | 5 |
| | 61 | G-5 | 68 | — | — | — | — | I2 | 0.37 | M4 | 0.3 | H1 | 3.34 | J1 | 27.99 | 4 | A | 4 | 4 | 3 |
| | 62 | G-6 | 68 | — | — | — | — | I1 | 0.37 | M4 | 0.4 | H1 | 3.34 | J1 | 27.89 | 5 | A | 4 | 3 | 4 |
| | 63 | G-7 | 68 | — | — | — | — | I1 | 0.37 | M4 | 0.4 | H1 | 3.34 | J1 | 27.89 | 5 | AA | 4 | 4 | 3 |
| | 64 | G-8 | 68 | — | — | — | — | I1 | 0.37 | M4 | 0.4 | H1 | 3.34 | J1 | 27.89 | 5 | A | 5 | 3 | 4 |
| | 65 | Bk-1 | 65 | — | — | — | — | I1 | 0.37 | M4 | 0.8 | H1 | 3.34 | J1 | 30.49 | 5 | AA | 5 | 5 | 5 |
| | 66 | Bk-2 | 65 | — | — | — | — | I1 | 0.37 | M4 | 0.8 | H1 | 3.34 | J1 | 30.49 | 5 | A | 5 | 4 | 4 |
| | 67 | Bk-3 | 65 | — | — | — | — | I1 | 0.37 | M4 | 0.8 | H1 | 3.34 | J1 | 30.49 | 5 | A | 4 | 3 | 4 |
| | 68 | Bk-4 | 65 | — | — | — | — | I1 | 0.37 | M4 | 0.8 | H1 | 3.34 | J1 | 30.49 | 5 | AA | 5 | 5 | 5 |
| | 69 | Bk-5 | 65 | — | — | — | — | I1 | 0.37 | M4 | 0.8 | H1 | 3.34 | J1 | 30.49 | 5 | A | 4 | 3 | 4 |
| | 70 | Bk-6 | 65 | — | — | — | — | I1 | 0.37 | M4 | 0.8 | H1 | 3.34 | J1 | 30.49 | 5 | AA | 4 | 4 | 3 |
| | 71 | IR-1 | 65 | — | — | — | — | I1 | 0.37 | M4 | 0.8 | H1 | 3.34 | J1 | 30.49 | 5 | AA | 5 | 5 | 5 |
| | 72 | IR-2 | 65 | — | — | — | — | I1 | 0.37 | M4 | 0.8 | H1 | 3.34 | J1 | 30.49 | 5 | A | 5 | 4 | 4 |
| | 73 | IR-3 | 65 | — | — | — | — | I1 | 0.37 | M4 | 0.8 | H1 | 3.34 | J1 | 30.49 | 5 | A | 4 | 3 | 4 |
| | 74 | IR-4 | 65 | — | — | — | — | I1 | 0.37 | M4 | 0.8 | H1 | 3.34 | J1 | 30.49 | 5 | AA | 5 | 5 | 5 |
| | 75 | IR-5 | 65 | — | — | — | — | I1 | 0.37 | M4 | 0.8 | H1 | 3.34 | J1 | 30.49 | 5 | A | 4 | 3 | 4 |
| | 76 | IR-6 | 65 | — | — | — | — | I1 | 0.37 | M4 | 0.8 | H1 | 3.34 | J1 | 30.49 | 5 | AA | 4 | 4 | 3 |

Details of the compounds which are indicated by the abbreviations in Tables 6 to 8 are as follows.

[Other Resins]
P1: resin having the following structure (the numerical value described together with the main chain indicates a molar ratio, Mw=11,000)
P2: resin having the following structure (the numerical value described together with the main chain indicates a molar ratio, Mw=30,000)

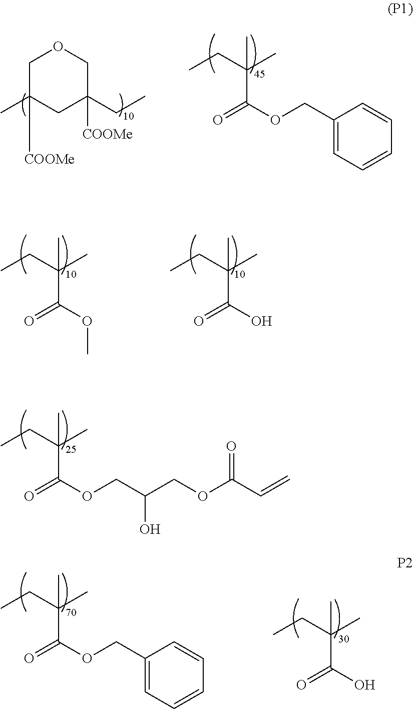

### [Photopolymerization Initiator]

I1: IRGACURE OXE02 (manufactured by BASF)
I2: IRGACURE OXE03 (manufactured by BASF)
I3: IRGACURE OXE04 (manufactured by BASF)
I4: compound having a structure represented by Formula (I4)
I5: ADEKA ARKLS NCI-831 (manufactured by ADEKA Corporation)
I6: IRGACURE 369 (manufactured by BASF)

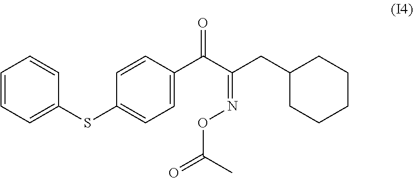 [SMILES: CC(=O)O/N=C(/CC1CCCCC1)C(=O)c1ccc(Sc2ccccc2)cc1]

[Polymerizable Compound]
M1: compound represented by Formula (M), a+b+c=3
M2: compound represented by Formula (M), a+b+c=4
M3: compound represented by Formula (M), compound in which a compound of a+b+c=5 and a compound of a+b+c=6 is mixed at a ratio (mass ratio) of 1:3
M4: dipentaerythritol hexaacrylate (DPHA)
M5: compound represented by Formula (M5)
M6: compound represented by Formula (M6)

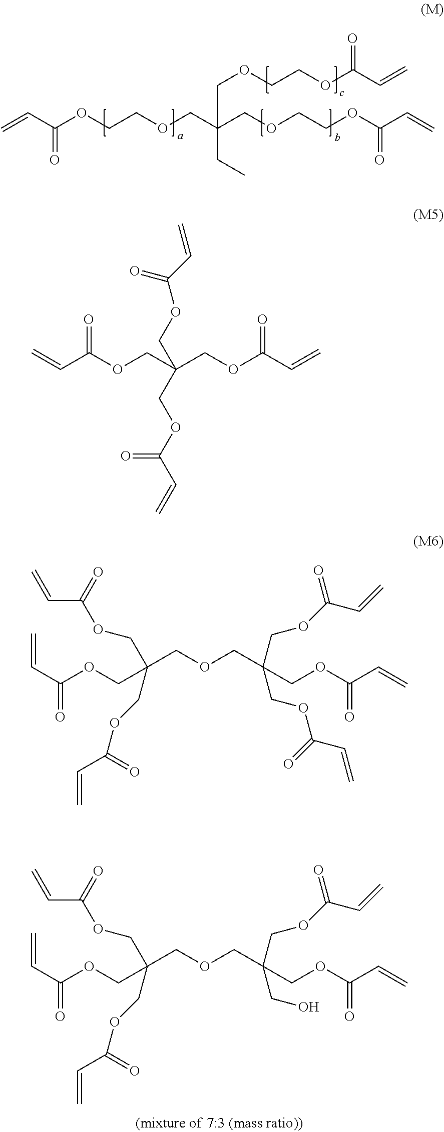

[Surfactant]
H1: MEGAFACE F-781F (manufactured by DIC Corporation)

<Evaluation of Adhesion Sensitivity (Adhesiveness)>

The curable composition obtained in each Example and Comparative Example was applied to an 8-inch (1 inch is 2.54 cm) silicon wafer sprayed with hexamethyldisilazane using a spin coater such that the film thickness after drying was 0.8 μm, and a pre-baking was performed for 120 seconds at 100° C.

Using an i-ray stepper exposure device FPA-i5+ (manufactured by Canon Inc.), the coating film in the coated substrate was irradiated with i-rays having a wavelength of 365 nm at an exposure dose of 50 to 1,700 mJ/cm² through a mask having a 1.1 μm square island pattern. After the exposure, the exposed film was developed using an alkaline developer CD-2000 (manufactured by Fujifilm Electronic Materials Co., Ltd.) at 25° C. for 40 seconds. Next, the developed film was rinsed with flowing water for 30 seconds and was dried by spraying to obtain a colored pattern.

The above-described colored pattern corresponds to a film formed by using the curable composition.

The obtained colored pattern was observed using a scanning electron microscope (S-9220, manufactured by Hitachi, Ltd.) from above the pattern to measure the size of the pattern. In addition, adhesiveness was evaluated using an optical microscope. The pattern size in a case where all the patterns were in closely attached was evaluated on a 5-point scale according to the following evaluation standard. The evaluation results are described in the column of “Adhesion sensitivity” in Tables 6 to 8.

It can be said that the adhesiveness to the support is better as the evaluation result is closer to 5. The evaluation result is preferably 3, 4, or 5, more preferably 4 or 5, and most preferably 5.

[Evaluation Standard]

5: pattern size was 0.9 μm or more and less than 1.0 μm, and was closely attached.

4: pattern size was 1.0 μm or more and less than 1.05 μm, and was closely attached.

3: pattern size was 1.05 μm or more and less than 1.1 μm, and was closely attached.

2: pattern size was 1.1 μm or more and less than 1.2 μm, and was closely attached.

1: adhesion did not occur unless the pattern size was 1.2 μm or more.

<Evaluation of Pattern Shape>

By the following method, a patterned cured product was formed using the curable composition obtained in each Example and Comparative Example, and the edge shape (pattern shape) of the cured product was evaluated.

The above-described patterned cured product corresponds to a film formed by using the curable composition.

[Curable Composition Layer Forming Step]

A curable composition layer (composition film) was formed on a silicon wafer so that the film thickness after drying was 0.9 μm. The curable composition layer was formed by using spin coating. The rotation speed of the spin coating was adjusted so as to obtain the above-described film thickness. The curable composition layer after coating was placed on a hot plate with the silicon wafer facing down and was dried. The surface temperature of the hot plate was set to 100° C. and the drying time was set to 120 seconds.

[Exposing Step]

The obtained curable composition layer was exposed under the following conditions.

The exposure was performed using an i-ray stepper (trade name “FPA-3000 iS+”, manufactured by Canon Inc.). The curable composition film was irradiated (exposed) with i-rays at an exposure dose of 400 mJ/cm² (irradiation time: 0.5 seconds) through a mask having a linear shape of 20 μm (width 20 μm, length 4 mm).

[Developing Step]

The curable composition layer after curing was developed under the following conditions to obtain a patterned cured film.

The curable composition layer after curing was subjected to a puddle development at 23° C. for 60 seconds using a 0.3 mass % tetramethylammonium hydroxide (TMAH) aqueous solution for 5 times to obtain a patterned cured product. Thereafter, the patterned cured product was rinsed using a spin shower, and further washed with pure water.

[Post-Baking Process]

The patterned cured product obtained above was heated at 220° C. for 300 seconds using a clean oven CLH-21CDH (manufactured by Koyo Thermo Systems Co., Ltd.).

Furthermore, the patterned cured product after heating was placed on a hot plate having a surface temperature of 220° C. and heated for 300 seconds.

[Evaluation]

The above-described patterned cured product was imaged with a scanning electron microscope, and the edge shape of the 1.5 μm pattern cross section was evaluated according to the following standard.

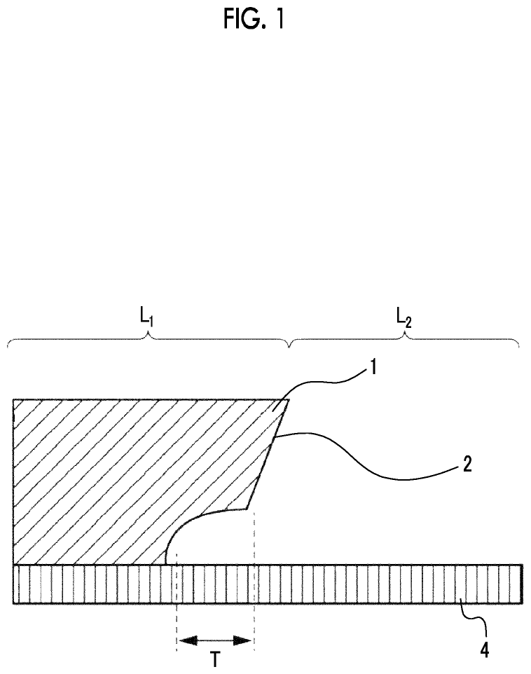

As shown in FIG. 1, a length T of a notch at the bottom of a pattern edge part 2 of a patterned cured product 1 formed on a wafer 4 was measured. In FIG. 1, L₁ corresponds to an exposed area, and L₂ corresponds to an unexposed area. The evaluation was performed according to the following standard. The evaluation results are described in the column of “Pattern shape” in Tables 6 to 8.

It can be said that the pattern shape is excellent as the undercut width is smaller. The evaluation result is preferably A or AA, and more preferably AA.

—Evaluation Standard—

“AA”: undercut width (the above-described length T) was more than 0 μm and 0.05 μm or less.

“A”: undercut width was more than 0.05 μm and 0.15 μm or less.
“B”: undercut width was more than 0.15 μm and 0.25 μm or less.
“C”: undercut width was more than 0.25 μm.

<Evaluation of Storage Stability>

### [1. Exposure Sensitivity of Curable Composition (Initial)]

In each Example and Comparative Example, each curable composition immediately after preparation was applied to a glass substrate by spin coating and dried to form a curable composition layer having a film thickness of 1.0 μm. The conditions of the spin coating were first set at a rotation speed of 300 rpm (rotation per minute) for 5 seconds, and then at 800 rpm for 20 seconds. In addition, the drying condition was set to 100° C. for 80 seconds.

Using an i-ray stepper exposure device FPA-3000 i5+ (manufactured by Canon Inc.), the coating film obtained as described above was irradiated for exposure with light having a wavelength of 365 nm at an exposure dose of 10 to 1,600 mJ/cm² through a pattern mask having 1 μm line and space. Next, the curable composition film after exposure was developed using a 60% CD-2000 (manufactured by Fujifilm Electronic Materials Co., Ltd.) developer at 25° C. for 60 seconds to obtain a patterned cured film. Next, the patterned cured film was rinsed with flowing water for 20 seconds and was air-dried.

The above-described patterned cured film corresponds to a film formed by using the curable composition.

In the above-described exposure, the minimum exposure dose at which the developed pattern line width of the area irradiated with light was 1.0 μm or more was defined as the exposure sensitivity, and this exposure sensitivity was defined as the initial exposure sensitivity.

[2. Exposure Sensitivity of Curable Composition (after Aging: After 30 Days at 45° C.)]

The curable composition immediately after preparation was sealed in an airtight container, kept in an incubator (EYELA/LTI-700) in which the internal temperature was set to 45° C., and taken out after 30 days. Using the taken-out curable composition, the same test as that performed with the curable composition immediately after preparation was performed, and the exposure sensitivity was determined. This exposure sensitivity was defined as the exposure sensitivity after aging.

[Evaluation]

From the initial exposure sensitivity and the exposure sensitivity after aging, the rate (%) of change in exposure sensitivity obtained by the following expression was calculated. As the value of the rate (%) of change is smaller, the storage stability of the curable composition is better.

(Expression) Rate of change=[Exposure sensitivity after aging−Initial exposure sensitivity)/Initial exposure sensitivity]×100

The evaluation results are described in the column of “Storage stability” in Tables 6 to 8. The evaluation result is preferably 3, 4, or 5, more preferably 4 or 5, and most preferably 5.

—Evaluation Standard—

“5”: rate of change was 0% to 3%.

“4”: rate of change was more than 3% and 6% or less.

“3”: rate of change was more than 6% and 10% or less.

“2”: rate of change was more than 10% and 15% or less.

“1”: rate of change was more than 15%.

<Evaluation of Development Residue (Residue in Unexposed Area)>

In the test of [1. Exposure sensitivity of curable composition (initial)] described above, the above-described cured film obtained with the minimum exposure dose such that the pattern line width after development was 1.0 μm or more was heated together with a glass substrate in an oven at 220° C. for 1 hour. After heating the cured film, the number of residues, on the glass substrate, in a region (unexposed area) not irradiated with light during the exposing step was observed using a scanning electron microscope (SEM) (magnification: 20,000 times), and the residue in unexposed area was evaluated. The evaluation was performed according to the following standard, and the results are shown in the column of “Development residue” of Tables 6 to 8.

It can be said that the generation of development residues is suppressed as the number of residues is smaller. The evaluation result is preferably 3, 4, or 5, more preferably 4 or 5, and most preferably 5.

—Evaluation Standard—

“5”: pattern was formed, and no residue was observed in the unexposed area.

“4”: pattern was formed, and 1 to 3 residues were observed in 1.0 μm square of the unexposed area.

“3”: pattern was formed, and 4 to 10 residues were observed in 1.0 μm square of the unexposed area.

“2”: pattern was formed, and 11 or more residues were observed in 1.0 μm square of the unexposed area.

“1”: no pattern was formed due to poor development.

<Evaluation of Sustenance-Defect (Defect)>

The curable composition in each Example and Comparative Example was applied to a glass substrate by a spin coating method so that the film thickness after drying was 0.9 μm, and the glass substrate coated with the curable composition was heated at 100° C. for 2 minutes on a hot plate to obtain a coating film. After 24 hours, a patterned cured product was obtained through exposing, developing, and post-baking processes under the same conditions as in the above-described “Evaluation of pattern shape”.

By observing this patterned cured product using an optical microscope MT-3600LW (manufactured by FLOVEL), the sustenance-defect (presence or absence of foreign matter generation) was evaluated. It can be said that, as the amount of foreign matter is smaller, the storage stability is better and the sustenance-defect is suppressed. The evaluation result is preferably 3, 4, or 5, more preferably 4 or 5, and most preferably 5.

[Evaluation Standard]

“5”: no foreign matter was found on the patterned cured product.

“4”: less than 5 foreign matters were found on the patterned cured product.

“3”: 5 to 10 foreign matters were found on the patterned cured product.

“2”: 11 to 50 foreign matters were found on the patterned cured product.

“1”: 51 to 100 foreign matters were found on the patterned cured product.

### Examples 77 and 78 and Comparative Examples 3 and 4

In each Example and Comparative Example, raw materials shown in Table 9 were mixed to prepare a curable composition.

In Table 9, the description of “R-1”, “Y-1” and the like in the column of “Pigment dispersion liquid 1” or “Pigment dispersion liquid 2” means that the above-described “pigment dispersion liquid R-1”, “pigment dispersion liquid Y-1”, and the like were used.

In addition, in Table 9, the description of “-” indicates that the corresponding compound is not contained.

TABLE 9

| | | | | | | | | | | | | | | | | Evaluation |
|---|---|---|---|---|---|---|---|---|---|---|---|---|---|---|---|---|
| | | Pigment | | Pigment | | | | Photopoly- | | | | | | | | result |
| | | dispersion | | dispersion | | | | merization | | Polymerizable | | | | | | Glass |
| | | liquid 1 | | liquid 2 | | Other resin | | initiator | | compound | | Surfactant | | Solvent | | substrate |
| | | | Part by | | Part by | | Part by | | Part by | | Part by | | Part by | | Part by | adhesion |
| | | Type | mass | Type | mass | Type | mass | Type | mass | Type | mass | Type | mass | Type | mass | sensitivity |
| Example | 77 | R-1 | 42 | Y-1 | 19 | P1 | 1.02 | I1 | 0.45 | M4 | 0.86 | H1 | 4.17 | J1 | 32.5 | 5 |
| | 78 | R-23 | 44.8 | Y-1 | 20.2 | — | — | I1 | 0.37 | M4 | 0.4 | H1 | 4.17 | J1 | 30.06 | 5 |
| Comparative | 3 | R-45 | 44.8 | Y-2 | 20.2 | — | — | I1 | 0.37 | M4 | 0.4 | H1 | 4.17 | J1 | 30.06 | 1 |
| example | 4 | R-46 | 44.8 | Y-2 | 20.2 | — | — | I1 | 0.37 | M4 | 0.4 | H1 | 4.17 | J1 | 30.06 | 1 |

<Evaluation of Glass Substrate Adhesion Sensitivity (Adhesiveness)>

[Production of Glass Substrate with Undercoat Layer]

A glass substrate (Corning 1737) was ultrasonically washed with a 0.5 mass % sodium hydroxide aqueous solution, washed with water, and subjected to a dehydration baking (200° C./20 minutes). Next, CT-4000 (manufactured by Fujifilm Electronic Materials Co., Ltd.) was applied to the washed glass substrate using a spin coater so that the film thickness after drying was 0.1 μm, and the coating film was heated and dried at 220° C. for 1 hour using a hot plate to produce a glass substrate with an undercoat layer.

[Evaluation of Adhesion Sensitivity]

The evaluation was performed by the same method as the evaluation method described in the above-described “Evaluation of adhesion sensitivity (adhesiveness)”, except that the glass substrate with an undercoat layer was used. The evaluation results are described in the column of “Glass substrate adhesion sensitivity” in Table 9.

As described above, as shown in Examples and Comparative Examples, according to the curable composition of Examples, a film having excellent adhesiveness to the support was formed.

The curable composition in Comparative Example 1 did not include a resin satisfying at least one of the requirement 1 or the requirement 2, and a film having excellent adhesiveness to the support was not formed.

The curable composition in Comparative Example 2 did not include a resin satisfying at least one of the requirement 1 or the requirement 2, and a film having excellent adhesiveness to the support was not formed.

### Examples 101 to 164

Any one of a Green composition, a Blue composition, or a Red composition was applied by a spin coating method so that the film thickness after film formation was 1.0 μm, considering that the color did not overlap with the above-described curable composition. For example, the color of the curable compositions of Examples 1 to 50 is red, the color of the curable compositions of Examples 51 to 56 is blue, and the color of the curable compositions of Examples 57 to 64 is green.

A total of three color compositions (any one color composition of Red composition, Green composition, or Blue composition is the composition of Examples 1 to 64) including any one of Red compositions of Examples 1 to 50, Green compositions of Examples 57 to 64, or Blue compositions of Examples 51 to 56, and two compositions selected from the group consisting of a Red composition described below, a Green composition described, below, and a Blue composition described below, in which the color did not overlap with the composition, was prepared.

Next, the coating film was heated using a hot plate at 100° C. for 2 minutes. Next, using an i-ray stepper exposure device FPA-3000 i5+ (manufactured by Canon Inc.), exposure was performed with light having an exposure dose of 1,000 mJ/cm² through a mask having a dot pattern of 2 μm square. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, by heating at 200° C. for 5 minutes using a hot plate, the Red composition, the Green composition, and the Blue composition were respectively patterned to form red, green, and blue colored patterns (Bayer pattern).

The Bayer pattern refers to a pattern, as disclosed in the specification of U.S. Pat. No. 3,971,065A, in which a 2×2 array of color filter element having one Red element, two Green elements, and one Blue element is repeated.

Regarding the obtained solid image pickup element, images were acquired to evaluate the imaging performance. In a case where any one of the compositions obtained in Examples 1 to 64 was used, the image could be clearly recognized even in a low-illuminance environment.

The Red composition, the Green composition, the Blue composition, and the composition for forming an infrared transmitting filter used in Examples 101 to 164 are as follows.

—Red Composition—

The following components were mixed and stirred, and the obtained mixture was filtered through a nylon filter (manufactured by Nihon Pall Corporation) having a pore size of 0.45 μm to prepare a Red composition.

Red pigment dispersion liquid: 51.7 parts by mass

Resin 4 (40 mass % PGMEA solution): 0.6 parts by mass

Polymerizable compound 4: 0.6 parts by mass

Photopolymerization initiator 1: 0.3 parts by mass

Surfactant 1: 4.2 parts by mass

PGMEA: 42.6 parts by mass

—Green Composition—

The following components were mixed and stirred, and the obtained mixture was filtered through a nylon filter (manufactured by Nihon Pall Corporation) having a pore size of 0.45 μm to prepare a Green composition.

Green pigment dispersion liquid: 73.7 parts by mass

Resin 4 (40 mass % PGMEA solution): 0.3 parts by mass

Polymerizable compound 1: 1.2 parts by mass

Photopolymerization initiator 1: 0.6 parts by mass

Surfactant 1: 4.2 parts by mass

Ultraviolet absorber (UV-503, manufactured by Daito Chemical Co., Ltd.): 0.5 parts by mass

PGMEA: 19.5 parts by mass

—Blue Composition—

The following components were mixed and stirred, and the obtained mixture was filtered through a nylon filter (manufactured by Nihon Pall Corporation) having a pore size of 0.45 μm to prepare a Blue composition.

Blue pigment dispersion liquid: 44.9 parts by mass

Resin 4 (40 mass % PGMEA solution): 2.1 parts by mass

Polymerizable compound 1: 1.5 parts by mass

Polymerizable compound 4: 0.7 parts by mass

Photopolymerization initiator 1: 0.8 parts by mass

Surfactant 1: 4.2 parts by mass

PGMEA: 45.8 parts by mass

—Composition for Forming Infrared Transmitting Filter—

Components having the following composition were mixed and stirred, and the obtained mixture was filtered through a nylon filter (manufactured by Nihon Pall Corporation) having a pore size of 0.45 μm to prepare a composition for forming an infrared transmitting filter.

<Composition 100>

Pigment dispersion liquid 1-1: 46.5 parts by mass

Pigment dispersion liquid 1-2: 37.1 parts by mass

Polymerizable compound 5: 1.8 parts by mass

Resin 4: 1.1 parts by mass

Photopolymerization initiator 2: 0.9 parts by mass

Surfactant 1: 4.2 parts by mass

Polymerization inhibitor (p-methoxyphenol): 0.001 parts by mass

Silane coupling agent: 0.6 parts by mass

PGMEA: 7.8 parts by mass

<Composition 101>

Pigment dispersion liquid 2-1: 1,000 parts by mass

Polymerizable compound (dipentaerythritol hexaacrylate): 50 parts by mass

Resin: 17 parts by mass

Photopolymerization initiator (1-[4-(phenylthio)]-1,2-octanedione-2-(O-benzoyloxime)): 10 parts by mass

PGMEA: 179 parts by mass

Alkali-soluble polymer FA-1: 17 parts by mass (concentration of solid contents: 35 parts by mass)

<Synthesis Example of Alkali-Soluble Polymer FA-1>

In a reaction vessel, 14 parts of benzyl methacrylate, 12 parts of N-phenylmaleimide, 15 parts of 2-hydroxyethyl methacrylate, 10 parts of styrene, and 20 parts of methacrylic acid were dissolved in 200 parts of propylene glycol monomethyl ether acetate, and 3 parts of 2,2′-azoisobutyronitrile and 5 parts of α-methylstyrene dimer were further added thereto. After purging the inside of the reaction vessel with nitrogen, the mixture was heated to 80° C. for 5 hours with stirring and nitrogen bubbling to obtain a solution including an alkali-soluble polymer FA-1 (concentration of solid contents: 35 mass %). This polymer had a polystyrene-equivalent weight-average molecular weight of 9,700, a number-average molecular weight of 5,700, and a Mw/Mn of 1.70.

<Pigment Dispersion Liquid 2-1>

60 parts of C. I. Pigment Black 32, 20 parts of C. I. Pigment Blue 15:6, 20 parts of C. I. Pigment Yellow 139, 80 parts (concentration of solid contents: 50 mass %) of SOLSPERSE 76500 manufactured by Lubrizol Corporation, 120 parts (concentration of solid contents: 35 mass %) of a solution including the alkali-soluble polymer FA-1, and 700 parts of propylene glycol monomethyl ether acetate were mixed, and the mixture was dispersed for 8 hours using a paint shaker to obtain a colorant dispersion liquid 2-1.

Raw materials used in the Red composition, the Green composition, the Blue composition, and the composition for forming an infrared transmitting filter are as follows.

Red Pigment Dispersion Liquid

A mixed solution consisting of 9.6 parts by mass of C. I. Pigment Red 254, 4.3 parts by mass of C. I. Pigment Yellow 139, 6.8 parts by mass of a dispersant (Disperbyk-161, manufactured by BYK Chemie), and 79.3 parts by mass of PGMEA was mixed and dispersed using a beads mill (zirconia beads; diameter: 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times. As a result, a Red pigment dispersion liquid was obtained.

Green Pigment Dispersion Liquid

A mixed solution consisting of 6.4 parts by mass of C. I. Pigment Green 36, 5.3 parts by mass of C. I. Pigment Yellow 150, 5.2 parts by mass of a dispersant (Disperbyk-161, manufactured by BYK Chemie), and 83.1 parts by mass of PGMEA was mixed and dispersed using a beads mill (zirconia beads; diameter: 0.3 mm) for 3 hours to prepare a pigment dispersion liquid.

Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times. As a result, a Green pigment dispersion liquid was obtained.

Blue Pigment Dispersion Liquid

A mixed solution consisting of 9.7 parts by mass of C. I. Pigment Blue 15:6, 2.4 parts by mass of C. I. Pigment Violet 23, 5.5 parts of a dispersant (Disperbyk-161, manufactured by BYK Chemie), and 82.4 parts of PGMEA was mixed and dispersed using a beads mill (zirconia beads; diameter: 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times. As a result, a Blue pigment dispersion liquid was obtained.

Pigment Dispersion Liquid 1-1

A mixed solution having the composition shown below was mixed and dispersed for 3 hours using a beads mill (a high-pressure disperser with a pressure reducing mechanism, NANO-3000-10 (manufactured by Nippon BEE Chemical Co., Ltd.)) in which zirconia beads having a diameter of 0.3 mm were used. As a result, a pigment dispersion liquid 1-1 was prepared.
Mixed pigment consisting of a red pigment (C. I. Pigment Red 254) and a yellow pigment (C. I. Pigment Yellow 139): 11.8 parts by mass
Resin (Disperbyk-111, manufactured by BYK Chemie): 9.1 parts by mass
PGMEA: 79.1 parts by mass

Pigment Dispersion Liquid 1-2

A mixed solution having the composition shown below was mixed and dispersed for 3 hours using a beads mill (a high-pressure disperser with a pressure reducing mechanism, NANO-3000-10 (manufactured by Nippon BEE Chemical Co., Ltd.)) in which zirconia beads having a diameter of 0.3 mm were used. As a result, a pigment dispersion liquid 1-2 was prepared.
Mixed pigment consisting of a blue pigment (C. I. Pigment Blue 15:6) and a violet pigment (C. I. Pigment Violet 23): 12.6 parts by mass
Resin (Disperbyk-111, manufactured by BYK Chemie): 2.0 parts by mass
Resin A: 3.3 parts by mass
Cyclohexanone: 31.2 parts by mass
PGMEA: 50.9 parts by mass

Resin A: following structure (Mw=14,000, a ratio in a constitutional unit is a molar ratio)

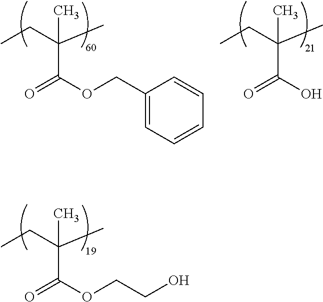

Polymerizable compound 1: KAYARAD DPHA (mixture of dipentaerythritol hexaacrylate and dipentaerythritol pentaacrylate, manufactured by Nippon Kayaku Co., Ltd.)
Polymerizable compound 4: following structure

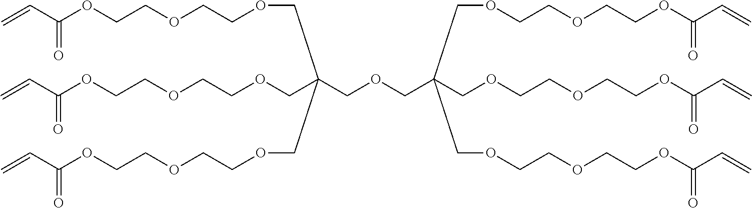 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Polymerizable compound 5: following structure (mixture in which a molar ratio between a left compound and a right compound is 7:3)

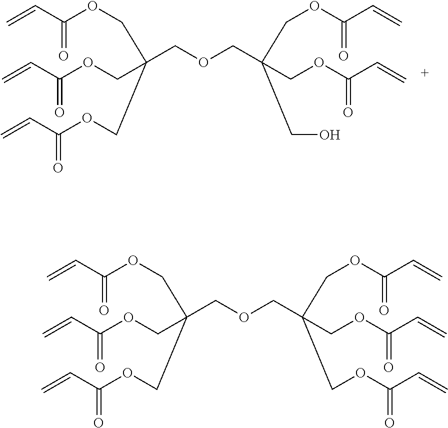

Resin 4: following structure (acid value: 70 mgKOH/g, Mw=11,000; a ratio in a constitutional unit is a molar ratio)

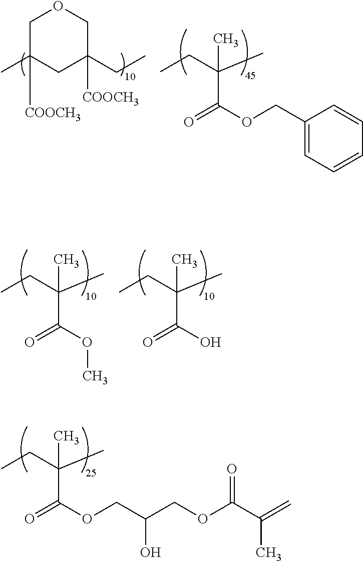

Photopolymerization initiator 1: IRGACURE-OXE01 (1-[4-(phenylthio)]-1,2-octanedione-2-(O-benzoyloxime), manufactured by BASF)
Photopolymerization initiator 2: following structure

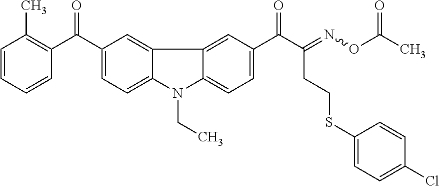 [SMILES: CCn1c2ccc(C(=O)C(CCSc3ccc(Cl)cc3)=NOC(C)=O)cc2c2cc(C(=O)c3ccccc3C)ccc21]

Surfactant 1: 1 mass % PGMEA solution of the following mixture (Mw: 14,000; in the following formula, the unit of % (62% and 38%) indicating the proportion of a constitutional unit is mass %)

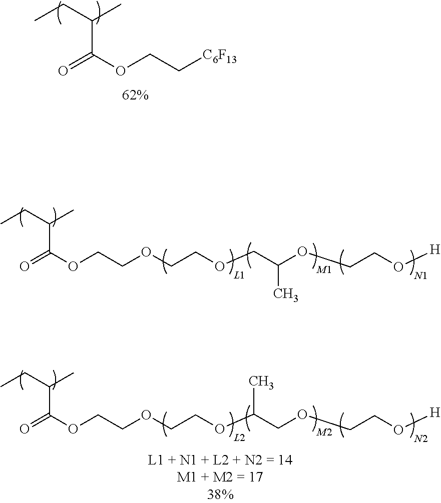

Silane coupling agent: compound having the following structure (in the following structural formula, Et represents an ethyl group)

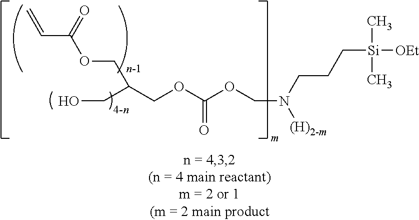

### EXPLANATION OF REFERENCES

1: cured product
2: pattern edge part of cured product
4: support (wafer)
L₁: exposed area
L₂: unexposed area
T: length of notch at bottom of pattern edge part of cured product

What is claimed is:

1. A curable composition comprising:
a pigment; and
a resin which satisfies at least one of the following requirement 1 or the following requirement 2,
requirement 1: the resin includes a constitutional unit having, in the same side chain, an anionic structure, a quaternary ammonium cationic structure which is ionically bonded to the anionic structure, and a radically polymerizable group,
requirement 2: the resin includes a constitutional unit having, in a side chain, a quaternary ammonium cationic structure and a group to which a radically polymerizable group is linked.

2. The curable composition according to claim 1,
wherein the resin includes at least one of a constitutional unit represented by Formula (A1) or a constitutional unit represented by Formula (B1), 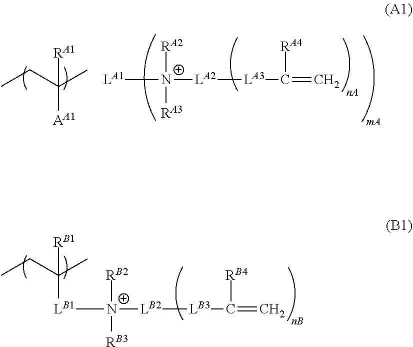
in Formula (A1), R^{A1} represents a hydrogen atom or an alkyl group,
A^{A1} represents a structure including a group in which a proton is separated from an acid group,
R^{A2} and R^{A3} each independently represent an alkyl group or an aralkyl group,
L^{A1} represents a monovalent substituent in a case where mA is 1, or represents a mA-valent linking group in a case where mA is 2 or more,
L^{A2} represents an (nA+1)-valent linking group,
L^{A3} represents a divalent linking group,
R^{A4} represents a hydrogen atom or an alkyl group,
nA represents an integer of 1 or more, and
mA represents an integer of 1 or more,
where in a case where mA is 2 or more, two or more R^{A2}'s, two or more R^{A3}'s, and two or more L^{A2}'s may be the same or different from each other,
in a case where mA is 2 or more, at least one of mA pieces of structures including a quaternary ammonium cation, which is selected from the group consisting of R^{A2} and R^{A3} included in one structure, may form a ring structure with at least one selected from the group consisting of R^{A2} and R^{A3} included in another structure,
in a case where at least one selected from the group consisting of nA and mA is 2 or more, two or more L^{A3}'s and two or more R^{A4}'s may be the same or different from each other, and
at least two of R^{A2}, R^{A3}, or L^{A2} may be bonded to each other to form a ring,
in Formula (B1), R^{B1} represents a hydrogen atom or an alkyl group,
L^{B1} represents a divalent linking group,
R^{B2} and R^{B3} each independently represent an alkyl group,
L^{B2} represents an (nB+1)-valent linking group,
L^{B3} represents a divalent linking group,
R^{B4} represents a hydrogen atom or an alkyl group, and
nB represents an integer of 1 or more,
where in a case where nB is 2 or more, two or more L^{B3}'s and two or more R^{B4}'s may be the same or different from each other, and
at least two of R^{B2}, R^{B3} L^{B1}, or L^{B2} may be bonded to each other to form a ring.

3. The curable composition according to claim 2,
wherein nA in Formula (A1) is 1 and a bond between L^{A2} and L^{A3} represents any one of groups represented by Formulae (C1) to (C4), or
nB in Formula (B1) is 1 and L^{B2} and L^{B3} represent any one of groups represented by Formulae (C1) to (C4), 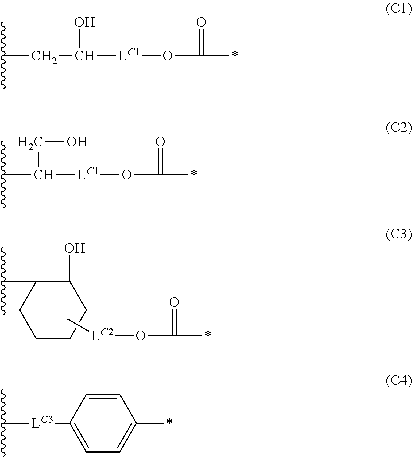
in Formulae (C1) to (C4), L^{C1}, L^{C2}, and L^{C3} each independently represent a single bond or a divalent linking group,
a wavy line part represents a bonding site with a nitrogen atom in Formula (A1) or Formula (B1), and
* represents a bonding site with a carbon atom to which R^{A4} in Formula (A1) is bonded or a carbon atom to which R^{B4} in Formula (B1) is bonded.

4. The curable composition according to claim 2,
wherein a content of the constitutional unit represented by Formula (A1) and a content of the constitutional unit represented by Formula (B1) in the resin are 1 mass % to 60 mass %.

5. The curable composition according to claim 2,
wherein the resin has a radically polymerizable group and further includes a constitutional unit D which is different from the constitutional unit represented by Formula (A1) and the constitutional unit represented by Formula (B1).

6. The curable composition according to claim 5,
wherein the resin further includes a constitutional unit represented by Formula (D1) as the constitutional unit D, 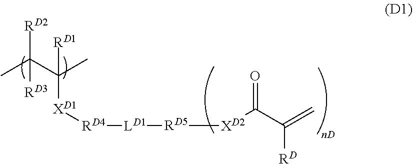
in Formula (D1), R^{D1} to R^{D3} each independently represent a hydrogen atom or an alkyl group,
X^{D1} represents —COO—, —CONR^{D6}—, or an arylene group, where R^{D6} represents a hydrogen atom, an alkyl group, or an aryl group,
R^{D4} represents a divalent linking group,
L^{D1} represents a group represented by Formula (D2), Formula (D3), or Formula (D3′),
R^{D5} represents an (n+1)-valent linking group,
X^{D2} represents an oxygen atom or NR^{D7}—, where R^{D7} represents a hydrogen atom, an alkyl group, or an aryl group,
R^{D} represents a hydrogen atom or a methyl group, and
nD represents an integer of 1 or more,
where in a case where nD is 2 or more, two or more X^{D2}'s and two or more R^{D}'s may be the same or different from each other, 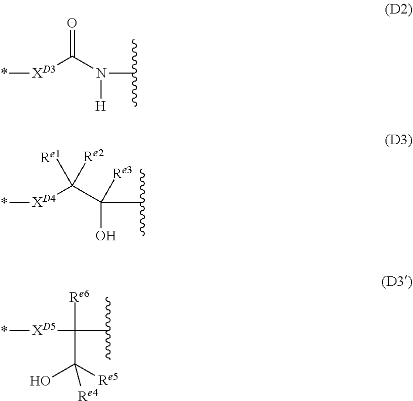
in Formulae (D2), (D3), and (D3′), X^{D3} represents an oxygen atom or —NH—,
X^{D4} represents an oxygen atom or —COO—,
R^{e1} to R^{e3} each independently represent a hydrogen atom or an alkyl group, where at least two of R^{e1} to R^{e3} may be bonded to each other to form a ring structure,
X^{D5} represents an oxygen atom or —COO—,
R^{e4} to R^{e6} each independently represent a hydrogen atom or an alkyl group, where at least two of R^{e4} to R^{e6} may be bonded to each other to form a ring structure, and
* and a wavy line part represent a bonding position with other structures.

7. The curable composition according to claim 1,
wherein the resin further includes a constitutional unit represented by Formula (D5), 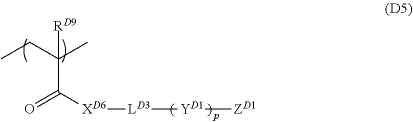
in Formula (D5), R^{D9} represents a hydrogen atom or an alkyl group,
X^{D6} represents an oxygen atom or NR^{C}—, where R^{C} represents a hydrogen atom, an alkyl group, or an aryl group,
L^{D3} represents a divalent linking group,
Y^{D1} represents an alkyleneoxy group or an alkylenecarbonyloxy group,
Z^{D1} represents an aliphatic hydrocarbon group having 1 to 20 carbon atoms or an aromatic hydrocarbon group having 6 to 20 carbon atoms, and
p represents an integer of 1 or more, where in a case where p is 2 or more, p pieces of Y^{D1}'s may be the same or different from each other.

8. The curable composition according to claim 1, further comprising:
an oxime compound as a photopolymerization initiator.

9. The curable composition according to claim 1, further comprising:
a polymerizable compound.

10. The curable composition according to claim 1,
wherein the curable composition is used for forming a colored layer or an infrared absorbing layer of a color filter.

11. A film formed from the curable composition according to claim 1.

12. A color filter formed from the curable composition according to claim 1.

13. A method for manufacturing a color filter, comprising:
a step of forming a composition layer on a support by applying the curable composition according to claim 1 to the support;
a step of patternwise exposing the composition layer; and
a step of forming a colored pattern by developing and removing an unexposed area.

14. A method for manufacturing a color filter, comprising:
a step of forming a composition layer on a support by applying the curable composition according to claim 1 to the support, and curing the composition layer to form a cured layer;
a step of forming a photoresist layer on the cured layer;
a step of obtaining a resist pattern by patterning the photoresist layer by exposure and development; and
a step of etching the cured layer using the resist pattern as an etching mask.

15. A solid-state imaging element comprising:
the film according to claim 11.

16. An image display device comprising:
the film according to claim 11.

17. A polymer compound comprising:
at least one of a constitutional unit represented by Formula (A1) or a constitutional unit represented by Formula (B1), 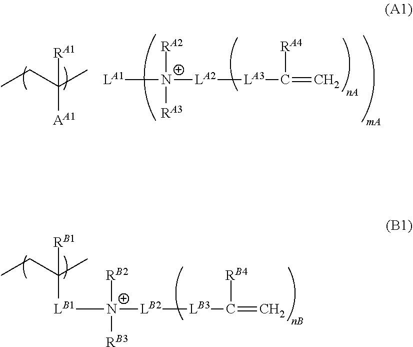
in Formula (A1), R^{A1} represents a hydrogen atom or an alkyl group,
A^{A1} represents a structure including a group in which a proton is separated from an acid group,
R^{A2} and R^{A3} each independently represent an alkyl group or an aralkyl group,
L^{A1} represents a monovalent substituent in a case where mA is 1, or represents a mA-valent linking group in a case where mA is 2 or more,
L^{A2} represents an (nA+1)-valent linking group,
L^{A3} represents a divalent linking group,
R^{A4} represents a hydrogen atom or an alkyl group,
nA represents an integer of 1 or more, and
mA represents an integer of 1 or more,
where in a case where mA is 2 or more, two or more R^{A2}'s, two or more R^{A3}'s, and two or more L^{A2}'s may be the same or different from each other,
in a case where mA is 2 or more, at least one of mA pieces of structures including a quaternary ammonium cation, which is selected from the group consisting of R^{A2} and R^{A3} included in one structure, may form a ring structure with at least one selected from the group consisting of R^{A2} and R^{A3} included in another structure,
in a case where at least one selected from the group consisting of nA and mA is 2 or more, two or more L^{A3}'s and two or more R^{A4}'s may be the same or different from each other, and
at least two of R^{A2}, R^{A3}, or L^{A2} may be bonded to each other to form a ring,
in Formula (B1), R^{B1} represents a hydrogen atom or an alkyl group,
L^{B1} represents a divalent linking group,
R^{B2} and R^{B3} each independently represent an alkyl group,
L^{B2} represents an (nB+1)-valent linking group,
L^{B3} represents a divalent linking group,
R^{B4} represents a hydrogen atom or an alkyl group, and
nB represents an integer of 1 or more,
where in a case where nB is 2 or more, two or more L^{B3}'s and two or more R^{B4}'s may be the same or different from each other, and
at least two of R^{B2}, R^{B3} L^{B1}, or L^{B2} may be bonded to each other to form a ring.

18. The polymer compound according to claim 17,
wherein nA in Formula (A1) is 1 and a bond between LA² and LA³ represents any one of groups represented by Formulae (C1) to (C4), or
nB in Formula (B1) is 1 and L^{B2} and L^{B3} represent any one of groups represented by Formulae (C1) to (C4), 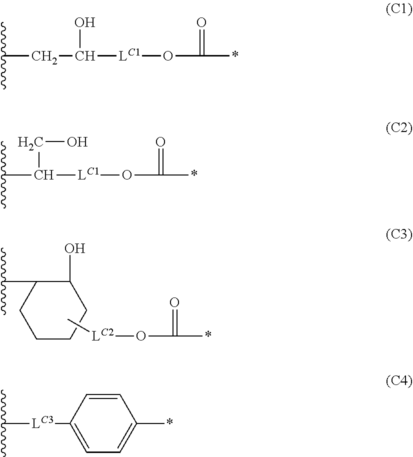
in Formulae (C1) to (C4), L^{C1}, L^{C2}, and L^{C3} each independently represent a divalent linking group,
a wavy line part represents a bonding site with a nitrogen atom in Formula (A1) or Formula (B1), and
* represents a bonding site with a carbon atom to which R^{A4} in Formula (A1) is bonded or a carbon atom to which R^{B4} in Formula (B1) is bonded.
